(19) United States
(12) Patent Application Publication
(10) Pub. No.: US 2018/0312531 A1
(43) Pub. Date: Nov. 1, 2018

(54) SILICON-CONTAINING ORGANIC COMPOUND AND APPLICATIONS THEREOF

(71) Applicant: GUANGZHOU CHINARAY OPTOELECTRONIC MATERIALS LTD., Guangzhou (CN)

(72) Inventors: Junyou Pan, Guangzhou (CN); Hong Huang, Guangzhou (CN)

(21) Appl. No.: 16/026,639

(22) Filed: Jul. 3, 2018

Related U.S. Application Data
(63) Continuation of application No. PCT/CN2016/105091, filed on Nov. 8, 2016.

(30) Foreign Application Priority Data
Jan. 7, 2016 (CN) 201610013186.3

(51) Int. Cl. C07F 7/08; H01L 51/00; H01L 51/50

(52) U.S. Cl. CPC C07F 7/0816; C07F 7/0814; H01L 51/0094; H01L 51/0072; H01L 51/0073; H01L 51/5004; H01L 51/0069; H01L 51/0035; H01L 51/5024; H01L 51/5016; H01L 51/0074

(57) ABSTRACT

The present invention relates to a silicon-containing organic compound and an application thereof. The silicon-containing organic compound comprises one or more silicon atoms, and has a ΔE (S1−T1)≤0.20 eV, allowing the compound to exhibit a property of thermally activated delayed fluorescence (TADF). The silicon-containing organic compound can be used as a TADF light emitting material. Combination thereof with a suitable host material will improve a luminous efficiency and a lifespan of an electroluminescent device. The silicon-containing organic compound thereby provides a low cost, high performance, long life span, and low roll-off light-emitting device.

### CROSS-REFERENCE TO THE RELATED APPLICATIONS

This application is a continuation application, under 35 U.S.C. § 111(a), of international application No. PCT/CN2016/105091, filed Nov. 8, 2016, wherein the entirety of said application is incorporated herein by reference. International application No. PCT/CN2016/105091 claims priority to Chinese Patent Application No. CN 201610013186.3, filed Jan. 7, 2016.

### TECHNICAL FIELD

The present disclosure relates to the field of organic electroluminescence materials, and more particularly relates to a silicon-containing organic compound and applications thereof.

### BACKGROUND

The diversity and synthesis of organic electroluminescent materials have established a solid foundation for the implement of large-area new display devices. In order to improve the luminous efficiency of organic light-emitting diodes (OLED), fluorescence-based and phosphorescence-based light-emitting material systems have been developed. The organic light-emitting diodes using fluorescent materials have a high reliability. However, since the exciton has a branching ratio between the singlet excited state and the triplet excited state of 1:3, its internal electroluminescence quantum efficiency is limited to 25% under electrical excitation. In contrast, the organic light-emitting diodes using phosphorescent materials have achieved almost 100% internal electroluminescent quantum efficiency. However, the organic light-emitting diodes of phosphorescent materials have a Roll-off effect in the high brightness. In other words, the efficiency of the OLED decreases rapidly with an increase in current or luminance, which is particularly disadvantageous for applications of organic light-emitting diodes requiring high brightness.

Conventional phosphorescent materials with practical use value are complexes including iridium or platinum, which are rare and expensive. The synthesis of the complexes is complicated which leads to a quite high cost. In order to overcome the rarity and cost of the raw materials for iridium or platinum complexes and the complexities of their synthesis, Adachi proposed the concept of reverse intersystem crossing, which makes it possible to use organic compounds, i.e., without using metal complexes, to achieve a high efficiency comparable to organic light-emitting diodes of phosphorescent materials. This concept has been achieved through various combinations of materials, such as: 1) Using exciplex, see Adachi et al., Nature Photonics, Vol. 6, p253 (2012); 2) Using thermally activated delayed fluorescence (TADF) materials, see Adachi et al., Nature, Vol. 492, 234, (2012).

The reported TADF materials mainly employ the way that the electron-donating group (Donor) is connected to the electron-deficiency group or the electron-accepting group (Acceptor), resulting in a complete separation of the electron cloud distributions of the highest occupied molecular orbital (HOMO) and the lowest unoccupied molecular orbital (LUMO), which further reduces the energy level difference (ΔE(S1−T1)) between singlet state (S1) and triplet state (T1) of organic compounds. The red and green TADF materials have been developed and have achieved certain results in many aspects of performance, but their lifetime is still low. In particular, the performance of blue TADF light-emitting material still has a large gap compared with that of the phosphorescent luminescent material.

Therefore, the prior art, in particular, the solution for TADF material has yet to be improved and developed.

### SUMMARY

Accordingly, the present disclosure provides a silicon-containing organic compound and application thereof, so as to solve the problems that the existing electrophosphorescent material has a high cost, a rapid roll-off at a high brightness, a short lifetime, and the TADF material has a short lifetime.

The technical solutions of the present disclosure to solve the aforementioned technical problems are as follows.

A silicon-containing organic compound has formula selected from any one of the following (1) to (7):

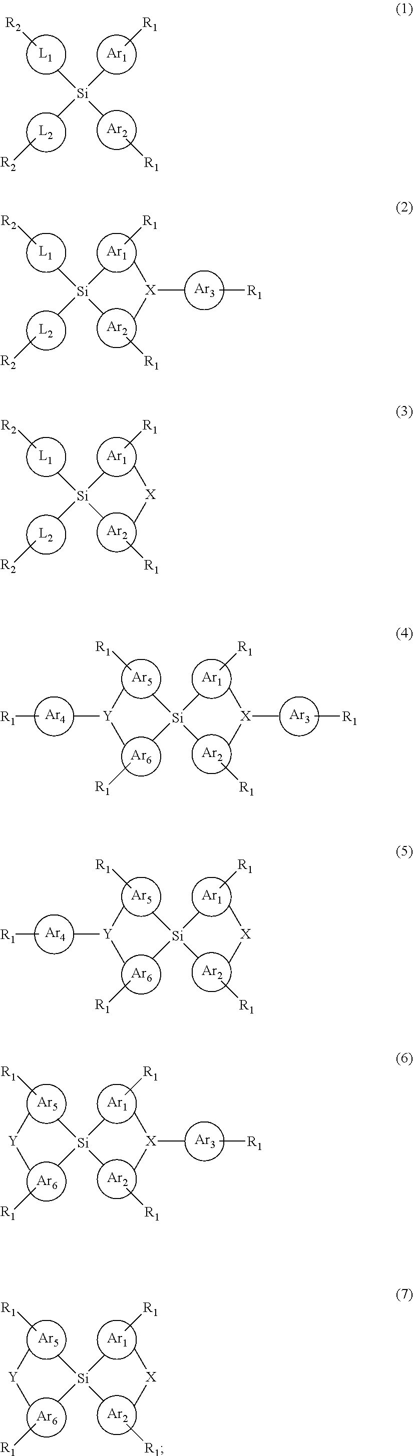

Ar₁, Ar₂, Ar₃, Ar₄, Ar₅, and Ar₆ are independently selected from the group consisting of aromatic group, heteroaromatic group, and non-aromatic cyclic group.

L₁ and L₂ are independently selected from the group consisting of aromatic group, heteroaromatic group, and non-aromatic cyclic group; or independently selected from the group consisting of linear alkyl, alkane ether group, alkane aromatic group, alkane heteroaromatic group, and alkane non-aromatic cyclic group.

The plurality of R₁ are independently selected from the group consisting of H, F, Cl, Br, I, D, CN, NO₂, CF₃, B(OR₃)₂, Si(R₃)₃, linear alkyl, alkane ether group, alkane thioether group containing 1 to 10 carbon atoms, branched alkyl, cycloalkyl, and alkane ether group containing 3 to 10 carbon atoms.

The plurality of R₂ are independently selected from the group consisting of H, F, Cl, Br, I, D, CN, NO₂, CF₃, B(OR₃)₂, Si(R₃)₃, linear alkyl, alkane ether group, alkane thioether group containing 1 to 10 carbon atoms, branched alkyl, cycloalkyl, and alkane ether group containing 3 to 10 carbon atoms.

The plurality of R₃ are independently selected from the group consisting of aliphatic alkyl containing 1 to 10 carbon atoms, aromatic hydrocarbon group, and unsubstituted or substituted aryl or heteroaryl containing 5 to 10 ring atoms.

X is a triply bridging group or a doubly bridging group; Y is a triply bridging group or a doubly bridging group.

The silicon-containing organic compound has a ΔE(S₁−T₁) less than or equal to 0.20 eV, and the silicon-containing organic compound comprises at least one electron-donating group and/or at least one electron-accepting group.

In one of the embodiments, carbon atoms in each of Ar₁, Ar₂, Ar₃, Ar₄, Ar₅, Ar₆, L₁, and L₂ are less than or equal to 20. In one of the embodiments, carbon atoms in each of Ar₁, Ar₂, Ar₃, Ar₄, Ar₅, Ar₆, L₁, and L₂ are less than or equal to 30.

In one of the embodiments, X and Y are independently selected from one of the following groups:

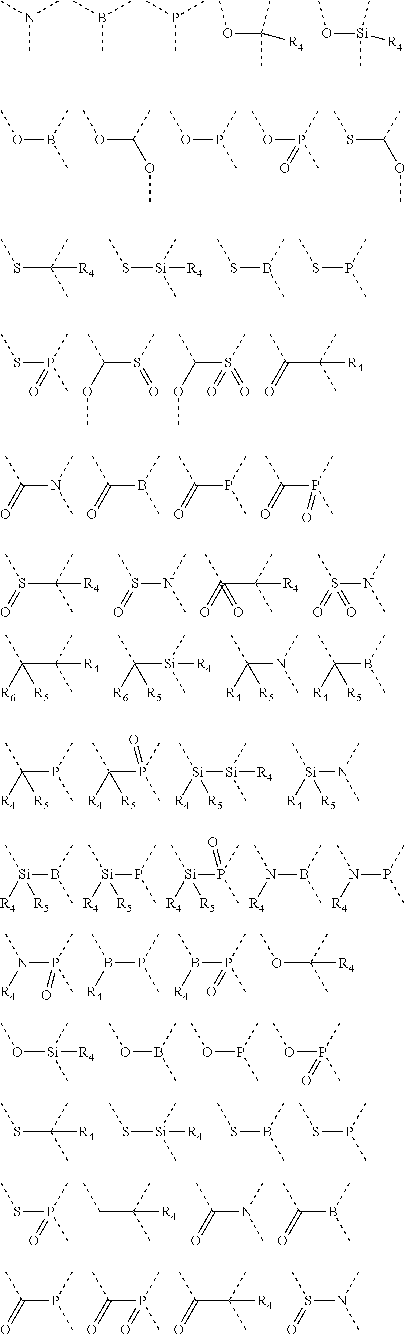

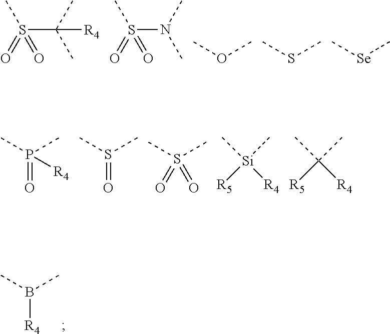

R₄, R₅, and R₆ are independently selected from the group consisting of H, F, Cl, Br, I, D, CN, NO₂, CF₃, B(OR₃)₂, Si(R₃)₃, linear alkyl, alkane ether group, alkane thioether group containing 1 to 10 carbon atoms, branched alkyl, cycloalkyl, and alkane ether group containing 3 to 10 carbon atoms.

In one of the embodiments, Ar₁, Ar₂, Ar₅, and Ar₆ are independently selected from one of the following groups:

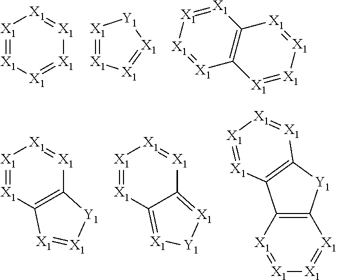

X₁ is CR⁵ or N; Y₁ is CR⁶R⁷, SiR⁸R⁹, NR¹⁰, C(═O), S, or O.

R⁵, R⁶, R⁷, R⁸, R⁹, and R¹⁰ independently are selected from at least one of the group consisting of H; D; linear alkyl containing 1 to 20 carbon atoms, linear alkoxy containing 1 to 20 carbon atoms, or linear thioalkoxy containing 1 to 20 carbon atoms; branched or cyclic alkyl containing 3 to 20 carbon atoms, branched or cyclic alkoxy containing 3 to 20 carbon atoms, or branched or cyclic thioalkoxy group containing 3 to 20 carbon atoms; silyl; substituted keto group containing 1 to 20 carbon atoms; alkoxy carbonyl containing 2 to 20 carbon atoms; aryloxy carbonyl containing 7 to 20 carbon atoms; cyano; carbamoyl; haloformyl; formyl; isocyano; isocyanate group; thiocyanate group; isothiocyanate group; hydroxy; nitro; CF₃; Cl; Br; F; crosslinkable group; substituted or unsubstituted aromatic group or heteroaromatic group containing 5 to 40 ring atoms; and aryloxy or heteroaryloxy containing 5 to 40 ring atoms.

In one of the embodiments, Ar₁, Ar₂, Ar₅, and Ar₆ are independently selected from one of the following groups:

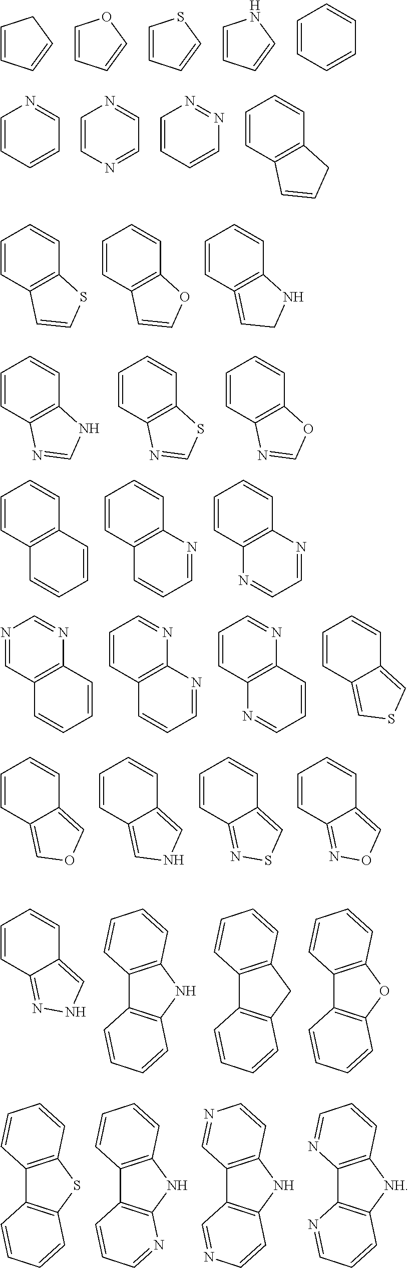

In one of the embodiments, Ar₃ and Ar₄ are independently selected from one of the following groups:

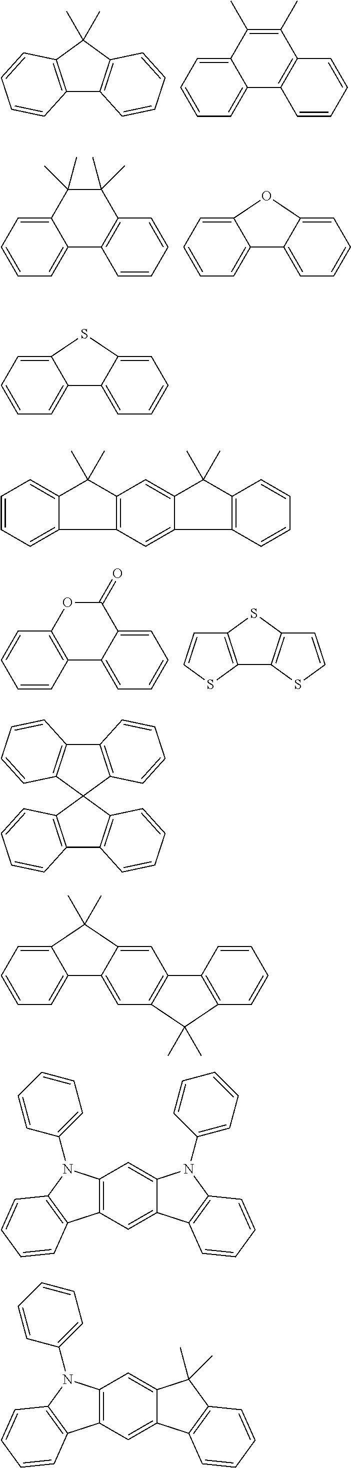

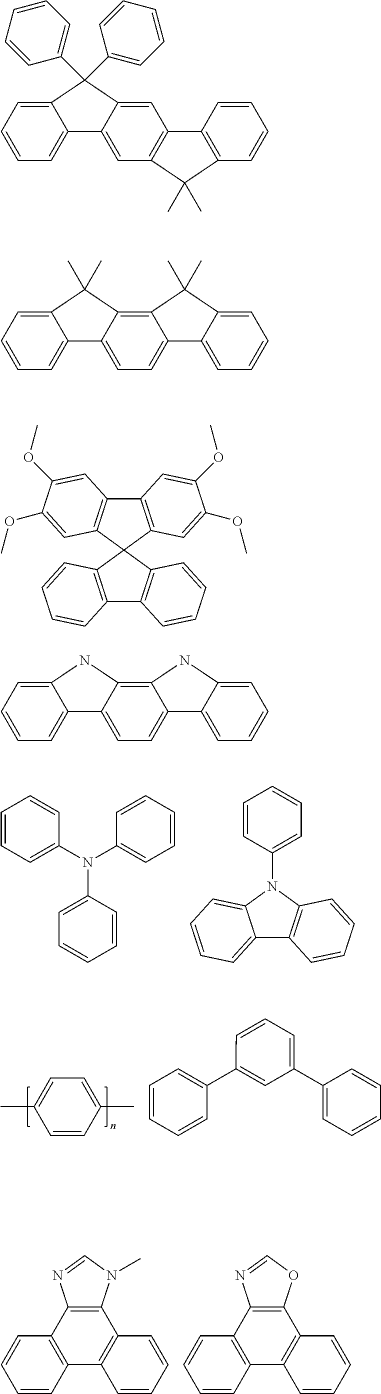

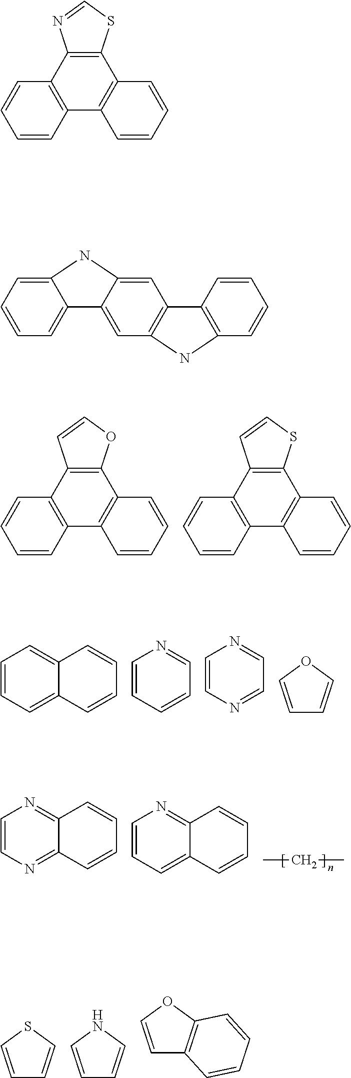

n is an integer selecting from 1 to 4.

In one of the embodiments, the silicon-containing organic compound has one of the following formulas:

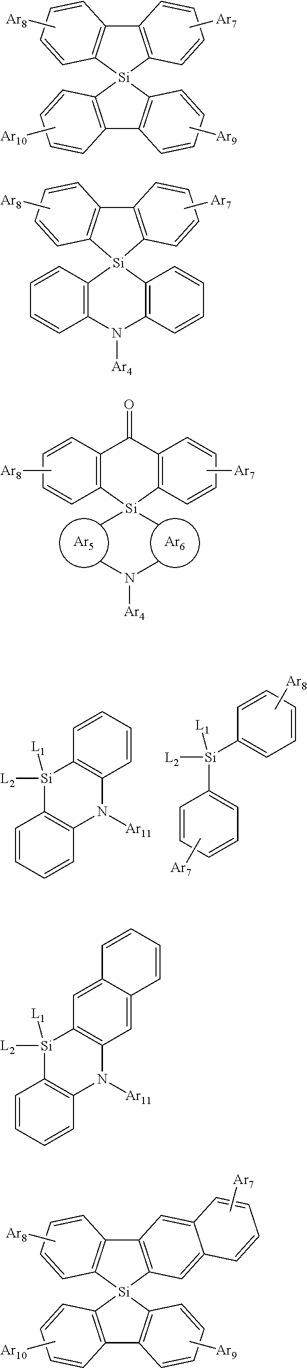

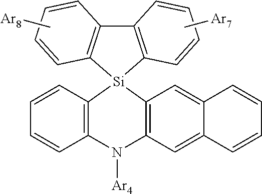

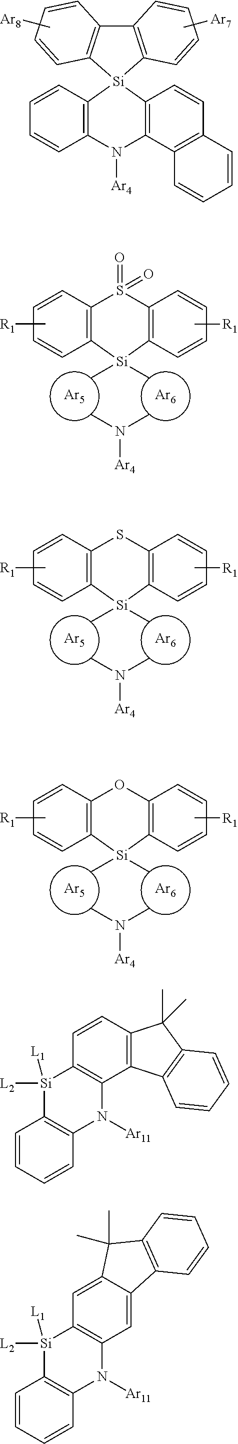

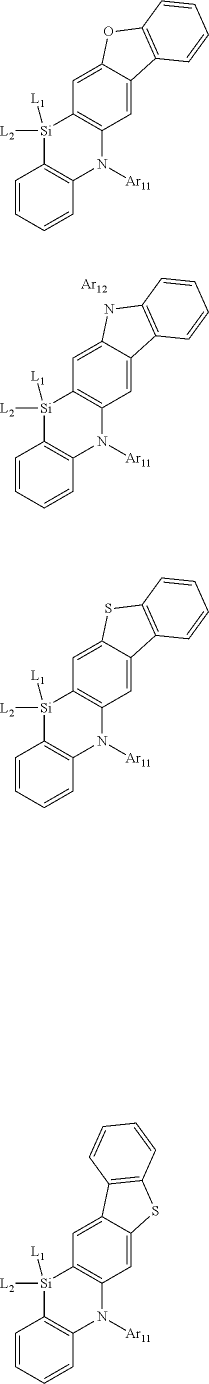

wherein, Ar₇ and/or Ar₈ are electron-accepting groups, Ar₁₁ and Ar₁₂ are electron-accepting groups, Ar₉ and/or Ar₁₀ are electron-donating groups.

In one of the embodiments, at least one of Ar₁, Ar₂, Ar₃, Ar₄, Ar₅, and Ar₆ comprises one electron-donating group, and/or at least one of Ar₁, Ar₂, Ar₃, Ar₄, Ar₅, and Ar₆ comprises one electron-accepting group.

In one of the embodiments, the electron-donating group is selected from at least one of the group consisting of:

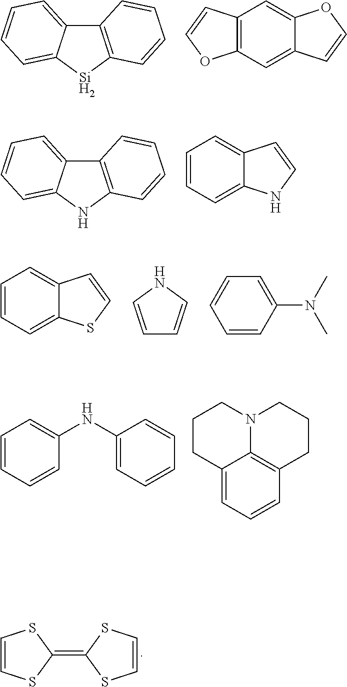

In one of the embodiments, the electron-accepting group is selected from —F or cyano, or is selected from at least one of the group consisting of:

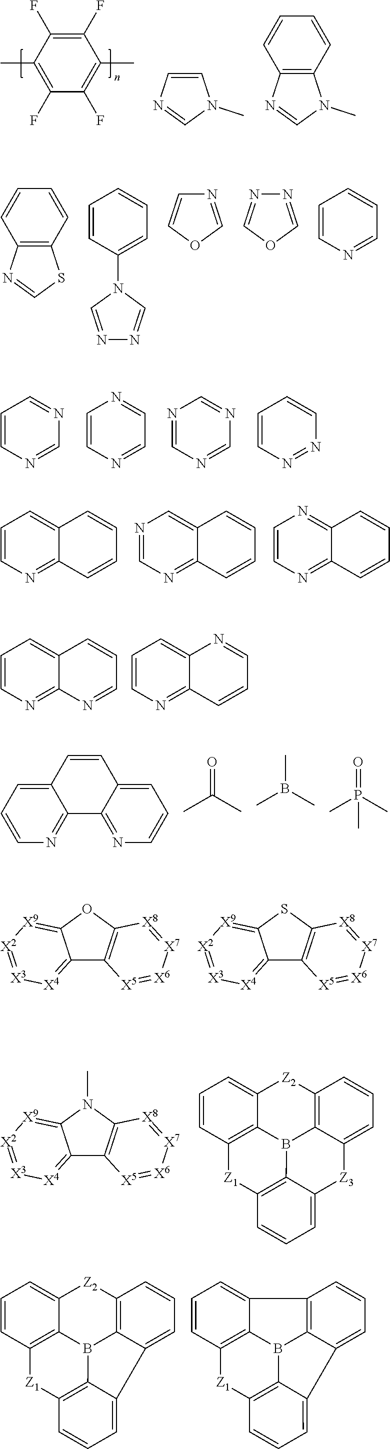

n is an integer selecting from 1 to 4.

X² to X⁹ is selected from CR or N, and at least one of X² to X⁹ is N.

Z₁, Z₂, and Z₃ are independently selected from the group consisting of N(R), C(R)₂, Si(R)₂, O, C═N(R), C═C(R)₂, P(R), P(═O)R, S, S═O, and SO₂.

R is selected from the group consisting of hydrogen, alkyl, alkoxy, amino, alkene, alkyne, aralkyl, heteroalkyl, aryl, and heteroaryl.

A silicon-containing organic polymer has a plurality of repetitive units of the silicon-containing organic compound according to any one of the aforementioned embodiments.

A silicon-containing mixture includes the silicon-containing organic compound and/or the silicon-containing organic polymer according to any one of the aforementioned embodiments, and an organic functional material. The organic functional material is selected from at least one of the group consisting of hole injection materials, hole transport materials, electron transport materials, electron injection materials, electron blocking materials, hole blocking materials, emitters, host materials, and organic dyes.

A silicon-containing formulation includes the silicon-containing organic compound and/or the silicon-containing organic polymer according to any one of the aforementioned embodiments, and an organic solvent.

An application of the silicon-containing organic compound, the silicon-containing organic polymer, the silicon-containing mixture, or the silicon-containing formulation according to any one of the aforementioned embodiments in manufacturing an organic electronic device.

An organic electronic device includes the silicon-containing organic compound, the silicon-containing organic polymer, the silicon-containing mixture, or the silicon-containing formulation according to any one of the aforementioned embodiments.

In one of the embodiments, the organic electronic device is an organic light-emitting diode, an organic photovoltaic cell, an organic light-emitting cell, an organic field-effect transistor, an organic light-emitting field-effect transistor, an organic laser, an organic spin electron device, an organic sensor, or an organic plasmon emitting diode.

In one of the embodiments, the organic electronic device is an organic electroluminescent device, a light-emitting layer includes the silicon-containing organic compound or the silicon-containing polymer according to any one of the aforementioned embodiments;

or the light-emitting layer includes a mixture of the silicon-containing organic compound or the silicon-containing polymer according to any one of the aforementioned embodiments and a phosphorescent emitter;

or the light-emitting layer includes a mixture of the silicon-containing organic compound or the silicon-containing polymer according to any one of the aforementioned embodiments and a host material;

or the light-emitting layer includes a mixture of the silicon-containing organic compound or the silicon-containing polymer according to any one of the aforementioned embodiments with the phosphorescent emitter and the host material.

The aforementioned silicon-containing organic compound contains one or more silicon atoms and has a ΔE(S₁−T₁) less than or equal to 0.20 eV, which facilitates the realization of the luminescent properties of thermally activated delayed fluorescence (TADF). By coordinating with a suitable host material, the aforementioned silicon-containing organic compound can be used as a TADF light-emitting material to improve the luminescent efficiency and lifetime of the electroluminescent device. Thus, the contained organic compound provides a better solution for manufacturing a light-emitting device with low cost, high efficiency, long lifetime, and low roll-off.

### DETAILED DESCRIPTION OF THE EMBODIMENTS

Embodiments of the invention are described more fully hereinafter with reference to the accompanying drawings. The various embodiments of the invention may, however, be embodied in many different forms and should not be construed as limited to the embodiments set forth herein. Rather, these embodiments are provided so that this disclosure will be thorough and complete, and will fully convey the scope of the invention to those skilled in the art.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. The term “and/or” as used herein includes any and all combinations of one or more of the associated listed items.

The formulations described herein have the same meaning as printing inks or inks and are interchangeable. The host materials (Host) and matrix materials (Matrix) described herein have the same meaning and are interchangeable. The metal organic complexes, metal organic coordination compounds, and organometallic complexes described herein have the same meaning and are interchangeable.

A silicon-containing organic compound is provided according to the present embodiment, which has formula selected from any one of the following (1) to (7).

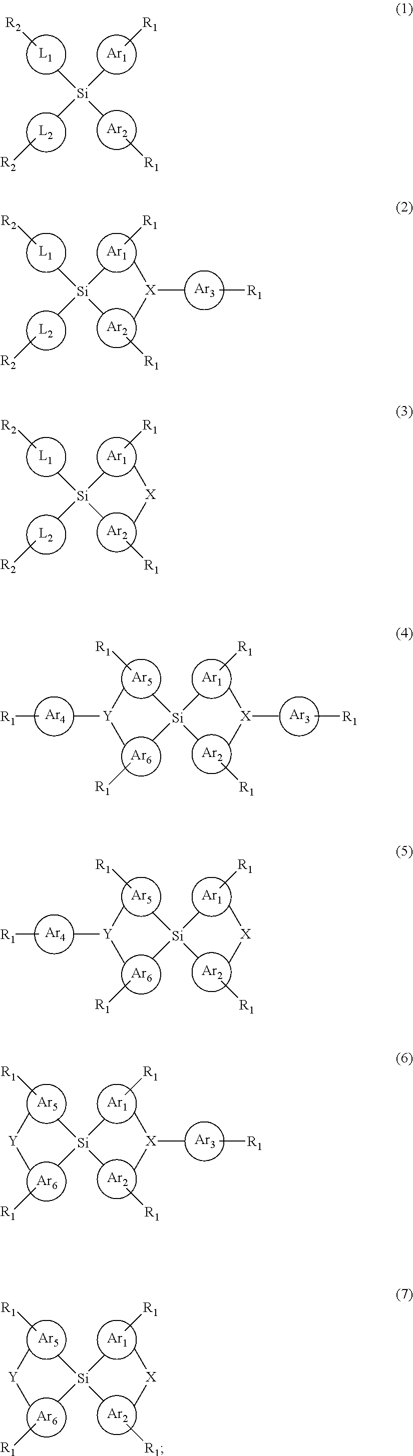

Ar₁, Ar₂, Ar₃, Ar₄, Ar₅, and Ar₆ are independently selected from the group consisting of aromatic group, heteroaromatic group, and non-aromatic cyclic group.

L₁ and L₂ are independently selected from the group consisting of aromatic group, heteroaromatic group, and non-aromatic cyclic group; or independently selected from the group consisting of linear alkyl, alkane ether, alkane aromatic group, alkane heteroaromatic group, and alkane non-aromatic cyclic group.

In one embodiment, carbon atoms in each of Ar₁, Ar₂, Ar₃, Ar₄, Ar₅, Ar₆, L₁, and L₂ are less than or equal to 20.

The plurality of R₁ are independently selected from the group consisting of H, F, Cl, Br, I, D (deuterium), CN, NO₂, CF₃, B(OR₃)₂, Si(R₃)₃, linear alkyl, alkane ether group, alkane thioether group containing 1 to 10 carbon atoms, branched alkyl, cycloalkyl, and alkane ether group containing 3 to 10 carbon atoms.

The plurality of R₂ are independently selected from the group consisting of H, F, Cl, Br, I, D, CN, NO₂, CF₃, B(OR₃)₂, Si(R₃)₃, linear alkyl, alkane ether group, alkane thioether group containing 1 to 10 carbon atoms, branched alkyl, cycloalkyl, and alkane ether group containing 3 to 10 carbon atoms.

The plurality of R₃ are independently selected from the group consisting of aliphatic alkyl containing 1 to 10 carbon atoms, aromatic hydrocarbon group, and substituted or unsubstituted aryl or heteroaryl containing 5 to 10 ring atoms.

X is a triply bridging group or a doubly bridging group, which is single-bonded to Ar₁, Ar₂, and Ar₃, respectively. Y is a triply bridging group or a doubly bridging group, which is single-bonded to Ar₄, Ar₅, and Ar₆, respectively.

The silicon-containing organic compound has a ΔE(S₁−T₁) less than or equal to 0.20 eV, which can be used as a TADF light-emitting material. In one embodiment, the ΔE(S₁−T₁) of the silicon-containing organic compound is less than or equal to 0.18 eV. In another embodiment, the ΔE(S₁−T₁) of the silicon-containing organic compound is less than or equal to 0.15 eV. In yet another embodiment, the ΔE(S₁−T₁) of the silicon-containing organic compound is less than or equal to 0.12 eV. In a further embodiment, the ΔE(S₁−T₁) of the silicon-containing organic compound is less than or equal to 0.10 eV.

In addition, the silicon-containing organic compound includes at least one electron-donating group and/or at least one electron-accepting group. In one embodiment, the silicon-containing organic compound includes at least one electron-donating group and one electron-accepting group.

In one embodiment, carbon atoms in each of Ar₁, Ar₂, Ar₃, Ar₄, Ar₅, and Ar₆ are less than or equal to 20. In another embodiment, carbon atoms in each of Ar₁, Ar₂, Ar₃, Ar₄, Ar₅, Ar₆, L₁, and L₂ are less than or equal to 30. Moreover, in one embodiment, the aromatic group contains 5 to 15 carbon atoms in the ring system. In another embodiment, the aromatic group contains 5 to 10 carbon atoms. The heteroaromatic group contains 2 to 15 carbon atoms and at least one heteroatom in the ring system. In one embodiment, the heteroaromatic group contains 2 to 10 carbon atoms and at least one heteroatom, provided that the total number of carbon atoms and heteroatoms is at least 4. In one embodiment, the heteroatoms are Si, N, P, O, S, and/or Ge. In another embodiment, the heteroatoms are selected from Si, N, P, O, and/or S.

The aromatics, aromatic group, or aromatic groups described herein refer to hydrocarbyl containing at least one aromatic ring, which includes a monocyclic group and a polycyclic ring system. The heteroaromatics or heteroaromatic group refers to hydrocarbyl (containing heteroatoms) containing at least one heteroaromatic ring, which includes a monocyclic group and a polycyclic ring system. These polycyclic rings may have two or more rings, in which two carbon atoms are shared by two adjacent rings, i.e., a fused ring. At least one ring of these polycyclic rings is aromatic or heteroaromatic. Regarding the present embodiment, the aromatic group or the heteroaromatic group includes not only aryl or heteroaryl, but also a plurality of aryl or heteroaryl may also be interrupted by short non-aromatic units (<10% non-H atoms, in one embodiment less than 5% of non-H atoms, such as C, N, or O atoms). Therefore, groups such as 9, 9′-spirobifluorene, 9, 9-diarylfluorene, triarylamine, diaryl ether, and the like also belong to the aromatic group of the present embodiment.

Specifically, examples of aromatic include benzene, naphthalene, anthracene, phenanthrene, perylene, naphthacene, pyrene, benzopyrene, triphenylene, acenaphthene, fluorene, and the corresponding derivatives. Aromatic groups are groups formed by aromatics, and the definitions of the following heteroaromatic groups and non-aromatic cyclic groups are the same.

Examples of heteroaromatic are furan, benzofuran, thiophene, benzothiophene, pyrrole, pyrazole, triazole, imidazole, oxazole, oxadiazole, thiazole, tetrazole, indole, carbazole, pyrroloimidazole, pyrrolopyrrole, thienopyrrole, thienothiophene, furopyrrole, furofuran, thienofuran, benzisoxazole, benzisothiazole, benzimidazole, pyridine, pyrazine, pyridazine, pyrimidine, triazine, quinoline, isoquinoline, cinnoline, quinoxaline, phenanthridine, perimidine, quinazoline, quinazolinone, and the corresponding derivatives.

Non-aromatic cyclic groups contain 1 to 10 carbon atoms in the ring system. In one embodiment, the non-aromatic cyclic groups contain 1 to 3 carbon atoms. The non-aromatic cyclic groups include not only saturated ring systems but also partially unsaturated ring systems, which may be unsubstituted or mono- or polysubstituted by the group R₁. The group R₁ may be the same or different in each occurrence, and may also contain one or more heteroatoms such as Si, N, P, O, S, and/or Ge. In one embodiment, the group R₁ may contain Si, N, P, O, and/or S. These can be, for example, cyclohexyl- or piperidine-like systems, but also can be cyclooctadiene-like cyclic systems. Non-aromatic ring systems described herein also include fused non-aromatic ring systems.

In the present embodiment, the H atom on the NH or the bridging CH₂ group can be substituted by a R₁ group. R₁ may be selected from the group consisting of: (1) C1-C10 alkyl, particularly refers to the following groups: methyl, ethyl, n-propyl, isopropyl, cyclopropyl, n-butyl, isobutyl, sec-butyl, t-butyl, cyclobutyl, 2-methylbutyl, n-pentyl, n-hexyl, cyclohexyl, n-heptyl, cycloheptyl, n-octyl, cyclooctyl, 2-ethylhexyl, trifluoromethyl, pentafluoromethyl, 2,2,2-trifluoroethyl, vinyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl, and octynyl; (2) C1-C10 alkoxy, particularly refers to methoxy, ethoxy, n-propoxy, isopropoxy, n-butoxy, isobutoxy, sec-butoxy, t-butoxy, and 2-methylbutoxy; (3) C2-C10 aryl or heteroaryl, which can be monovalent or divalent depending on the use. In each case, it may be further substituted by the aforementioned R₁ group and may be connected to the aromatic or heteroaromatic ring at any desired position. Particularly refers to the following groups: benzene, naphthalene, anthracene, pyrene, dihydropyrene, chrysene, perylene, fluoranthene, naphthacene, pentacene, benzopyrene, furan, benzofuran, isobenzofuran, dibenzofuran, thiophene, benzothiophene, isobenzothiophene, dibenzothiophen, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazol, indazole, imidazole, benzimidazole, naphthoimidazole, phenanthroimidazole, pyridimazole, pyrazimidazole, quinoxalineimidazole, oxazole, benzoxazole, naphthoxazole, anthraoxazole, phenanthroxazole, isoxazole, 1,2-thiazole, 1,3-thiazole, benzothiazole, pyridazine, benzopyridazine, pyrimidine, benzopyrimidine, quinoxaline, pyrazine, diazaanthracenyl, 1,5-naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole. 1,2,4,5-tetrazine, 1,2,3,4-tetrazine, 1,2,3,5-tetrazine, purine, pteridine, indolizine or benzothiadiazole. In addition, in addition to the specifically aforementioned aryl and heteroaryl, the aromatic ring system and the heteroaromatic ring system of the present embodiment also include biphenylene, terphenylene, fluorene, spirobifluorene, dihydrophenanthrene, tetrahydropyrene, cis- and trans-indenofluorene, and the like.

Moreover, in the silicon-containing organic compounds according to structural formulas (1)-(7), Ar₁, Ar₂, Ar₅, and Ar₆ are the same or different in each occurrence, in some embodiments, Ar₁, Ar₂, Ar₅, and Ar₆ are selected from aromatic ring system containing 2-10 carbon atoms, heteroaromatic ring system, or non-aromatic ring system. In one embodiment, they can be unsubstituted or substituted by one or two R₁ groups. In some embodiments, the aromatic ring system or heteroaromatic ring system are selected from the group consisting of benzene, naphthalene, anthracene, phenanthrene, pyridine, pyrene, and thiophene.

In the present embodiment, X and Y are independently selected from one of the following bridging groups:

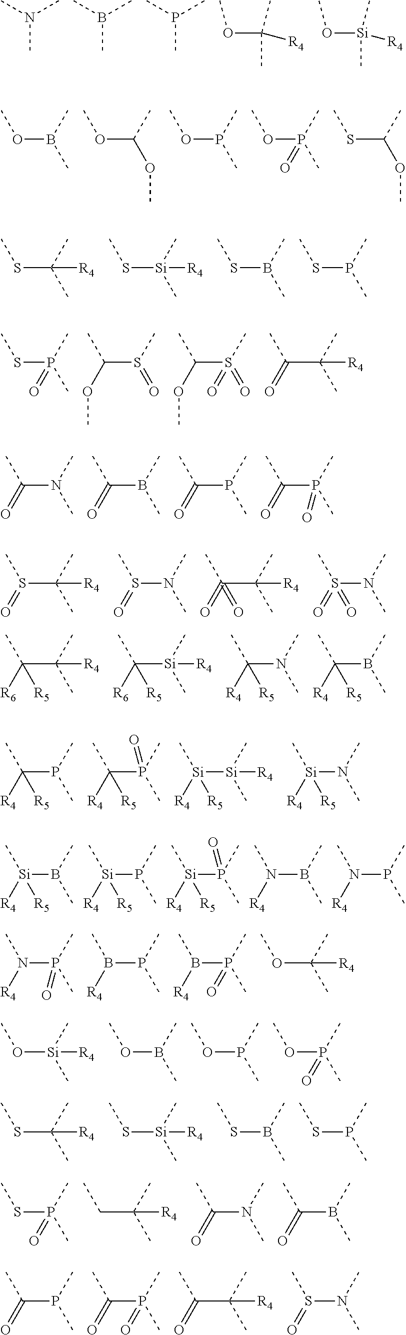

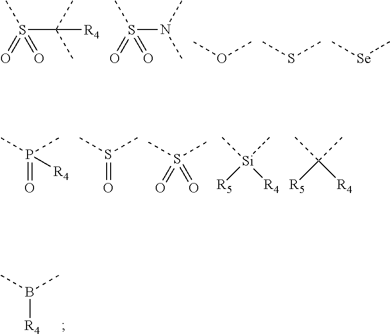

wherein R₄, R₅, and R₆ are independently selected from the group consisting of H, F, Cl, Br, I, D, CN, NO₂, CF₃, B(OR₃)₂, Si(R₃)₃, linear alkyl, alkane ether group, alkane thioether group containing 1 to 10 carbon atoms, branched alkyl, cycloalkyl, and alkane ether group containing 3 to 10 carbon atoms. Dashed lines represent bonds configured to bond with Ar₁, Ar₂, Ar₃, Ar₅, Ar₆, Ar₄, and the like.

In one embodiment, X, and Y are selected from the bridging groups of the following structural formulas:

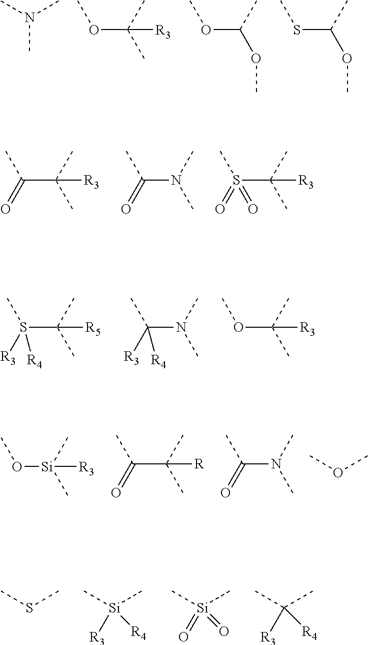

In another embodiment, X, and Y are selected from the bridging groups of the following structural formulas:

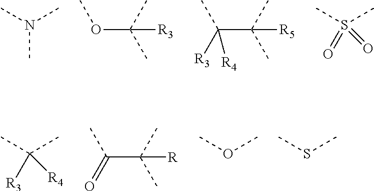

In the present embodiment, Ar₁, Ar₂, Ar₅, and Ar₆ are independently selected from one of the following groups:

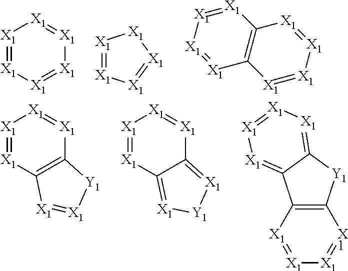

X₁ is CR⁵ or N; Y₁ is selected from CR⁶R⁷, SiR⁸R⁹, NR¹⁰, C(═O), S, or O.

R⁵, R⁶, R⁷, R⁸, R⁹, and R¹⁰ are independently selected from one of the following groups: H; D; linear alkyl containing 1 to 20 carbon atoms, linear alkoxy containing 1 to 20 carbon atoms, or linear thioalkoxy containing 1 to 20 carbon atoms; branched or cyclic alkyl containing 3 to 20 carbon atoms, branched or cyclic alkoxy containing 3 to 20 carbon atoms or branched or cyclic thioalkoxy group containing 3 to 20 carbon atoms; silyl; substituted keto group containing 1 to 20 carbon atoms; alkoxy carbonyl containing 2 to 20 carbon atoms; aryloxy carbonyl containing 7 to 20 carbon atoms; cyano; carbamoyl; haloformyl; formyl; isocyano; isocyanate group; thiocyanate group; isothiocyanate group; hydroxy; nitro; CF₃; Cl; Br; F; crosslinkable group; substituted or unsubstituted aromatic group or heteroaromatic group containing 5 to 40 ring atoms; and aryloxy or heteroaryloxy containing 5 to 40 ring atoms, or a combination of the above groups. One or more of the groups R⁵, R⁶, R⁷, R⁸, R⁹, and R¹⁰ may form a monocyclic or polycyclic aliphatic or aromatic ring with each other and/or with a ring bonded to a corresponding group.

In one embodiment, Ar₁, Ar₂, Ar₅, and Ar₆ are independently selected from one of the following groups:

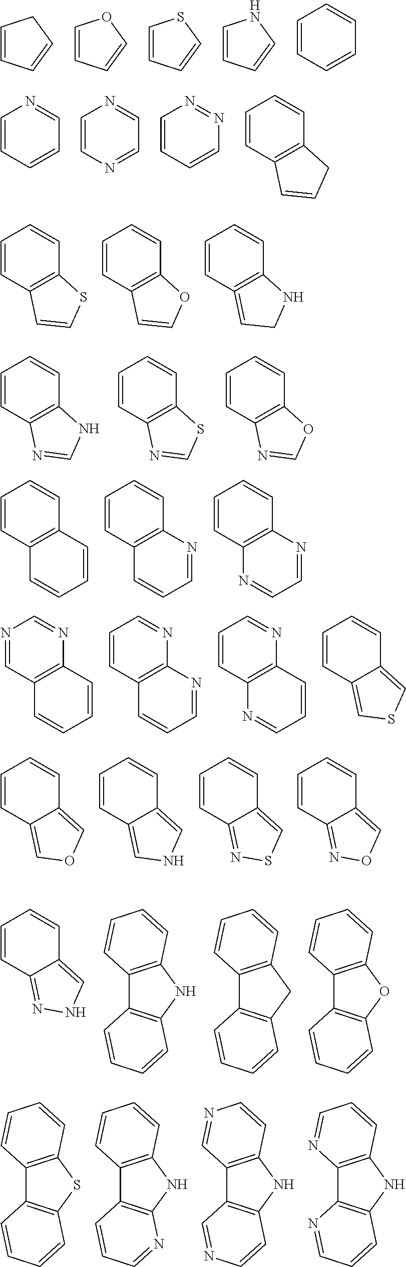

In the present embodiment, the silicon-containing organic compound has a higher triplet energy level T₁, for example, T₁ is greater than or equal to 2.0 eV. In one embodiment, T₁ is greater than or equal to 2.2 eV. In another embodiment, T₁ is greater than or equal to 2.4 eV. In yet another embodiment, T₁ is greater than or equal to 2.6 eV. In a further embodiment, T₁ is greater than or equal to 2.8 eV.

In general, the triplet energy level T₁ of the organic compound depends on the sub-structure having the largest conjugated system in the compound. Generally, T₁ decreases as the conjugate system increases. The chemical formula (1) has a large T₁ due to the sp³ atom structure of the silicon atom making the conjugation smaller. Therefore, in one embodiment, the structure represented by the following general formula (1a) has the largest conjugated system.

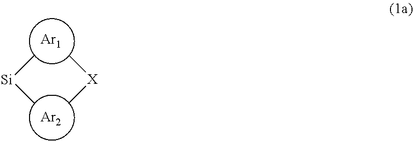

In one embodiment, when the substituent of general formula (1a) is removed, ring atoms of the general formula (1a) are less than or equal to 30. In another embodiment, ring atoms are less than or equal to 26. In yet another embodiment, ring atoms are less than or equal to 22. In a further embodiment, ring atoms are less than or equal to 20.

In addition, in one embodiment, when the substituent of general formula (1a) is removed, the T₁ of the general formula (1a) is greater than or equal to 2.0 eV. In another embodiment, T₁ is greater than or equal to 2.2 eV. In yet another embodiment, T₁ is greater than or equal to 2.4 eV. In yet another embodiment, T₁ is greater than or equal to 2.6 eV. In a further embodiment, T₁ is greater than or equal to 2.8 eV.

In the present embodiment, the silicon-containing organic compound has one of the following structural formulas:

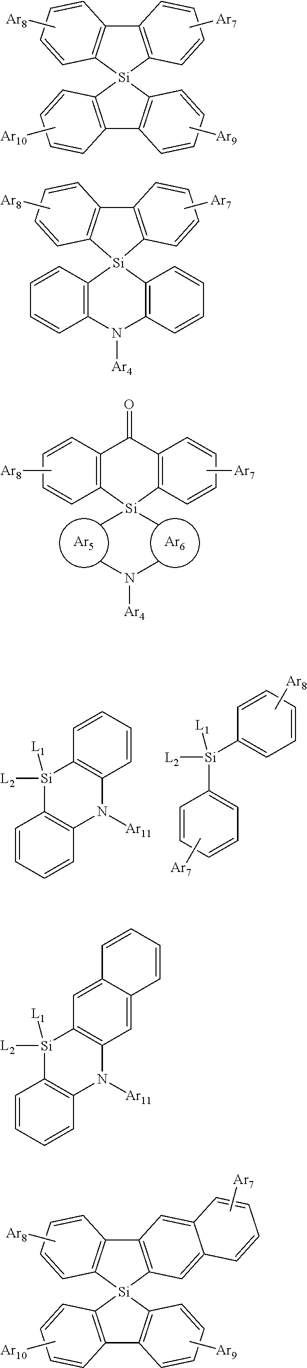

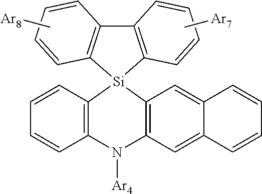

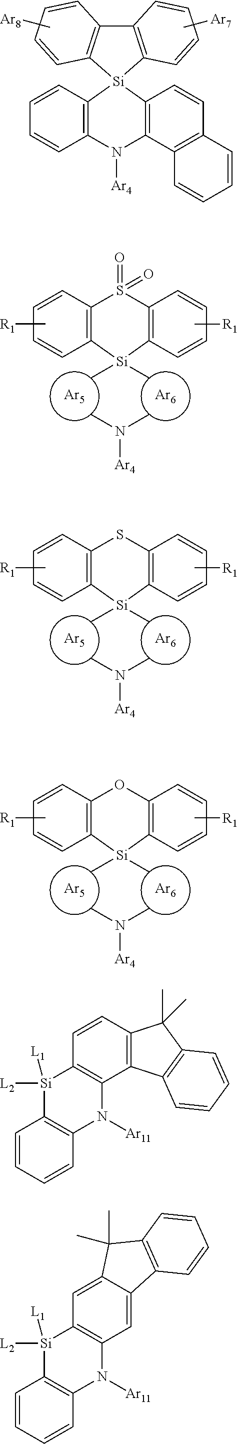

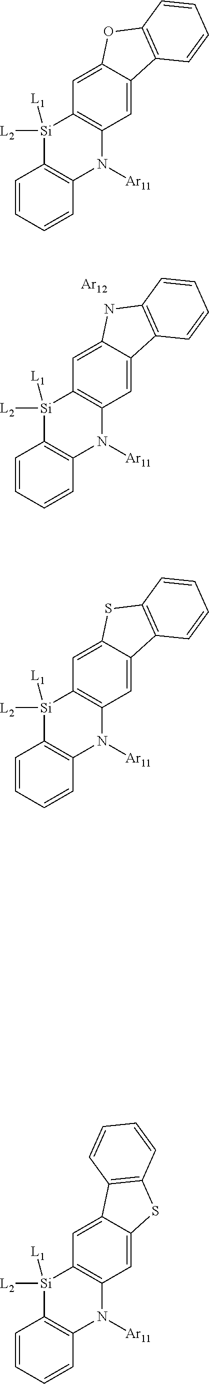

wherein Ar₇ and/or Ar₈ are electron-accepting groups, Ar₁₁ and Ar₁₂ are electron-accepting groups, Ar₉ and/or Ar₁₀ are electron-donating groups.

In one embodiment, Ar₃ and Ar₄ in the present embodiment are selected from one or more combinations of the following groups:

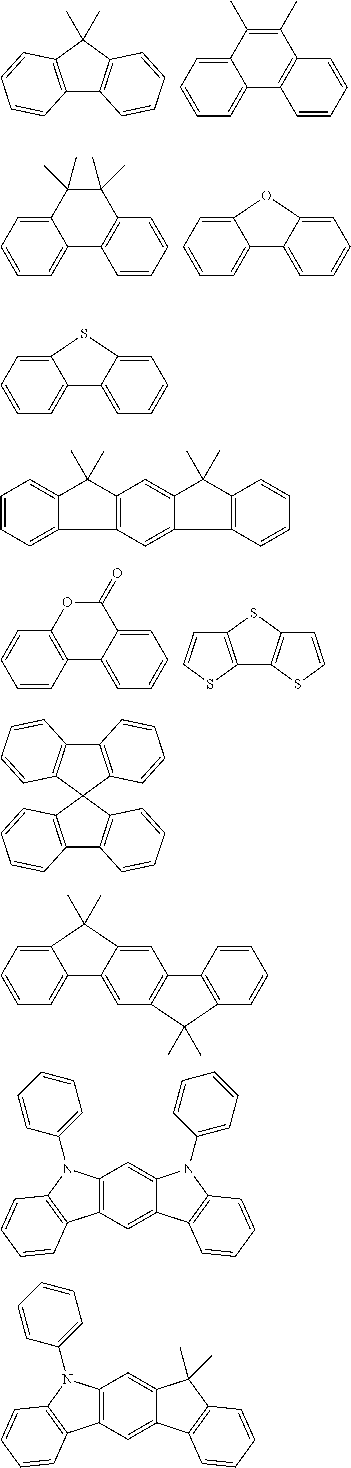

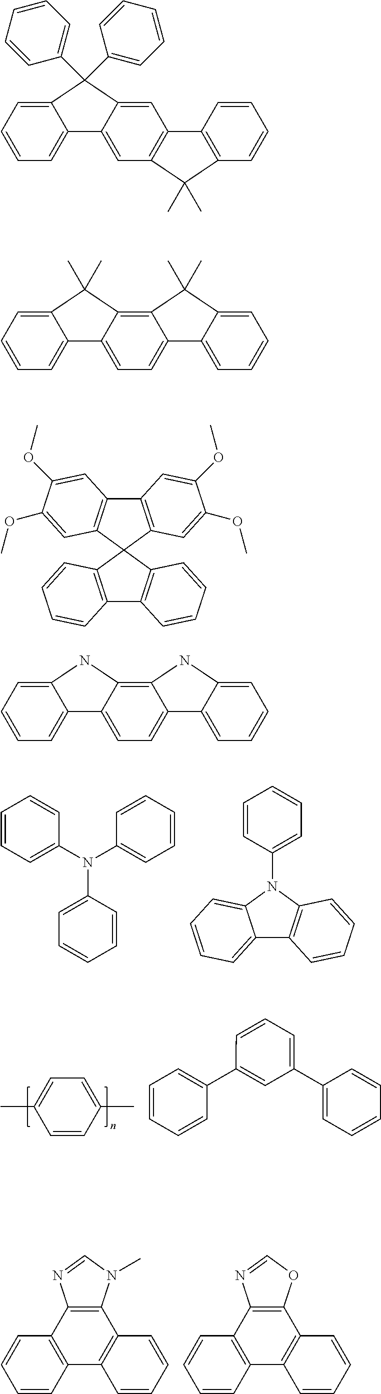

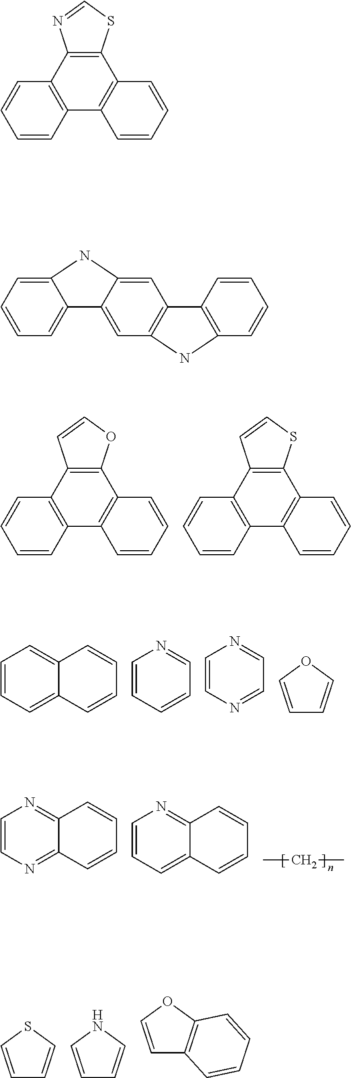

where n is an integer selecting from 1 to 4.

According to the silicon-containing organic compounds of the general formulas (1)-(7), in one embodiment, L₁, L₂, Ar₃, and Ar₄ may be the identically or differently selected from (i.e., independently selected from) the group consisting of: (1) C1-C10 alkyl, particularly refers to the following groups: methyl, ethyl, n-propyl, isopropyl, cyclopropyl, n-butyl, isobutyl, sec-butyl, t-butyl, cyclobutyl, 1-methylbutyl, n-pentyl, n-hexyl, cyclohexyl, n-heptyl, cycloheptyl, n-octyl, cyclooctyl, 2-ethylhexyl, trifluoromethyl, pentafluoroethyl, 2,2,2-trifluoroethyl, vinyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl, and octynyl; (2) C1-C10 alkoxy, particularly refers to methoxy, ethoxy, n-propoxy, isopropoxy, n-butoxy, isobutoxy, sec-butoxy, t-butoxy, and 2-methylbutoxy; (3) C2-C10 aryl or heteroaryl, which can be monovalent or divalent depending on the use. In each case, it may be substituted by the aforementioned R¹ group and may be connected to the aromatic or heteroaromatic ring at any desired position. Particularly refers to the following groups: benzene, naphthalene, pyrene, dihydropyrene, chrysene, perylene, naphthacene, pentacene, benzopyrene, furan, benzofuran, isobenzofuran, dibenzofuran, thiophene, benzothiophene, isobenzothiophene, dibenzothiophen, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazol, indazole, imidazole, benzimidazole, naphthoimidazole, phenanthroimidazole, pyridimazole, pyrazimidazole, quinoxalineimidazole, oxazole, benzoxazole, naphthoxazole, anthraoxazole, phenanthroxazole, isoxazole, 1,2-thiazole, 1,3-thiazole, benzothiazole, pyridazine, benzopyridazine, pyrimidine, benzopyrimidine, quinoxaline, pyrazine, 1,5-naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole. 1,2,4,5-tetrazine, 1,2,3,4-tetrazine, 1,2,3,5-tetrazine, purine, pteridine, indolizine or benzothiadiazole. In addition, in addition to the specifically aforementioned aryl and heteroaryl, the aromatic ring system and the heteroaromatic ring system of the present embodiment also include biphenylene, terphenylene, fluorene, spirobifluorene, dihydrophenanthrene, tetrahydropyrene, cis- and trans-indenofluorene, and the like.

The silicon-containing organic compound according to the present embodiment tends to obtain thermally activated delayed fluorescence TADF characteristics. According to the principle of thermally activated delayed fluorescence TADF material (see Adachi et al., Nature, Vol 492, 234, (2012)), when ΔE(S₁−T₁) of the organic compound is sufficiently small, the triplet excitons of the organic compound can be converted to singlet excitons through reverse intersystem crossing, thereby achieving high efficient light emission. In general, the TADF material is obtained by linking an electron-donating group (Donor) to an electron-deficiency group or an electron-accepting group (Acceptor). In other words, the TADF material has an obvious distinct D-A structure.

The silicon-containing organic compound according to the present embodiment has a smaller ΔE(S₁−T₁), normally ΔE(S₁−T₁) is less than or equal to 0.20 eV. In one embodiment, the ΔE(S₁−T₁) is less than or equal to 0.18 eV. In another embodiment, the ΔE(S₁−T₁) is less than or equal to 0.15 eV. In yet another embodiment, the ΔE(S₁−T₁) is less than or equal to 0.12 eV. In a further embodiment, the ΔE(S₁−T₁) is less than or equal to 0.09 eV.

In compounds according to the general formulas (1)-(7), when L₁, L₂, Ar₃, and Ar₄ are in multiple occurrences, at least one of L₁, L₂, Ar₃, and Ar₄ contains one electron-donating group, and/or at least one of L₁, L₂, Ar₃, and Ar₄ contains one electron-accepting group.

According to compounds of the general formulas (2)-(7), when the sub-structure according to the general formula (1a) has electron-accepting properties, at least one of L₁, L₂, Ar₃, and Ar₄ contains one electron-donating group. In one embodiment, at least one of L₁ and L₂ contains one electron-donating group, and at least one of Ar₃ and Ar₄ contains one electron-donating group.

Examples of suitable sub-structures having the electron-accepting properties according to the general formula (1a) include, but are not limited to:

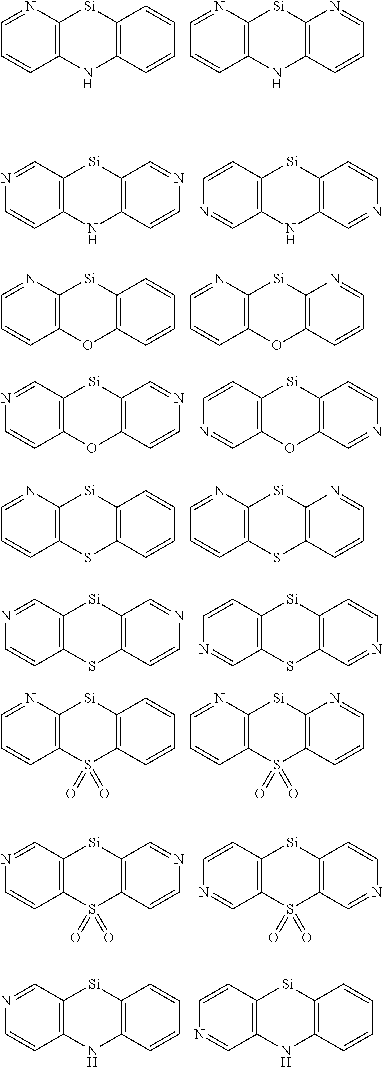

According to compounds of the general formulas (2)-(7), when the sub-structure according to the general formula (1a) has electron-donating properties, at least one of L₁, L₂, Ar₃, and Ar₄ contains one electron-accepting group. In one embodiment, at least one of L₁ and L₂ contains an electron-accepting group, and at least one of Ar₃ and Ar₄ contains an electron-accepting group.

Examples of suitable sub-structures having the electron-donating properties according to the general formula (1a) include, but are not limited to:

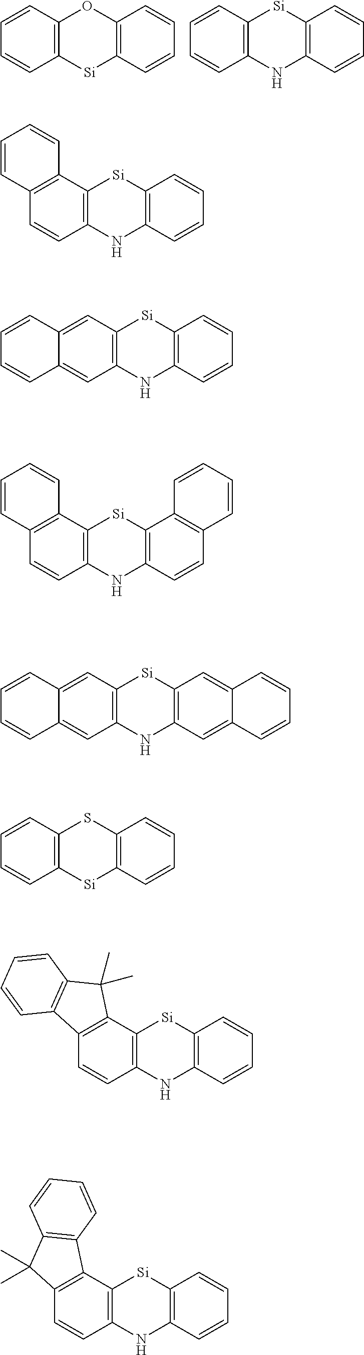

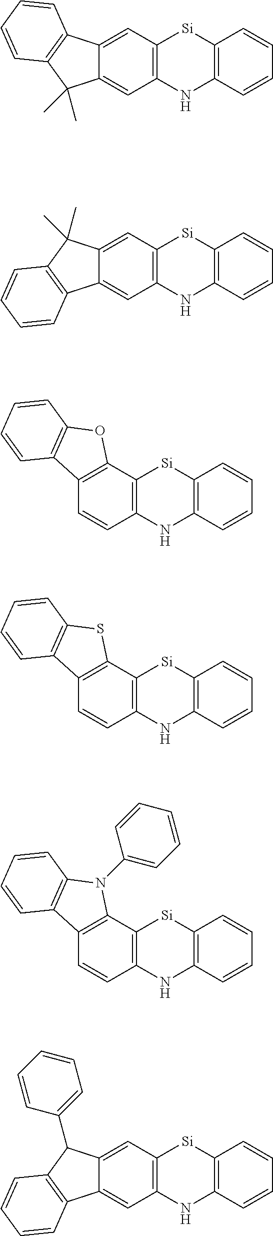

According to compounds of the general formulas (1)-(7), at least one of L₁, L₂, Ar₃, and Ar₄ contains one electron-donating group, and at least one of L₁, L₂, Ar₃, and Ar₄ contains one electron-accepting group.

In one embodiment, the electron-donating group contains the following groups:

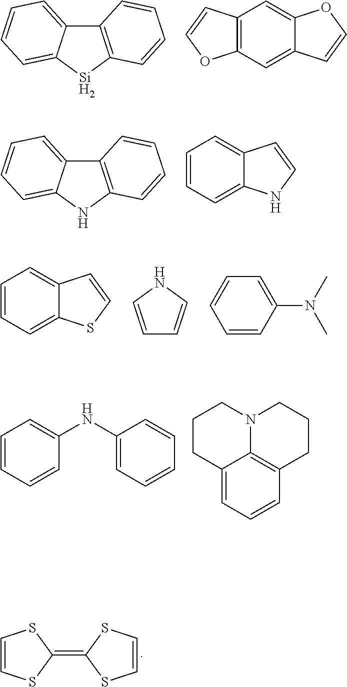

In one embodiment, the electron-accepting group is selected from the group consisting of F and cyano, or contains the following groups:

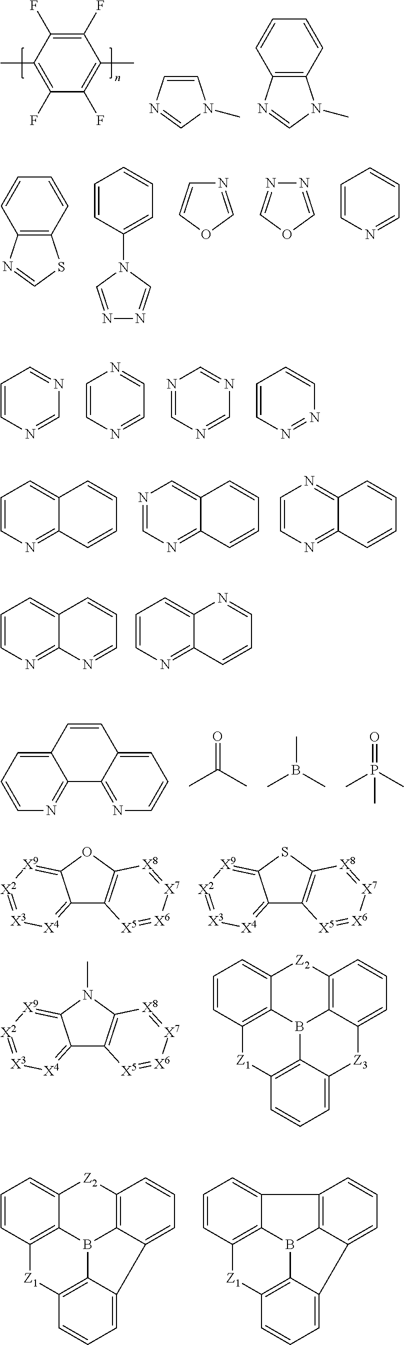

where n is an integer selecting from 1 to 3. X² to X⁹ is selected from CR or N, and at least one of X² to X⁹ is N. Z₁, Z₂, and Z₃ independently represent N(R), C(R)₂, Si(R)₂, O, C═N(R), C═C(R)₂, P(R), P(═O)R, S, S═O, or SO₂. R is selected from the group consisting of: hydrogen, alkyl, alkoxy, amino, alkenyl, alkynyl, aralkyl, heteroalkyl, aryl, and heteroaryl.

The silicon-containing organic compound of the present embodiment is a small molecule material.

The term “small molecule” as defined herein refers to a molecule that is not a polymer, oligomer, dendrimer, or blend. In particular, there is no repetitive structure in small molecules. The small molecule has a molecular weight less than or equal to 4000 g/mol. In one embodiment, the molecular weight is less than or equal to 3000 g/mol. In another embodiment, the molecular weight is less than or equal to 2000 g/mol. In yet another embodiment, the molecular weight is less than or equal to 1500 g/mol.

Polymer includes homopolymer, copolymer, and block copolymer. In addition, in the present embodiment, the polymer also includes dendrimer. The synthesis and application of the dendrimers are described in Dendrimers and Dendrons, Wiley-VCH Verlag GmbH & Co. KGaA, 2002, Ed. George R. Newkome, Charles N. Moorefield, Fritz Vogtle.

Conjugated polymer is also a type of polymers whose backbone is mainly composed of the sp² hybrid orbital of carbon (C) atom, such as polyacetylene and poly(phenylene vinylene). The C atom on the backbone thereof can also be substituted by other non-C atoms, and it is still considered to be a conjugated polymer when the sp² hybridization on the backbone is interrupted by some natural defects. In addition, in the present embodiment, the conjugated polymer further includes aryl amine, aryl phosphine and other heteroarmotics, organometallic complexes, and the like.

The tetrahedral structure of the silicon atom on the silicon-containing organic compound units of the general formulas (1) to (7) has a large steric hindrance, such that the molecules have a strong rigidity, and the solubility of the organic small molecule compound is ensured. If there are other substituents, these substituents can also improve solubility.

The silicon-containing organic compounds according to the general formulas (1) to (7) facilitate adjustment of various functions suitable for organic functional compounds. They can be used as host materials for small molecule compounds or as emitters. In particular, the photoelectric characteristics of the compounds can be determined by the substituents L₁ or L₂ or Ar³ or Ar⁴. The substituents Ar₁ and Ar₂, as well as X and Y can also affect the electronic characteristics of the compounds according to the general formulas (1) to (7).

Non-limiting examples of silicon-containing organic compounds according to formulas (1)-(7) are the following structures. These structures can also be substituted at all possible substitution positions.

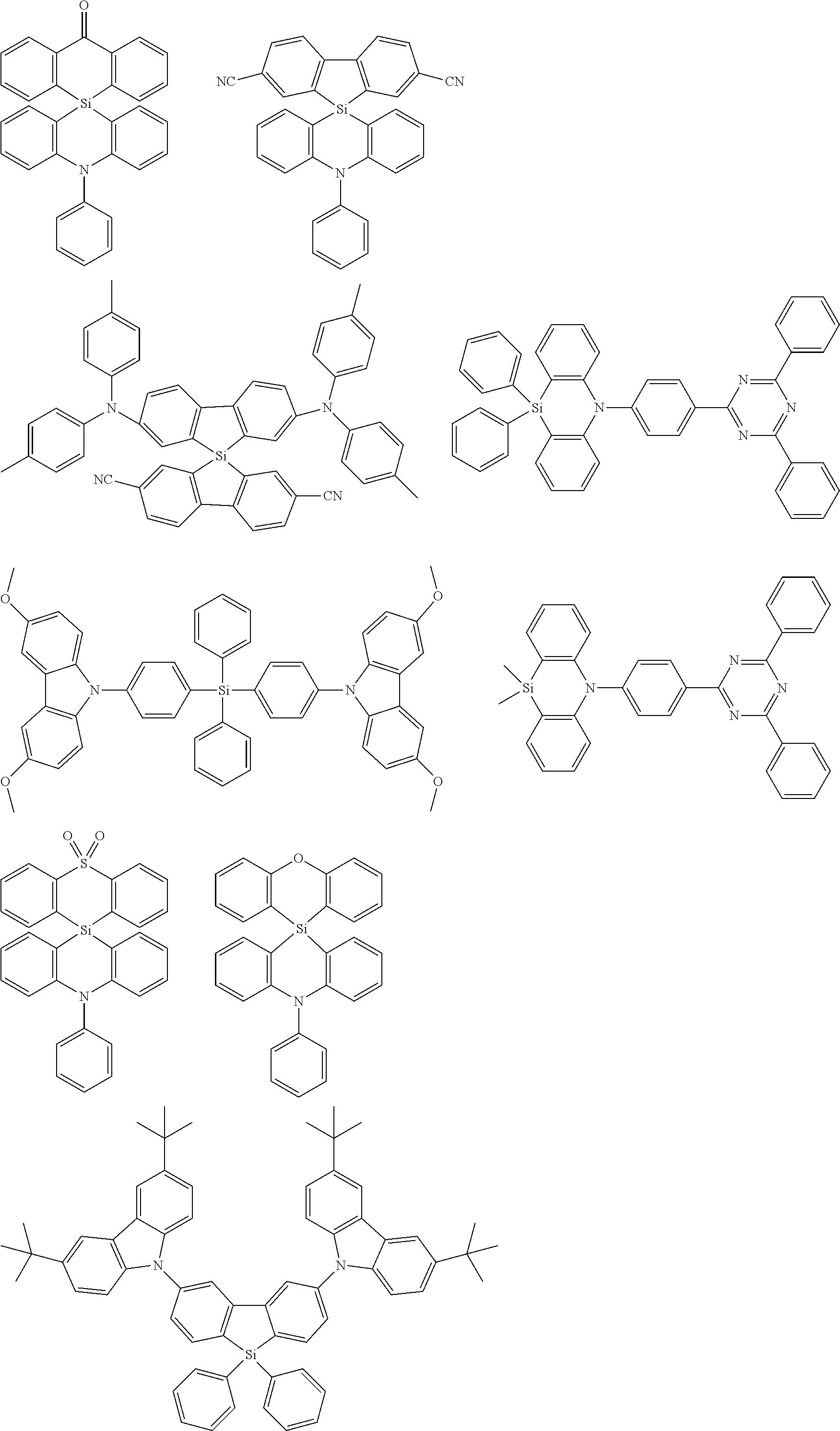

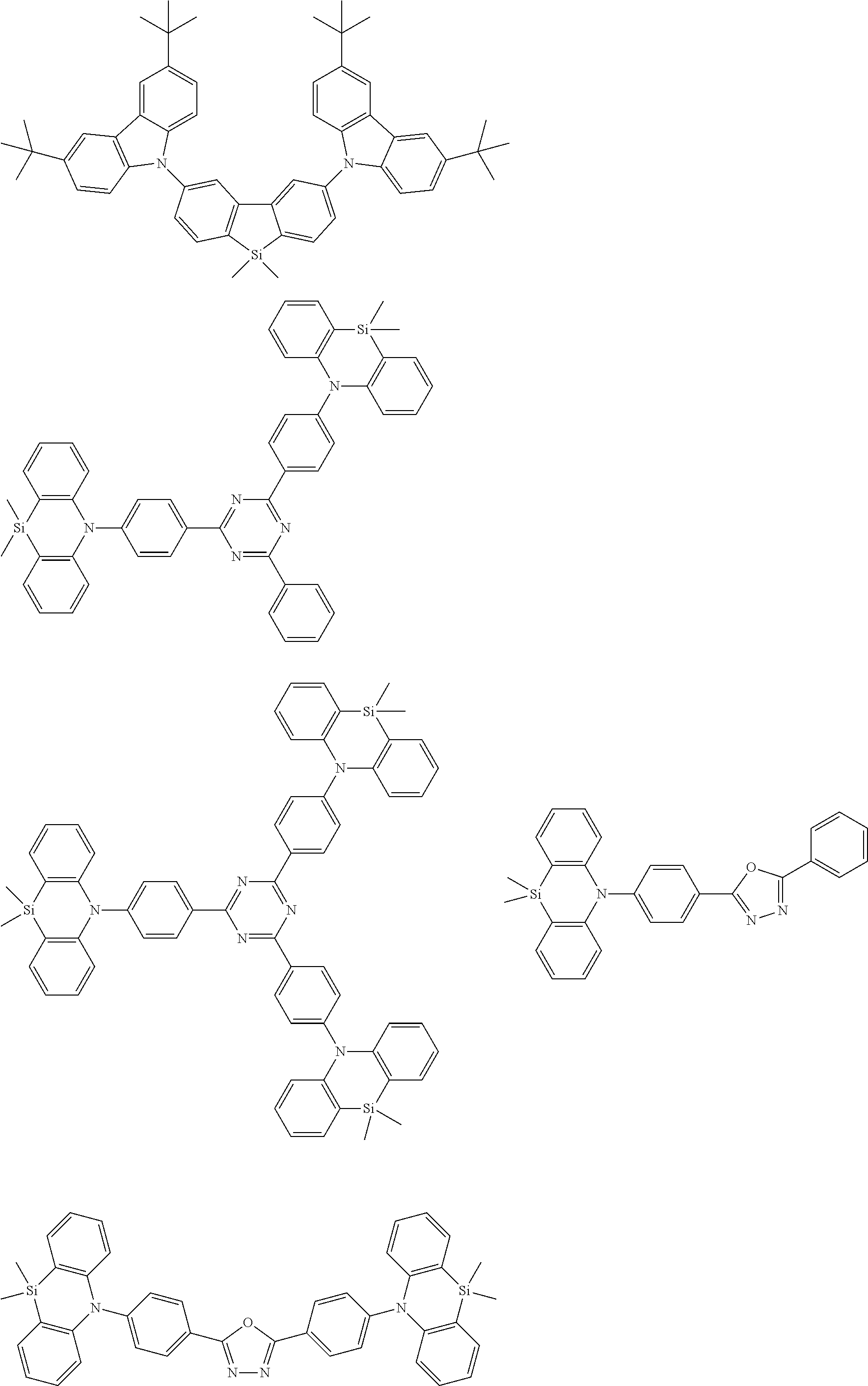

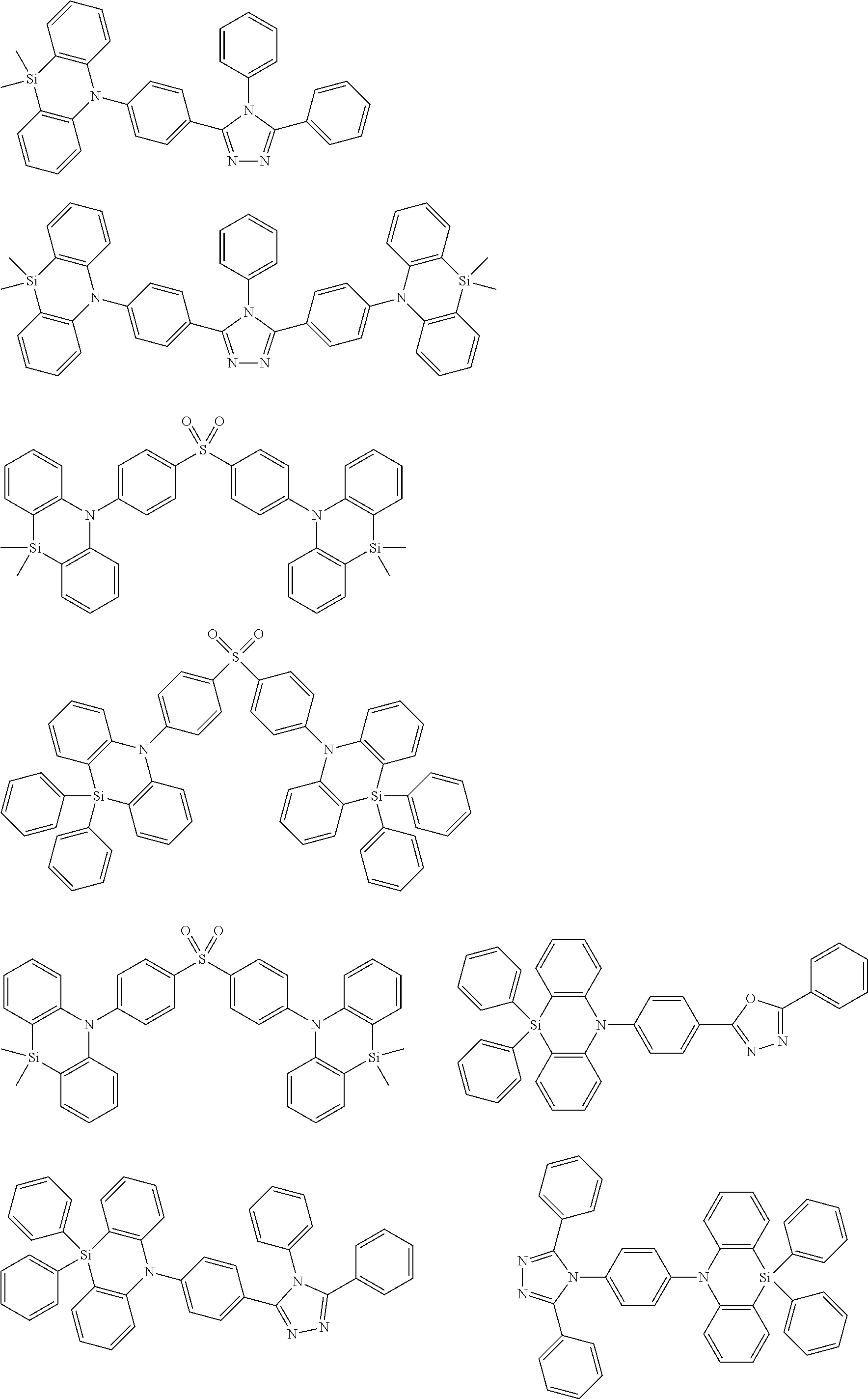

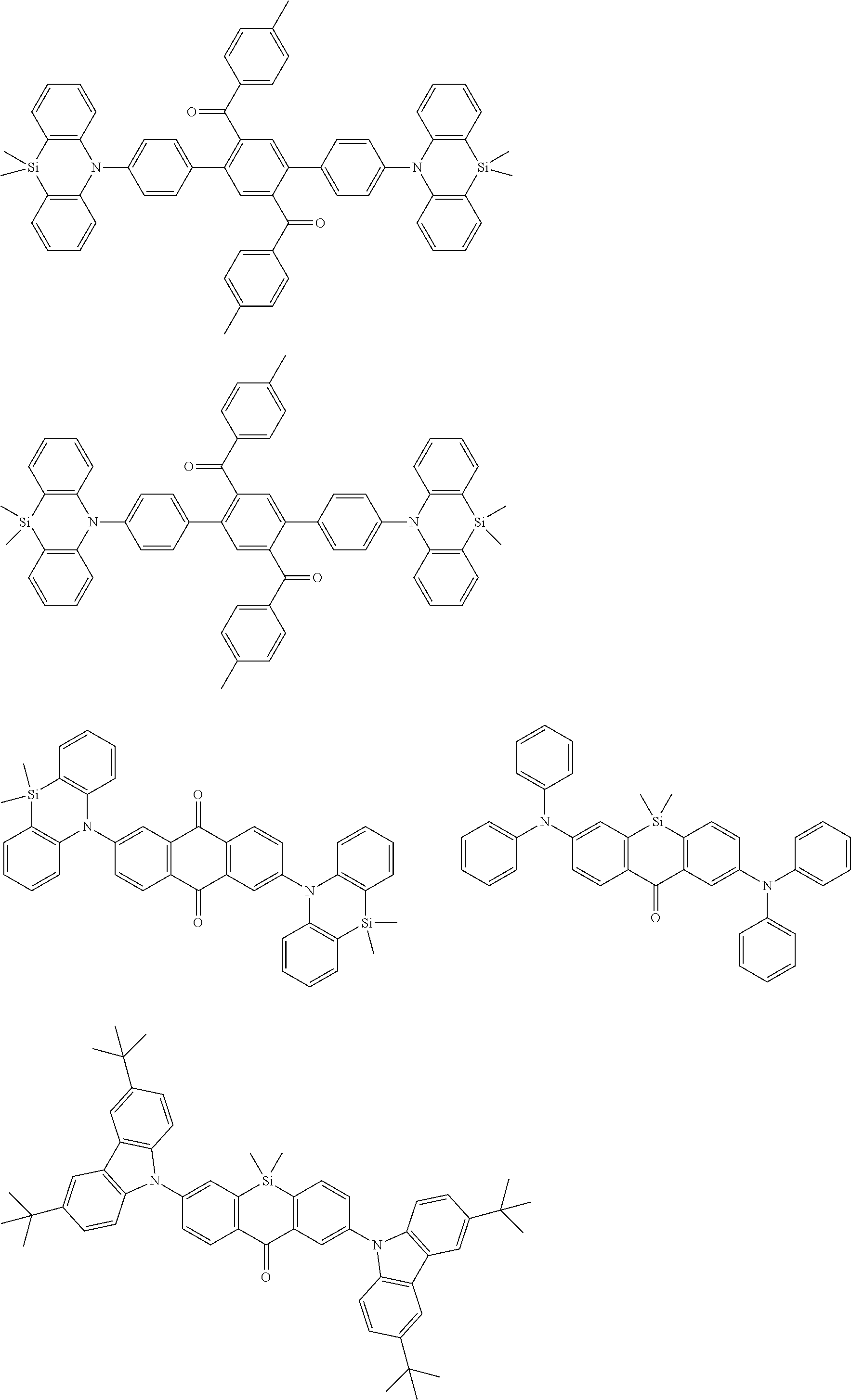

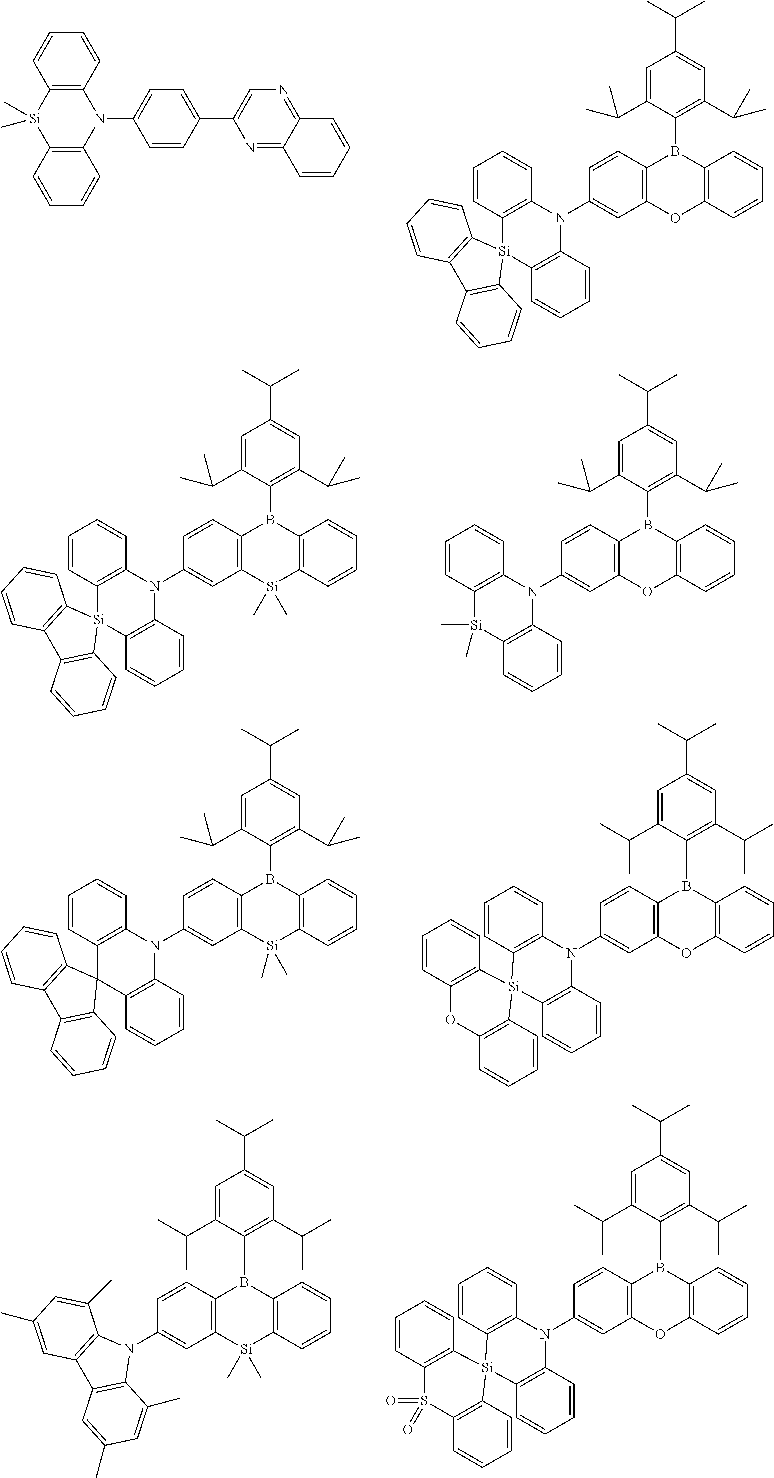

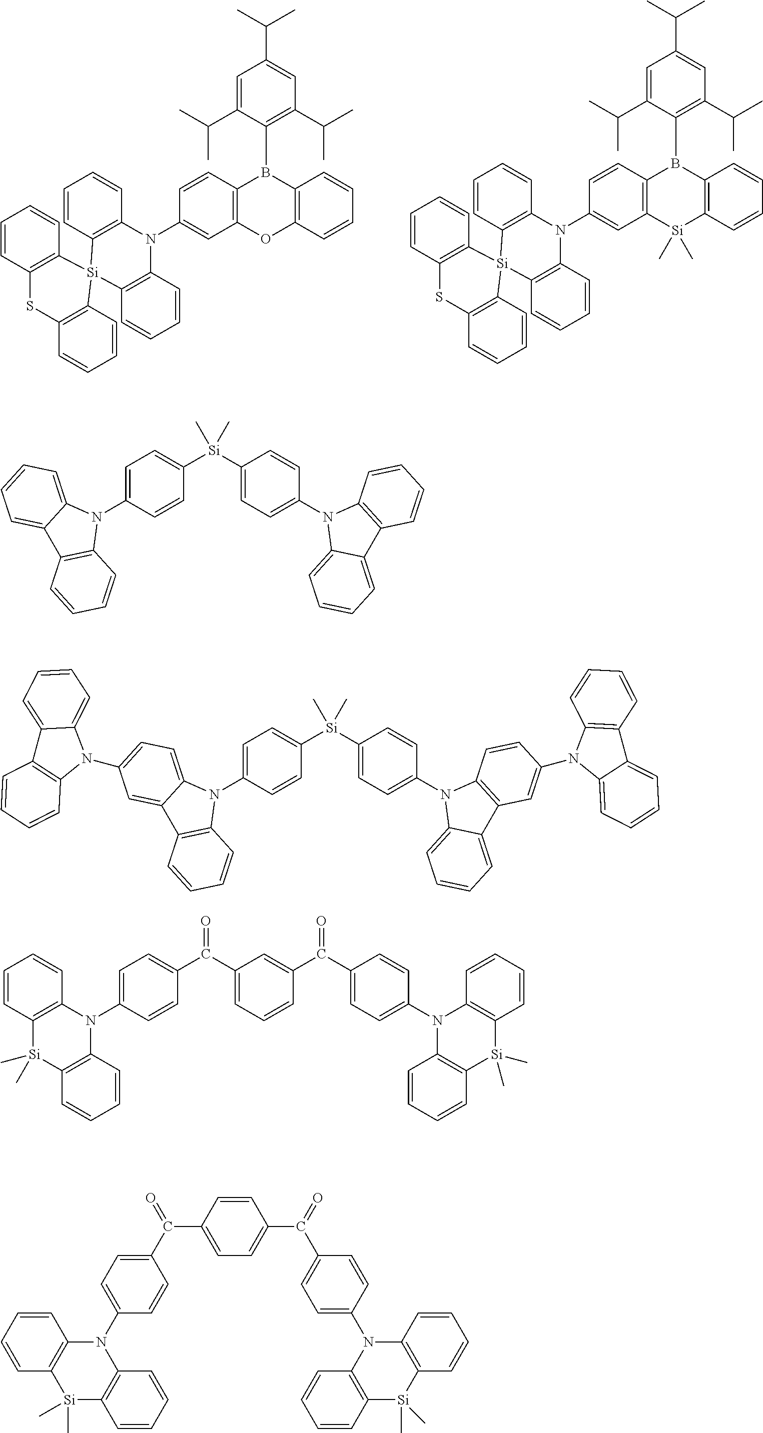

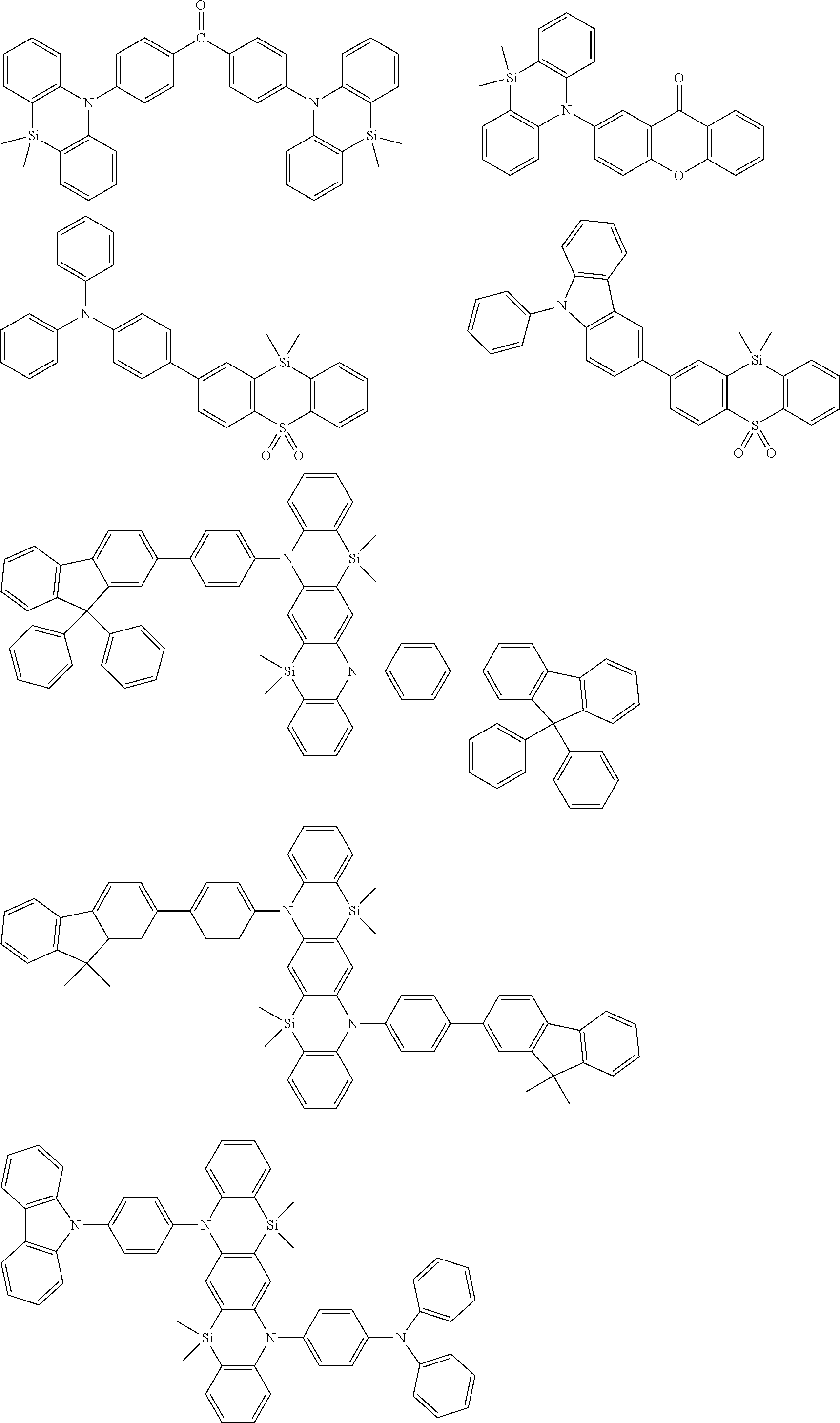

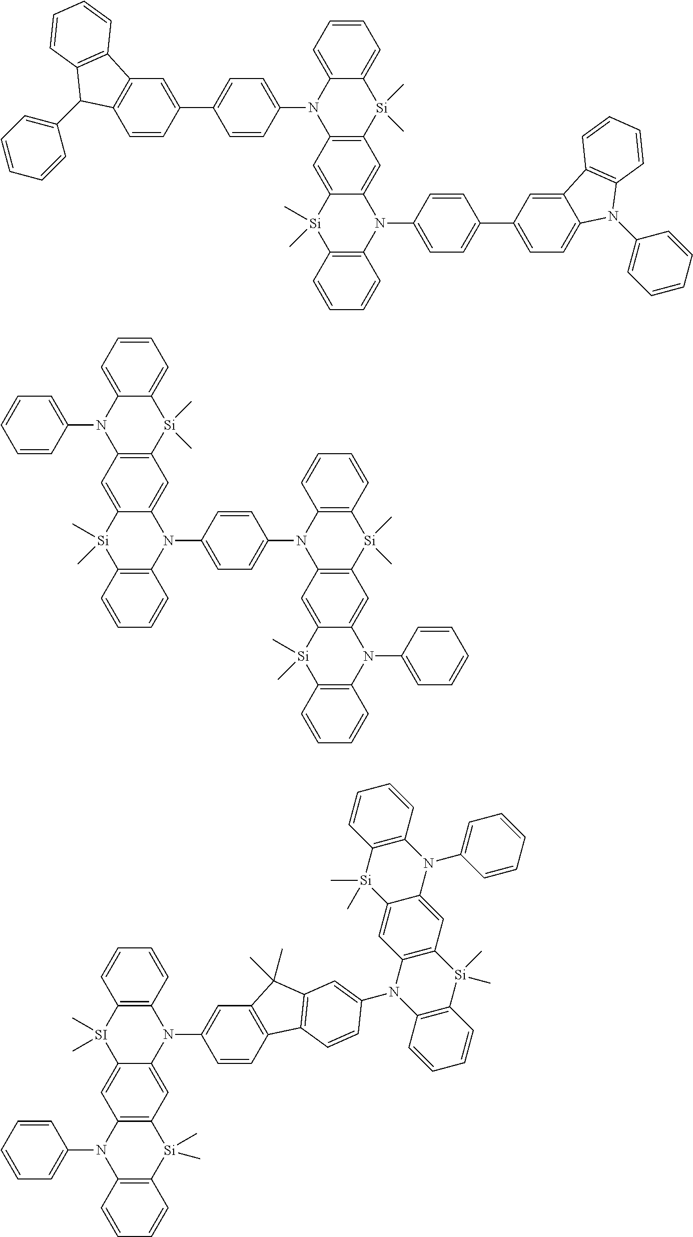

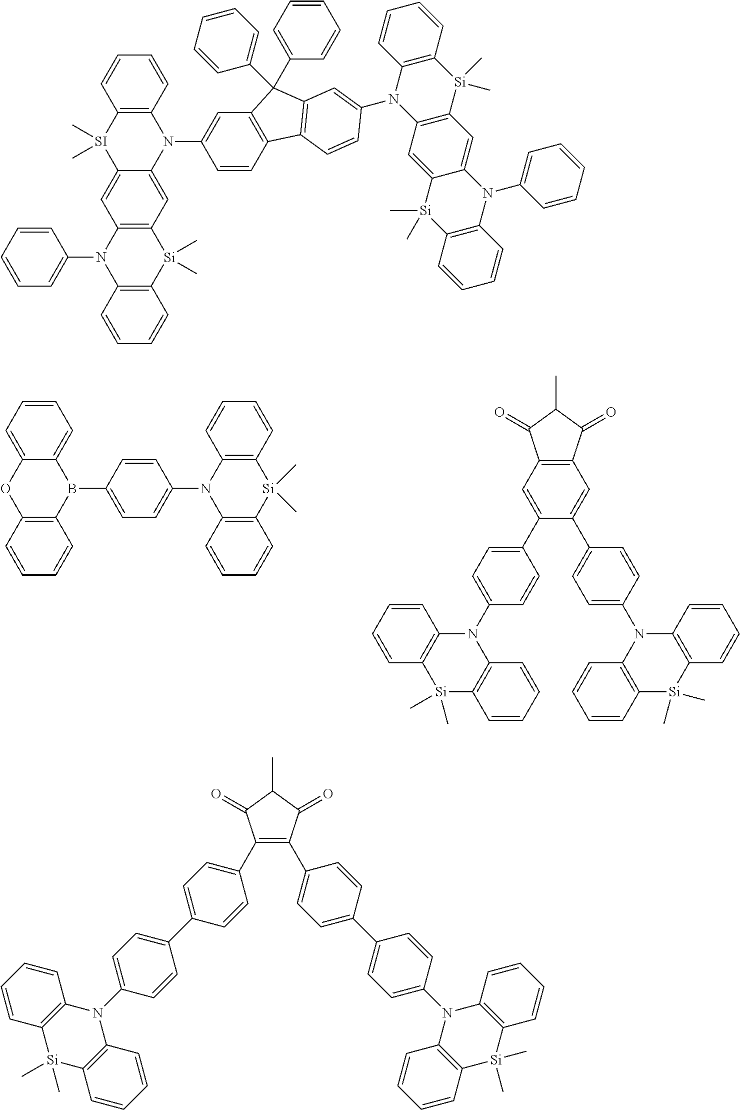

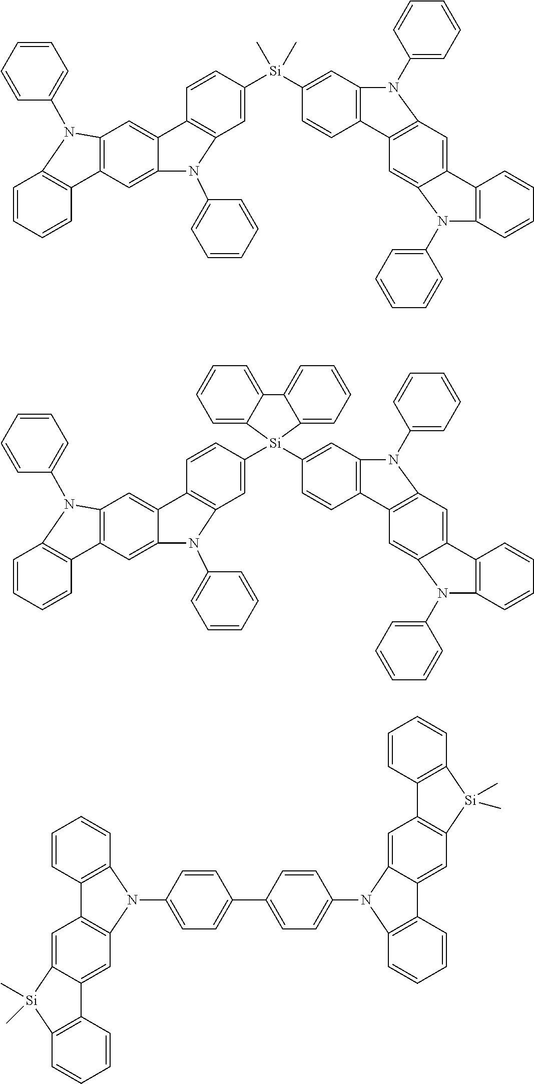

The present embodiment also provides a silicon-containing organic polymer, which has a plurality of repetitive units of the aforementioned silicon-containing organic compound. The silicon-containing organic polymer may be a non-conjugated polymer, in which the structural units represented by the general formulas (1) to (7) are on the side chains. The silicon-containing organic polymer can also be a conjugated polymer.

A silicon-containing mixture is further provided according to the present embodiment, which includes the aforementioned silicon-containing organic compound and/or the silicon-containing organic polymer, and an organic functional material. The organic functional material is at least one selected from the group consisting of hole injection materials (HIM), hole transport materials (HTM), electron transport materials (ETM), electron injection materials (EIM), electron blocking materials (EBM), hole blocking materials (HBM), emitters (singlet emitter such as fluorescent emitters and multiplet emitters such as phosphorescent emitters), organic thermally activated delayed fluorescence materials (TADF materials), host materials (Host), and organic dyes. Organic functional materials can be small molecules and polymer materials.

The silicon-containing mixture can include the aforementioned silicon-containing organic compound and/or the silicon-containing organic polymer, as well as a phosphorescent emitter. The silicon-containing organic compound and/or the silicon-containing organic polymer can serve as a host, and the weight percentage of the phosphorescent emitter in the silicon-containing mixture is less than or equal to 30 wt %. In one embodiment, the weight percentage in the silicon-containing mixture is less than or equal to 25 wt %. In another embodiment, the weight percentage in the silicon-containing mixture is less than or equal to 20 wt %.

The silicon-containing mixture can include the aforementioned silicon-containing organic compound and/or the silicon-containing organic polymer, as well as a host material. The silicon-containing organic compound and/or the silicon-containing organic polymer can serve as a light-emitting material, and the weight percentage thereof is less than or equal to 25 wt %. In one embodiment, the weight percentage is less than or equal to 20 wt %. In another embodiment, the weight percentage is less than or equal to 15 wt %. In yet another embodiment, the weight percentage is less than or equal to 10 wt %.

The silicon-containing mixture can include the aforementioned silicon-containing organic compound and/or the silicon-containing organic polymer, as well as the phosphorescent emitter and the host material. In one embodiment, the silicon-containing organic compound and/or the silicon-containing organic polymer can serve as an auxiliary light-emitting material, and a weight ratio between the auxiliary light-emitting material and the phosphorescent emitter is 1:2 to 2:1. In addition, in another embodiment, T₁ of the silicon-containing organic compound and/or the silicon-containing organic polymer is greater than T₁ of the phosphorescent emitter.

The silicon-containing mixture can further include the aforementioned silicon-containing organic compound and/or the silicon-containing organic polymer, as well as another TADF material.

The host material, the phosphorescent material, and the TADF material are described in further detail below, but are not limited thereto.

1. Host Material (Host).

Examples of a triplet host material (Triplet Host) are not particularly limited and any metal complex or organic compound can be used as the host material as long as its triplet energy is greater than that of the emitter, especially the triplet emitter or phosphorescent emitter. Examples of metal complexes that may be used as triplet hosts may include, but are not limited to, the general structure as follows:

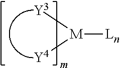

where M is a metal; (Y³-Y⁴) is a bidentate ligand, Y³ and Y⁴ are independently selected from C, N, O, P, or S; L is an auxiliary ligand; m is an integer with the value from 1 to the maximum coordination number of the metal; and m+n is the maximum number of coordination of the metal.

In one embodiment, the metal complex which can be used as the triplet host has the following formula:

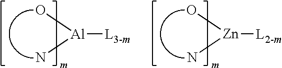

(O—N) is a bidentate ligand, in which the metal is coordinated to O and N atoms.

In alternative embodiments, M may also be selected from Ir and Pt.

Examples of organic compounds that can be used as triplet host material are selected from compounds containing cyclic aryl, such as benzene, biphenyl, triphenyl, benzo, and fluorene; compounds containing heterocyclic aryl, such as dibenzothiophene, dibenzofuran, dibenzoselenophen, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, oxazole, bibenzoxazole, benzisoxazole, benzothiazole, quinoline, isoquinoline, cinnoline, quinazoline, quinoxaline, naphthalene, phthalein, pteridine, xanthene, acridine, phenazine, phenothiazine, phenoxazine, benzofuropyridine, furopyridine, benzothienopyridine, thienopyridine, benzoselenophenopyridine, and selenophenobenzodipyridine; and groups containing 2 to 10 ring atom structures, which may be the same or different types of cyclic aryl or heterocyclic aryl and are linked to each other directly or by at least one of the following groups, such as oxygen atom, nitrogen atom, sulfur atom, silicon atom, phosphorus atom, boron atom, chain structural unit, and aliphatic ring group. Each ring atom may be further substituted and the substituents may be selected from the group consisting of hydrogen, alkyl, alkoxy, amino, alkenyl, alkynyl, aralkyl, heteroalkyl, aryl, and heteroaryl.

In one embodiment, the triplet host material may be selected from compounds containing at least one of the following groups:

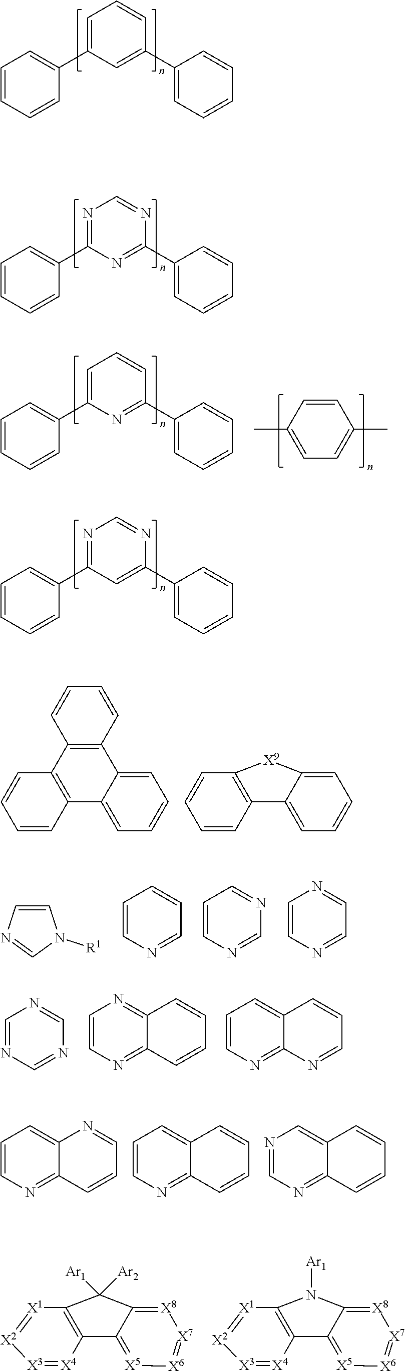

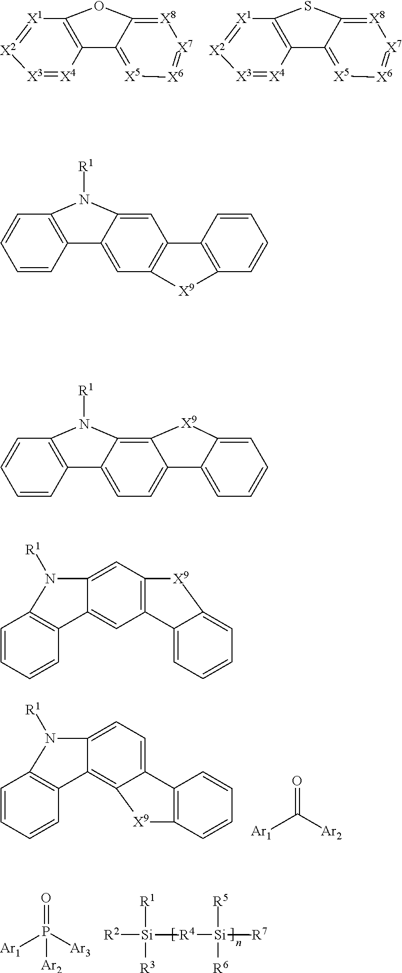

R¹-R⁷ can be independently selected from the group consisting of hydrogen, alkyl, alkoxy, amino, alkenyl, alkynyl, aralkyl, heteroalkyl, aryl, and heteroaryl, which have the same meaning as the aforementioned Ar₁, Ar₂, and Ar₃ when R¹-R⁷ are selected from aryl or heteroaryl. n is an integer from 0 to 20; X¹ to X⁸ is selected from CH or N; and X⁹ is selected from CR¹R² or NR¹.

Examples of triplet host materials are as follows:

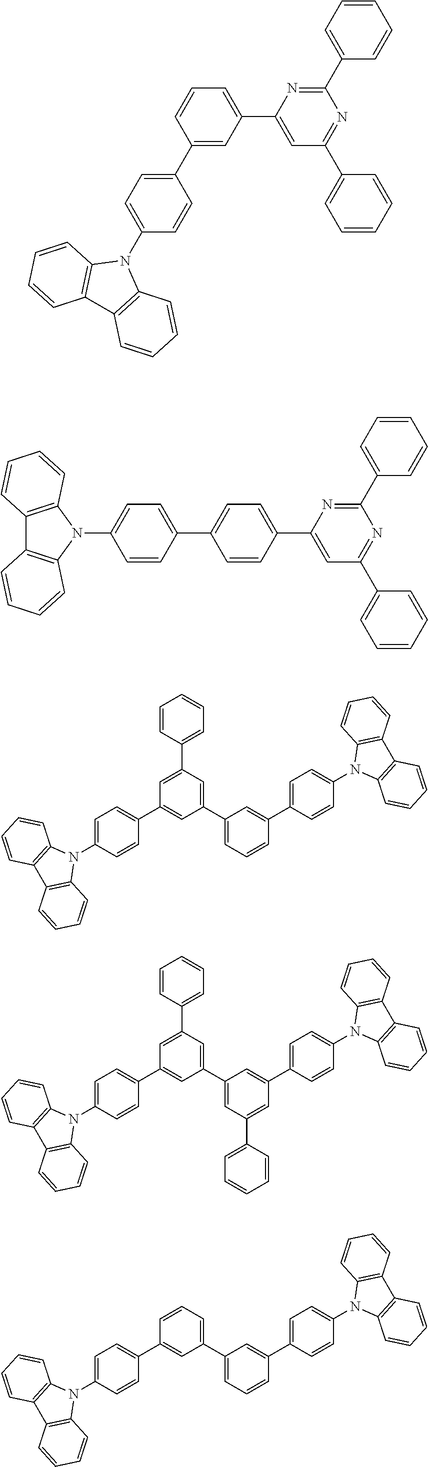 [SMILES: c1ccc(-c2cc(-c3cccc(-c4ccc(-n5c6ccccc6c6ccccc65)cc4)c3)nc(-c3ccccc3)n2)cc1 ; c1ccc(-c2cc(-c3ccc(-c4ccc(-n5c6ccccc6c6ccccc65)cc4)cc3)nc(-c3ccccc3)n2)cc1 ; c1ccc(-c2cc(-c3ccc(-n4c5ccccc5c5ccccc54)cc3)cc(-c3cccc(-c4ccc(-n5c6ccccc6c6ccccc65)cc4)c3)c2)cc1 ; c1ccc(-c2cc(-c3ccc(-n4c5ccccc5c5ccccc54)cc3)cc(-c3cc(-c4ccccc4)cc(-c4ccc(-n5c6ccccc6c6ccccc65)cc4)c3)c2)cc1 ; c1cc(-c2ccc(-n3c4ccccc4c4ccccc43)cc2)cc(-c2cccc(-c3ccc(-n4c5ccccc5c5ccccc54)cc3)c2)c1]

2. Phosphorescent Materials.

The phosphorescent material is also called a triplet emitter. In one embodiment, the triplet emitter is a metal complex having a general formula M(L)ₙ, wherein M is a metal atom. L may be the same or different organic ligand in each occurrence, and is bonded or coordinated to the metal atom M at one or more positions. n is an integer greater than 1. In one embodiment, n is selected from 1, 2, 3, 4, 5 or 6. Optionally, these metal complexes are attached to one polymer by one or more positions. In one embodiment, these metal complexes are attached to the polymer by an organic ligand.

In one embodiment, the metal atom M is selected from the group consisting of transition metal elements, lanthanides, and actinides. In another embodiment, the metal atom M is selected from the group consisting of Ir, Pt, Pd, Au, Rh, Ru, Os, Sm, Eu, Gd, Tb, Dy, Re, Cu, and Ag. In yet another embodiment, the metal atom M is selected from the group consisting of Os, Ir, Ru, Rh, Re, Pd, and Pt.

In one embodiment, the triplet emitter includes a chelating ligand, i.e., a ligand, coordinated to the metal by at least two bonding sites. In another embodiment, the triplet emitter includes two or three identical or different bidentate or multidentate ligand. Chelating ligands help to improve stability of metal complexes.

Examples of organic ligands can be selected from the group consisting of phenylpyridine derivative, 7, 8-benzoquinoline derivative, 2(2-thienyl) pyridine derivative, 2(1-naphthyl) pyridine derivative, and 2 phenylquinoline derivative. All of these organic ligands can be substituted, for example, by fluoromethyl or trifluoromethyl. The auxiliary ligand may be selected from acetylacetonate or picric acid.

In one embodiment, the metal complex which can be used as the triplet emitter has the following form:

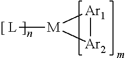

where M is a metal selected from the group consisting of transition metal elements, lanthanides, and actinides.

Ar₁ may be the same or different cyclic group in each occurrence, which includes at least one donor atom, i.e., an atom having a lone pair of electrons, such as nitrogen or phosphorus, through which the cyclic group is coordinated to the metal. Ar₂ may be the same or different cyclic group in each occurrence, which includes at least one C atom and through which the cyclic group is attached to the metal. Ar₁ and Ar₂ are covalently bonded together, and each of them may carry one or more substituents which may also be linked together by substituents. L may be the same or different in each occurrence and is an auxiliary ligand. In one embodiment, L is a bidentate chelating ligand. In another embodiment, L is a monoanionic bidentate chelating ligand. m is 1, 2 or 3. In one embodiment, m is 2 or 3. In another embodiment, m is 3. n is 0, 1, or 2. In one embodiment, n is 0 or 1. In another embodiment, n is 0.

Examples of triplet emitters are as follows:

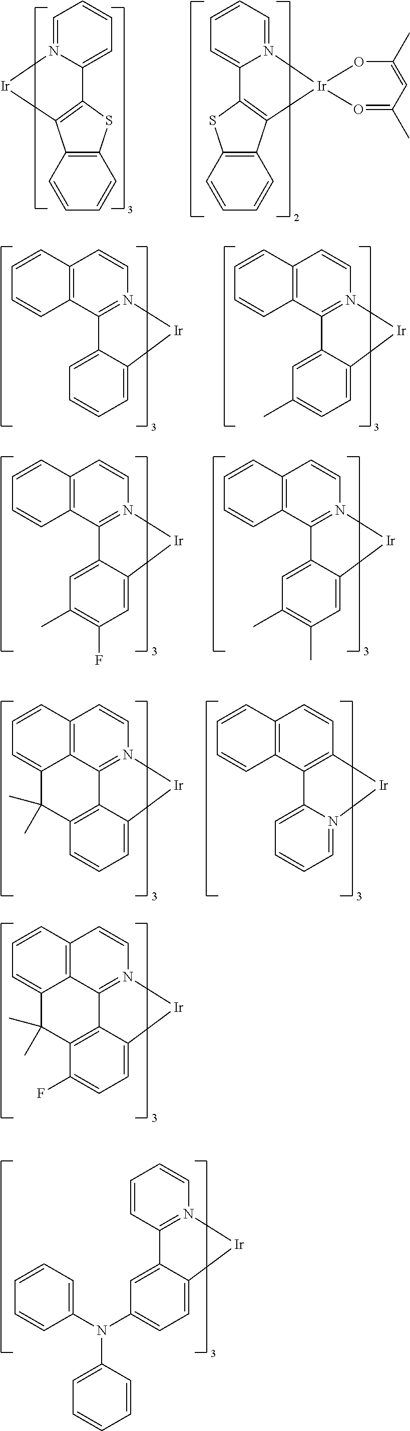

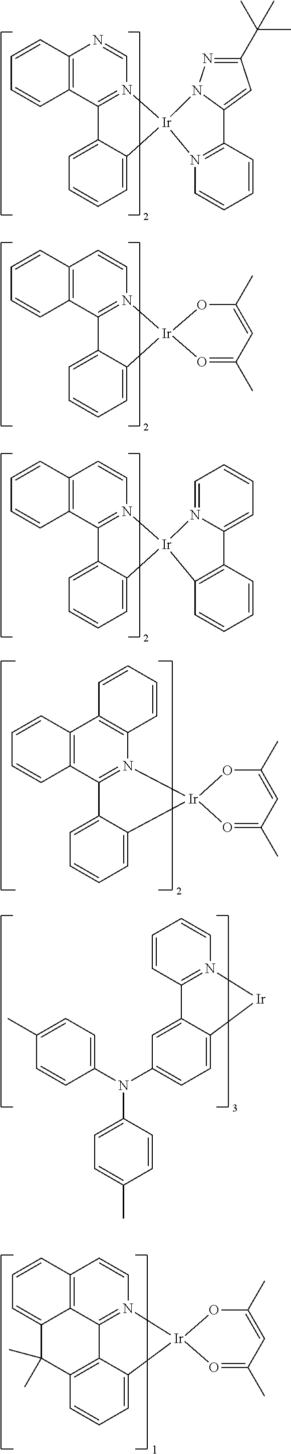

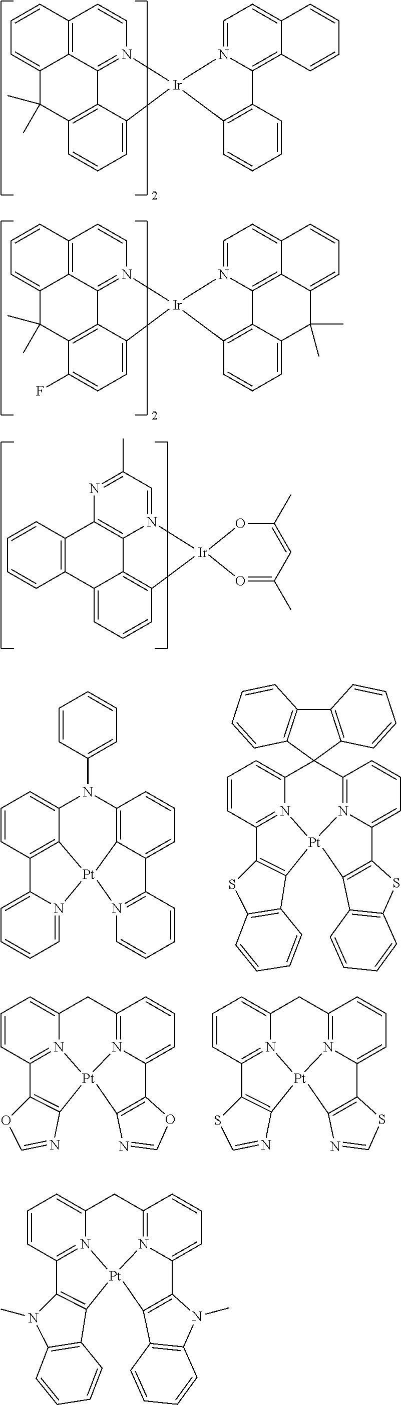

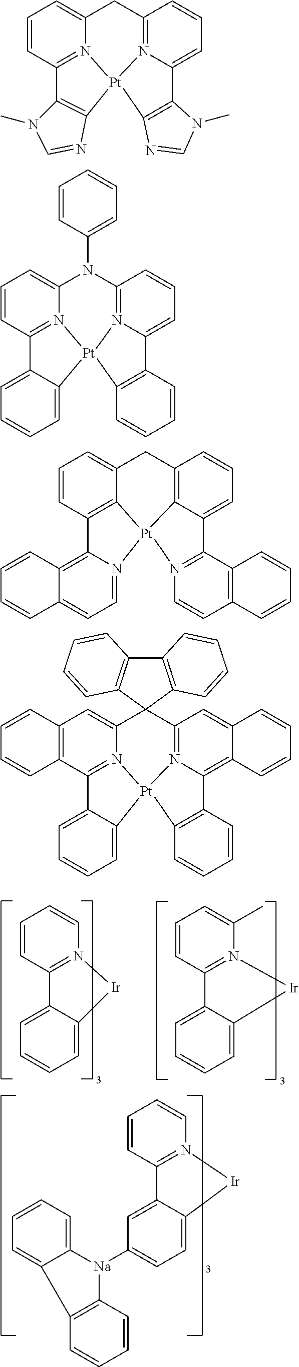

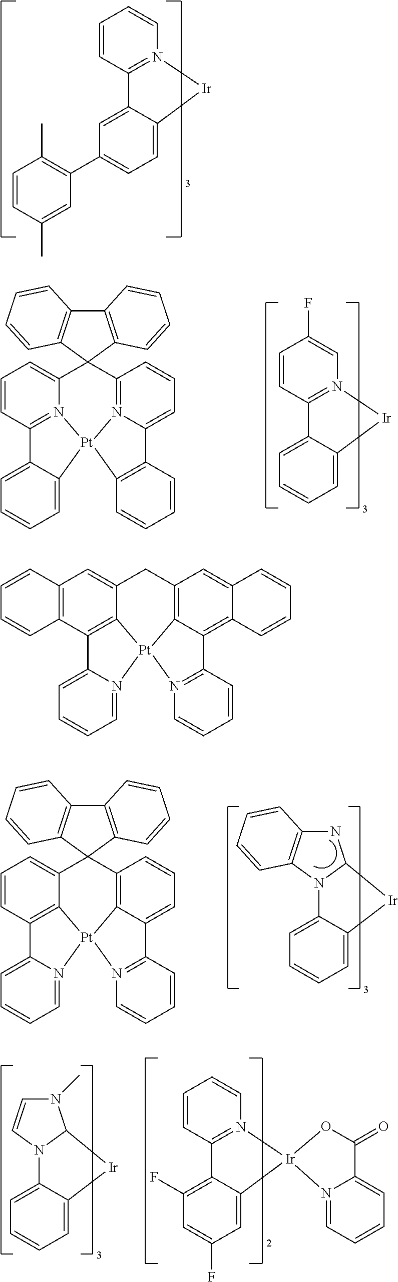

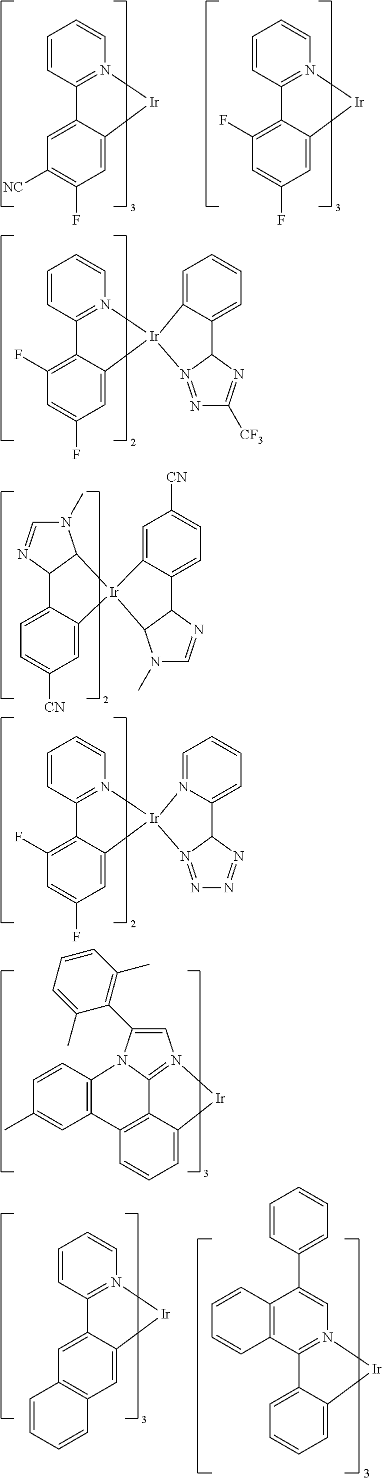

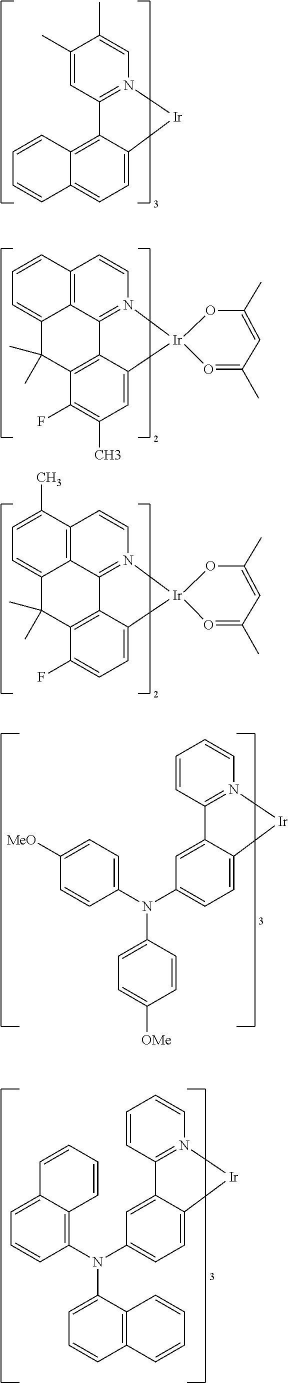

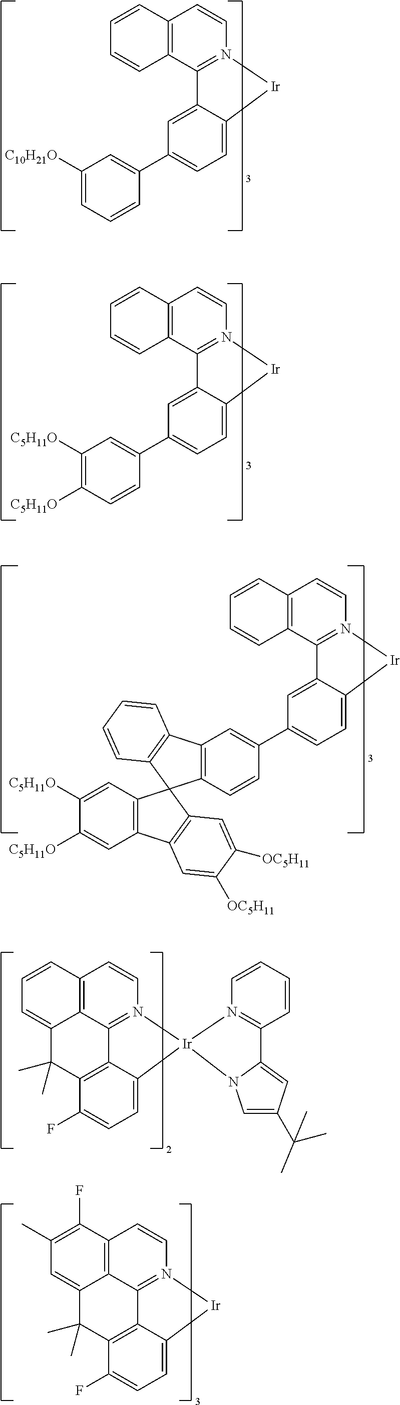

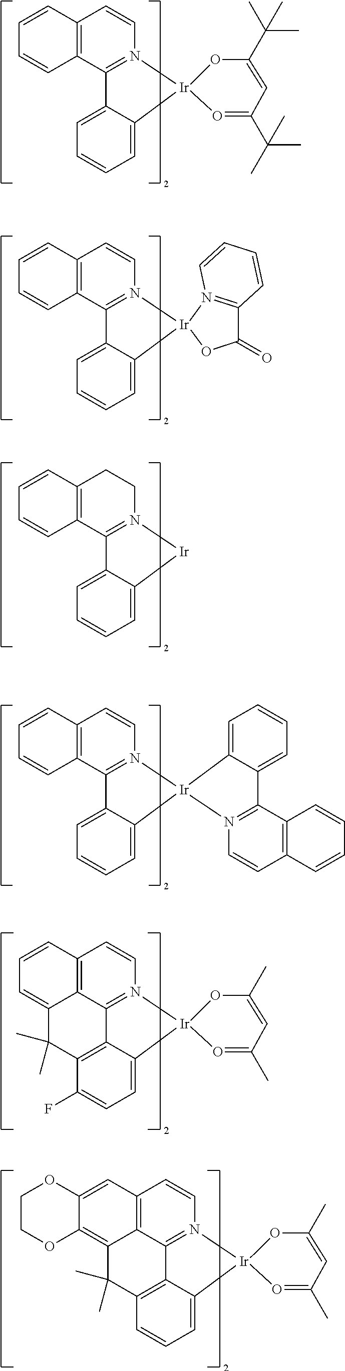

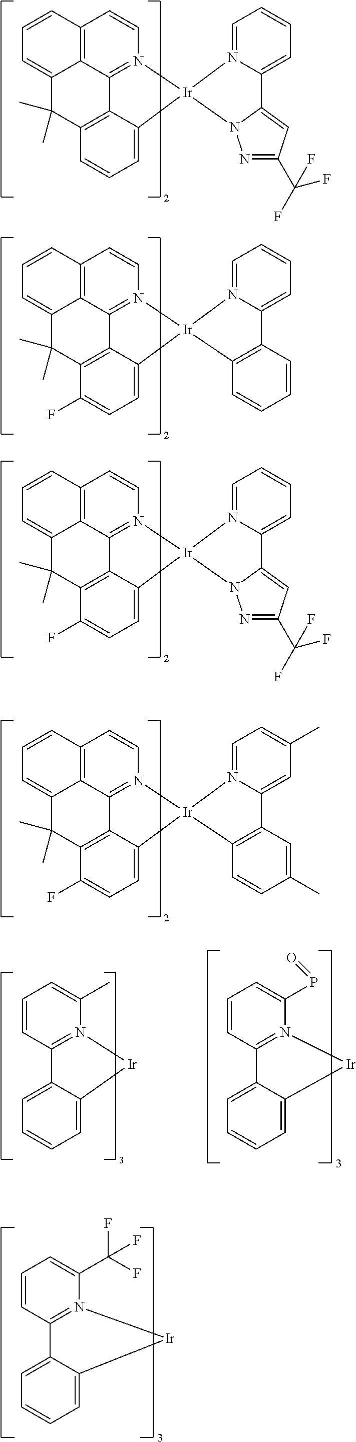

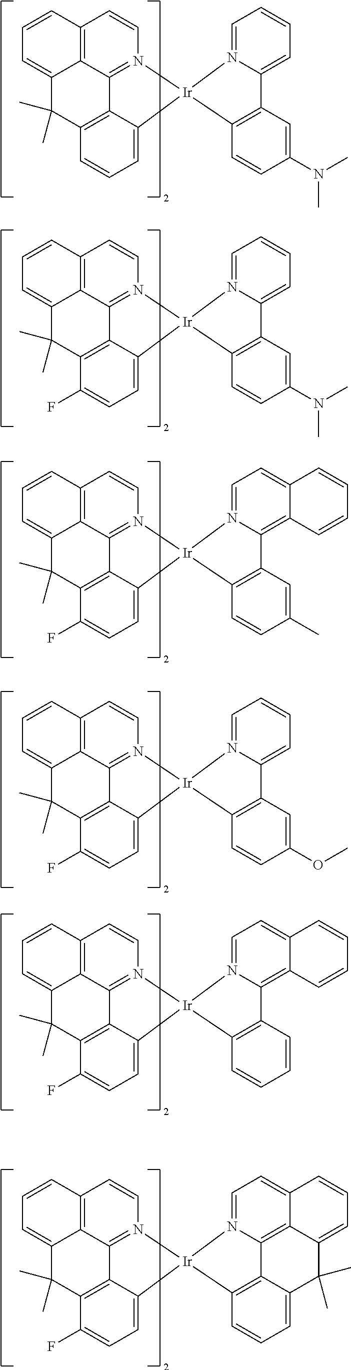

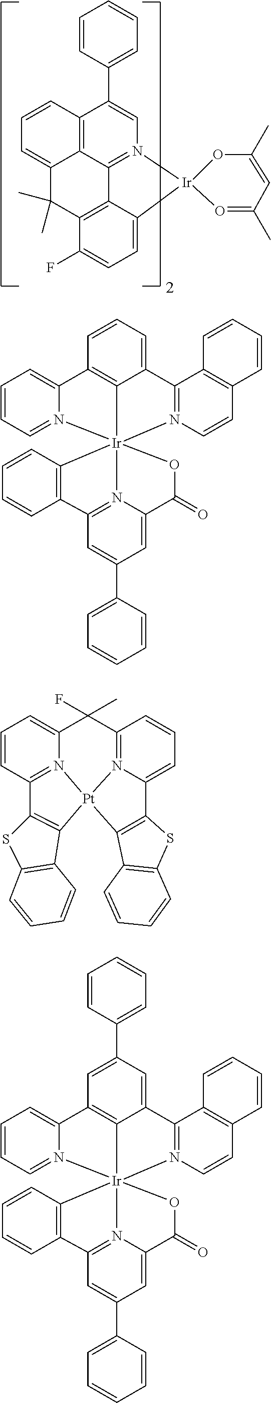

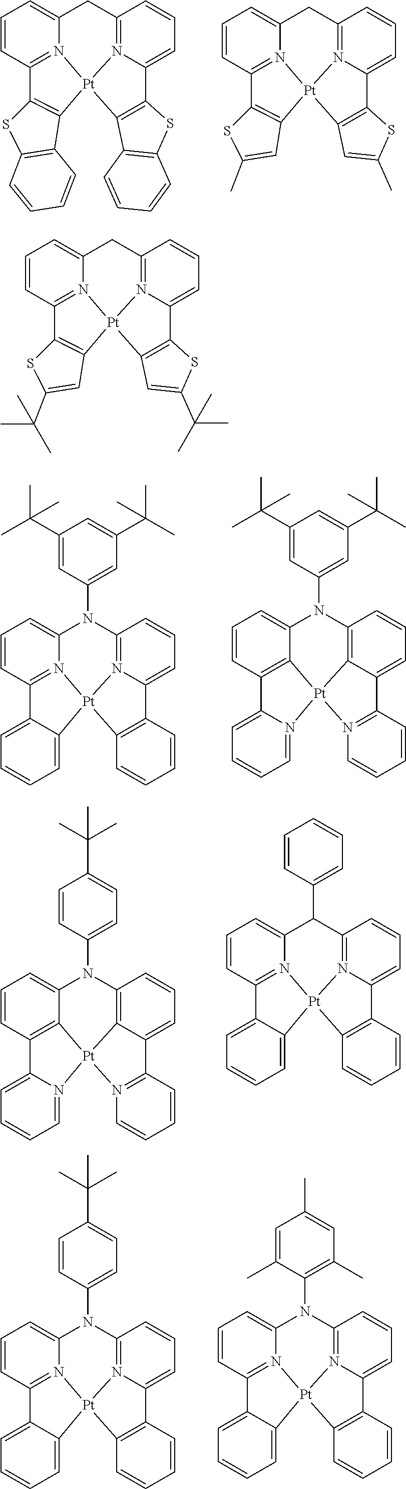

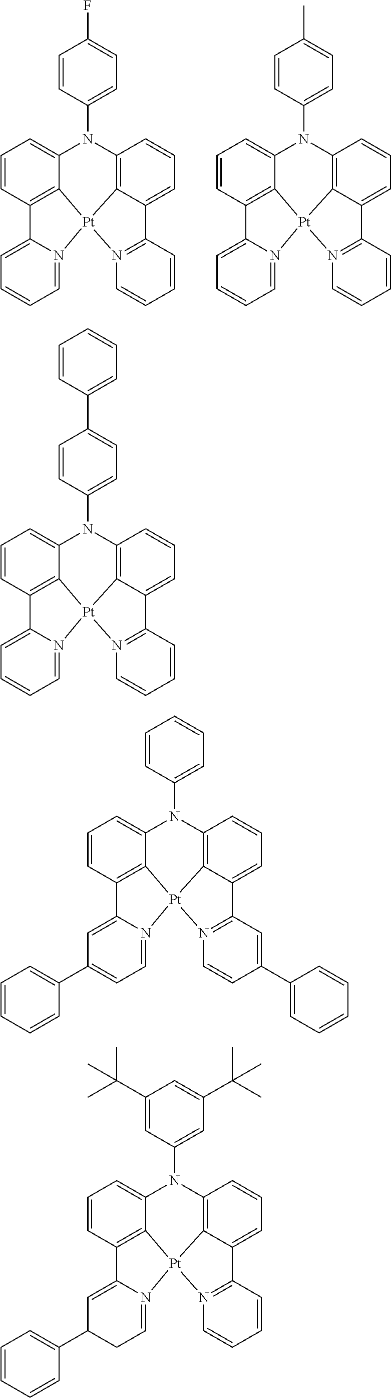

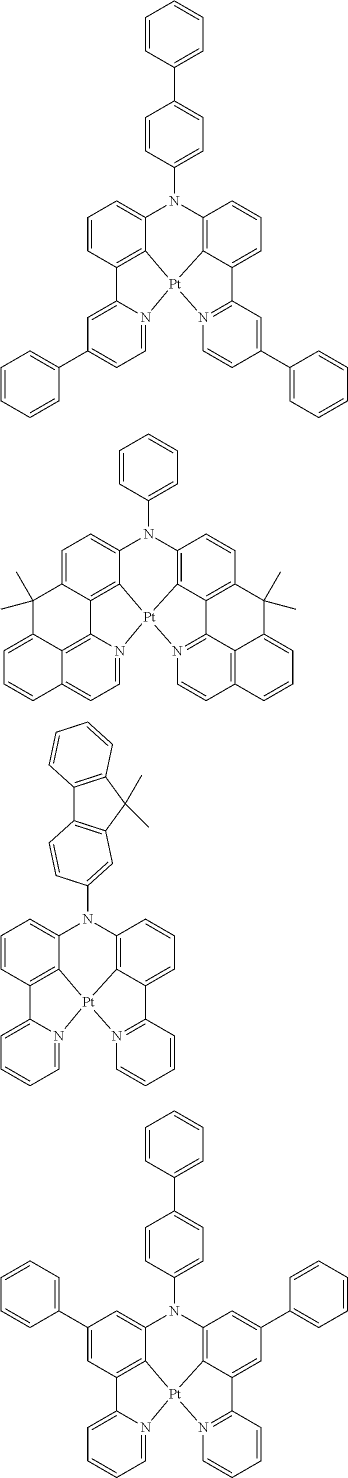

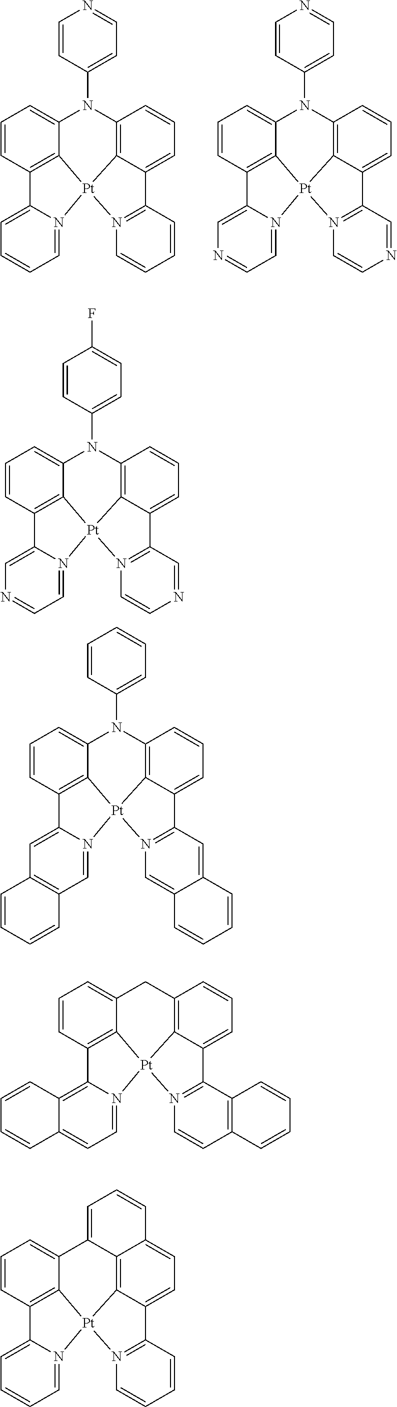

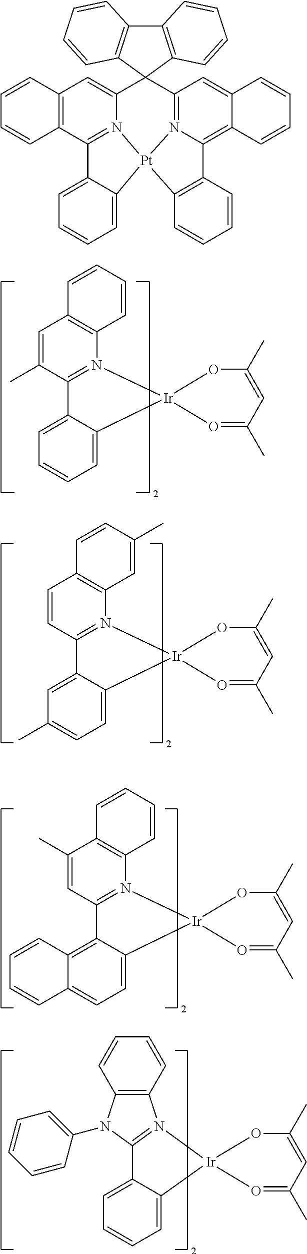

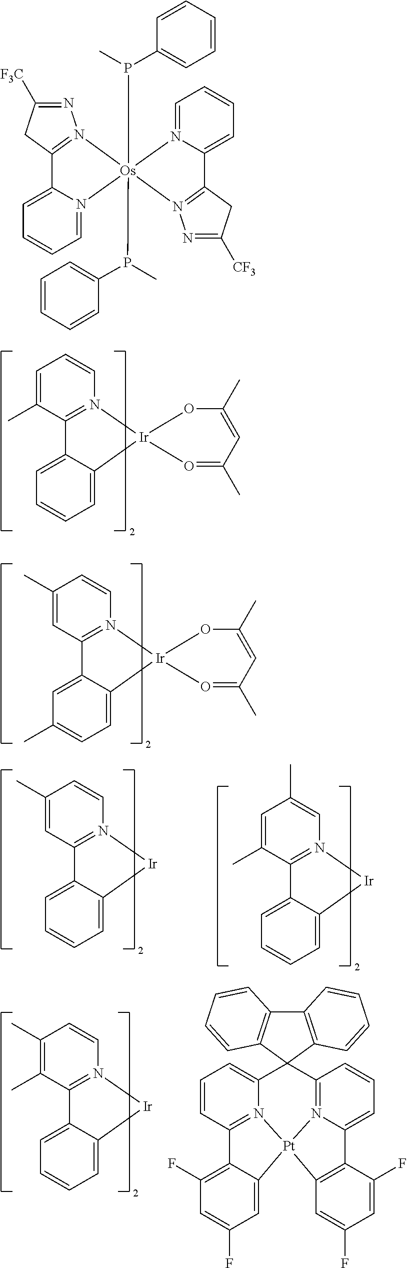

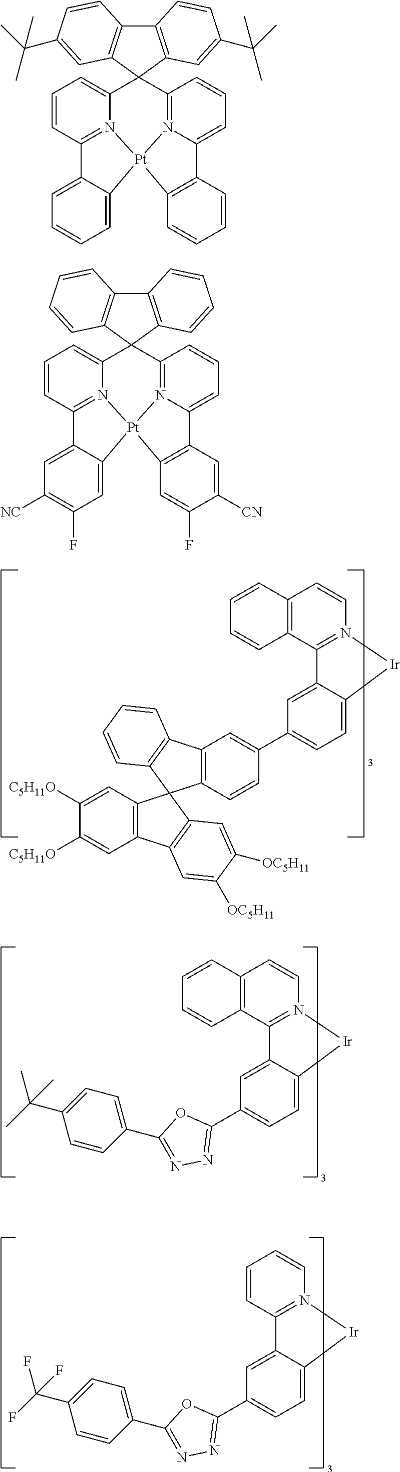

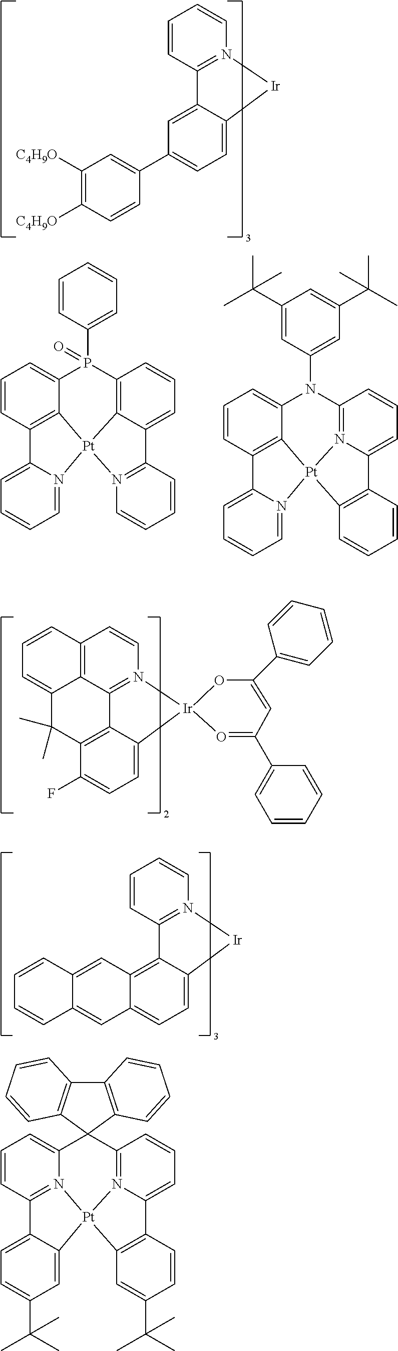

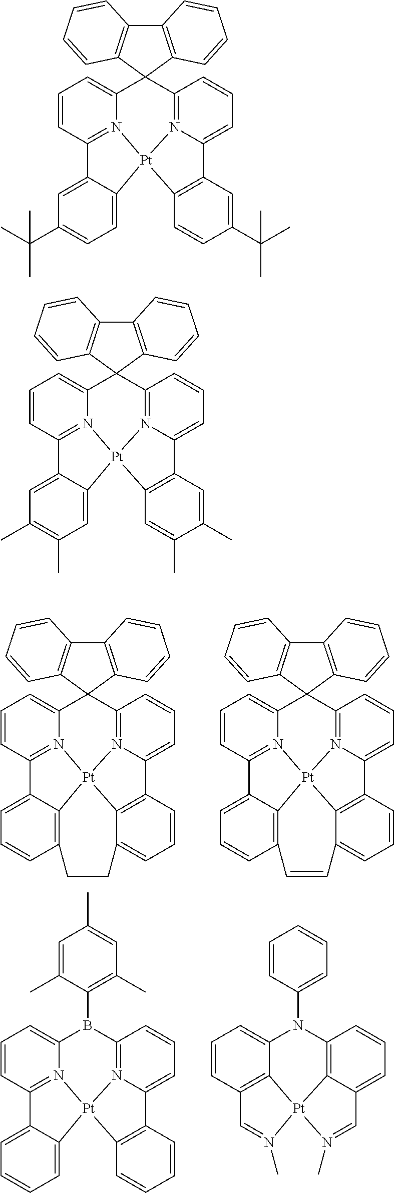

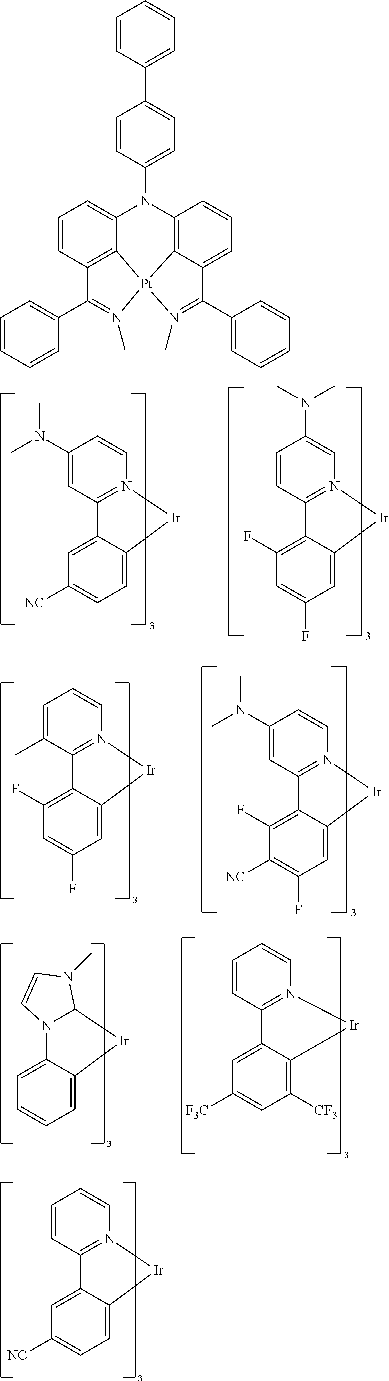

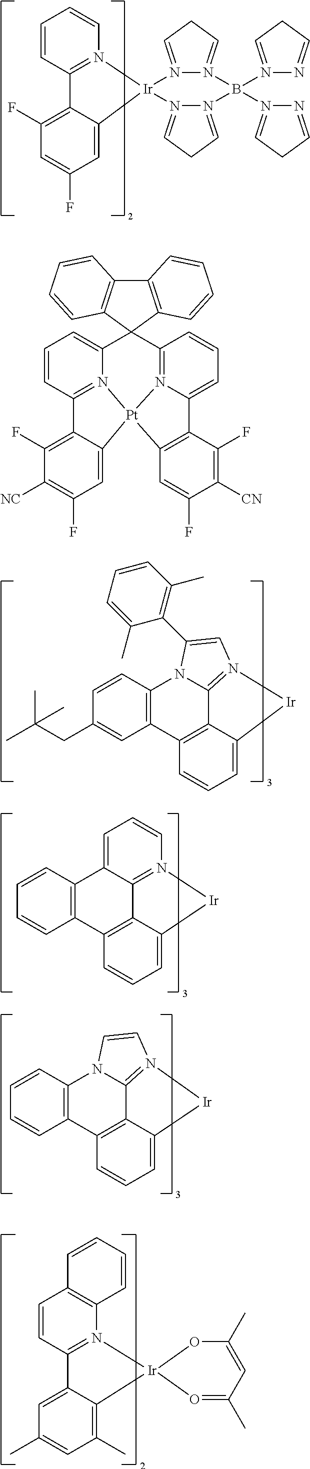

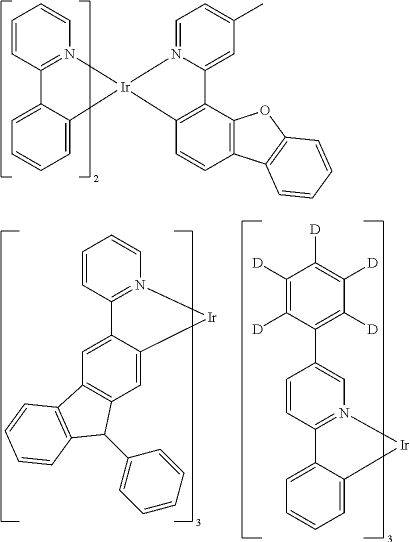

3. TADF Material.

The TADF material is required to have a small singlet-triplet energy level difference. In one embodiment, ΔEst is less than 0.3 eV. In another embodiment, ΔEst is less than 0.2 eV. In yet another embodiment, ΔEst is less than 0.1 eV. In one embodiment, the TADF material has a relatively small ΔEst. In another embodiment, the TADF has a good fluorescence quantum efficiency.

Examples of TADF light-emitting materials are as follows:

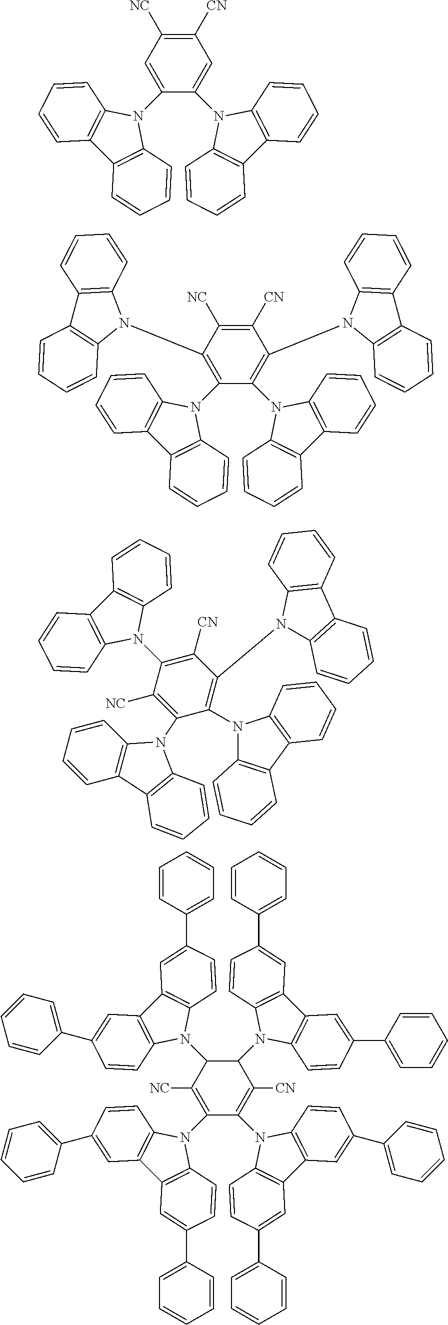

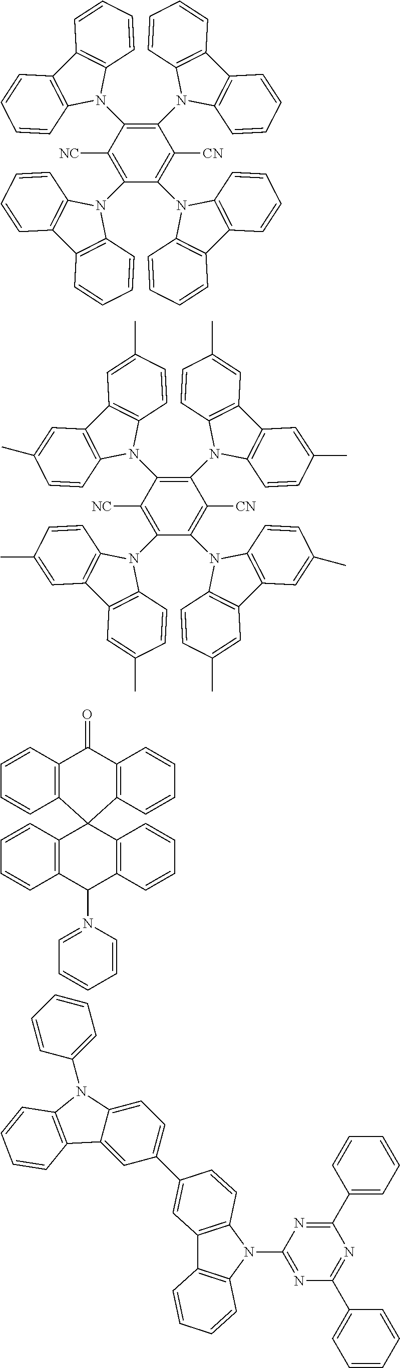

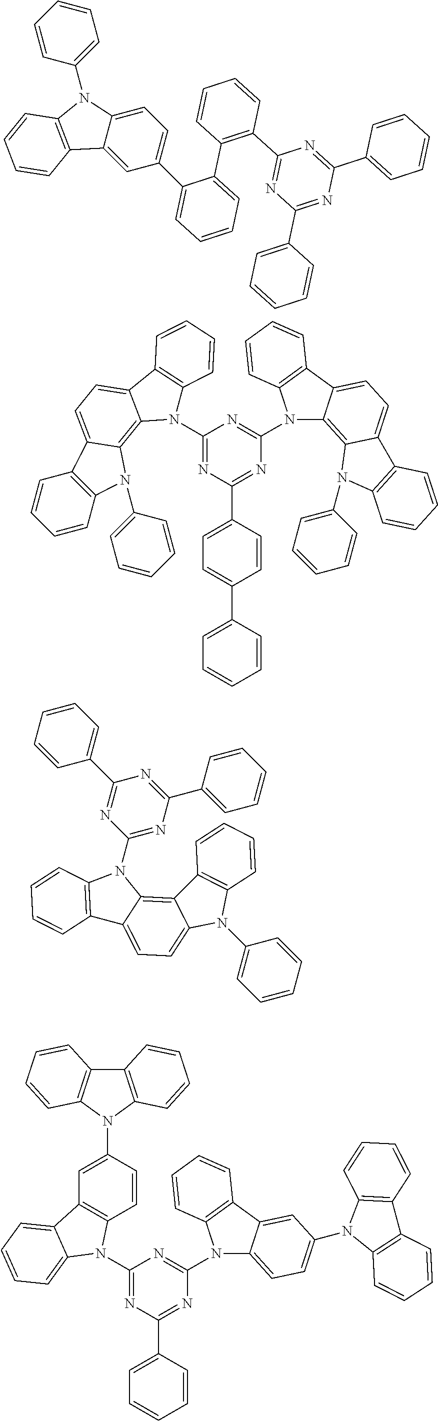

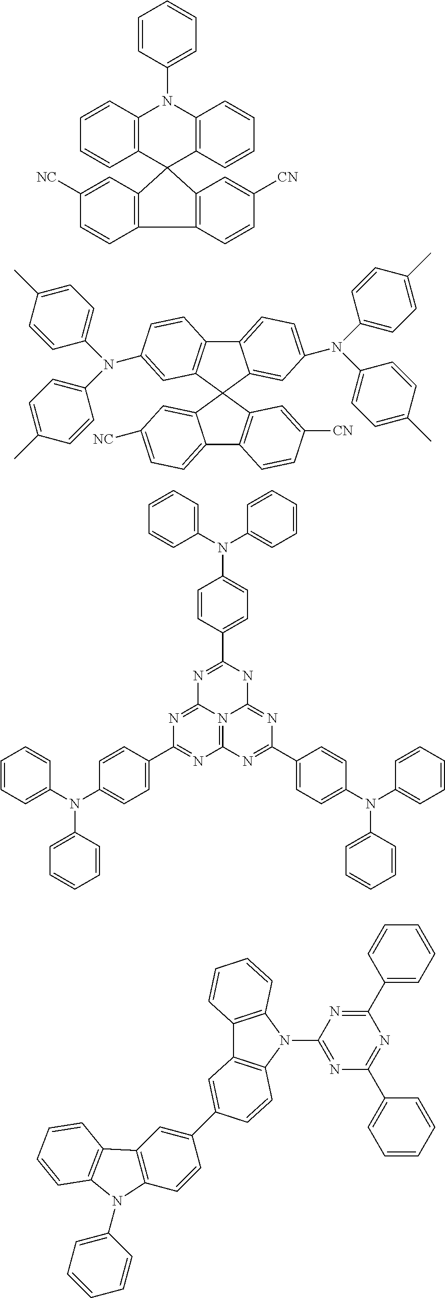

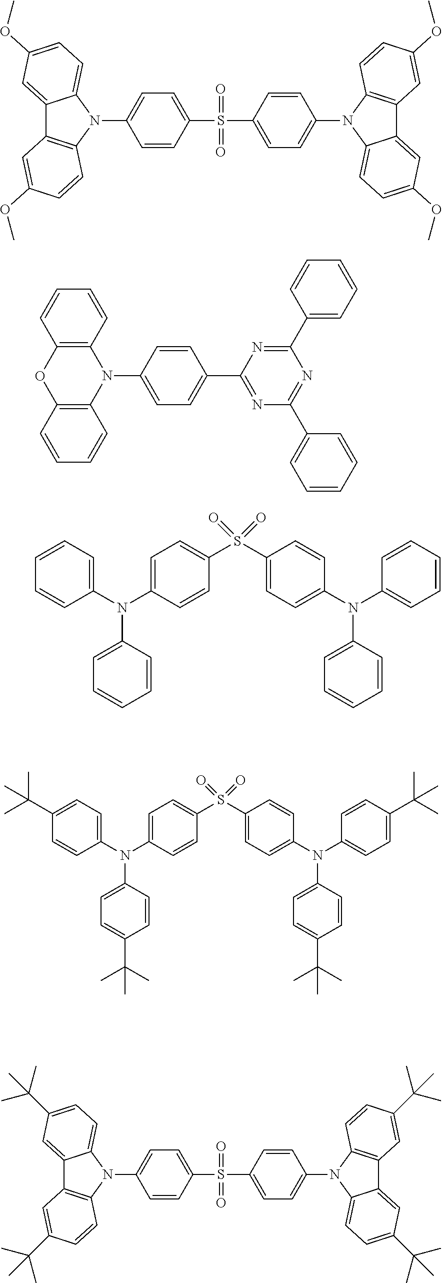

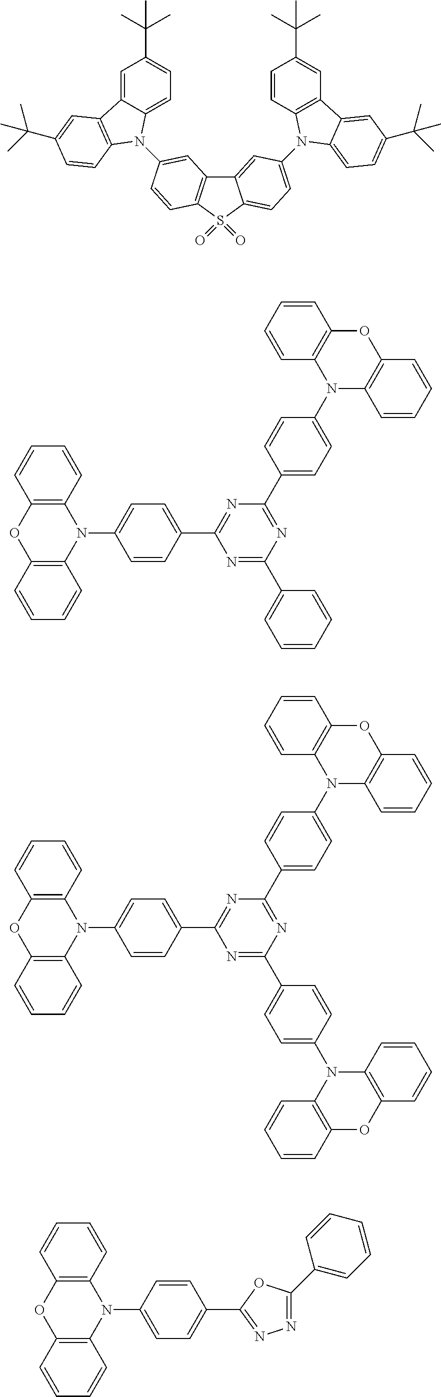 [SMILES: CC(C)(C)c1ccc2c(c1)c1cc(C(C)(C)C)ccc1n2-c1ccc2c(c1)-c1cc(-n3c4ccc(C(C)(C)C)cc4c4cc(C(C)(C)C)ccc43)ccc1S2(=O)=O ; c1ccc(-c2nc(-c3ccc(N4c5ccccc5Oc5ccccc54)cc3)nc(-c3ccc(N4c5ccccc5Oc5ccccc54)cc3)n2)cc1 ; c1ccc2c(c1)Oc1ccccc1N2c1ccc(-c2nc(-c3ccc(N4c5ccccc5Oc5ccccc54)cc3)nc(-c3ccc(N4c5ccccc5Oc5ccccc54)cc3)n2)cc1 ; c1ccc(-c2nnc(-c3ccc(N4c5ccccc5Oc5ccccc54)cc3)o2)cc1]

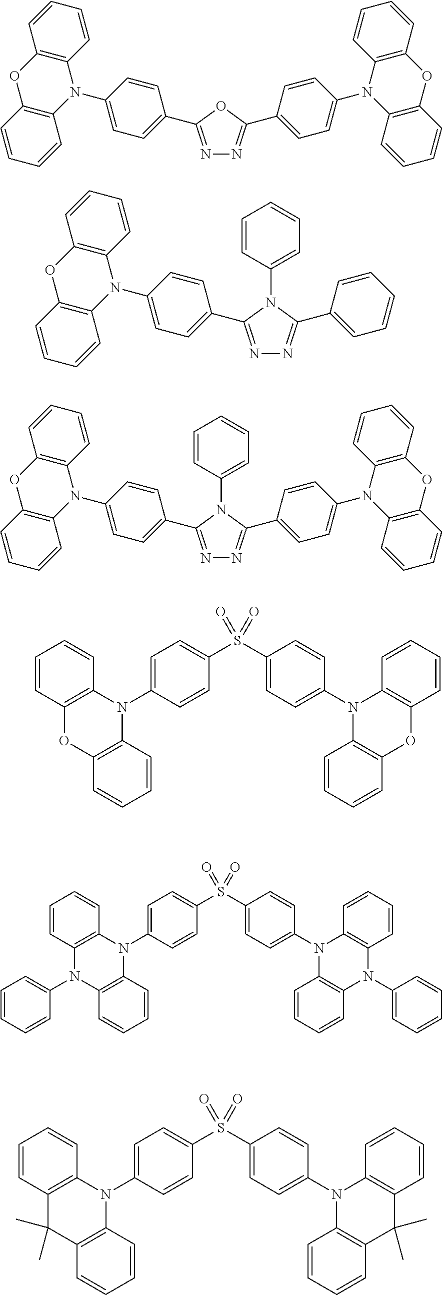

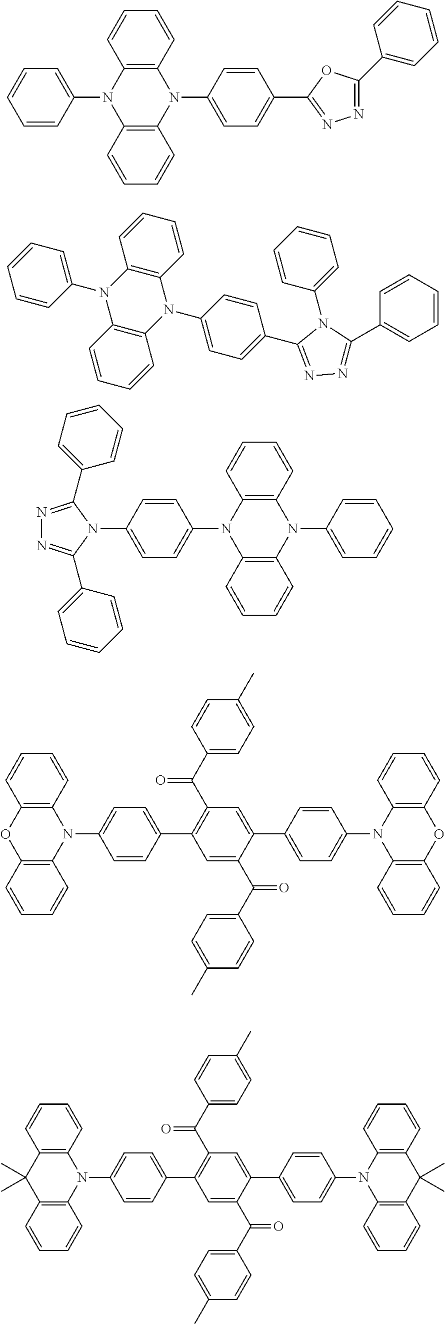

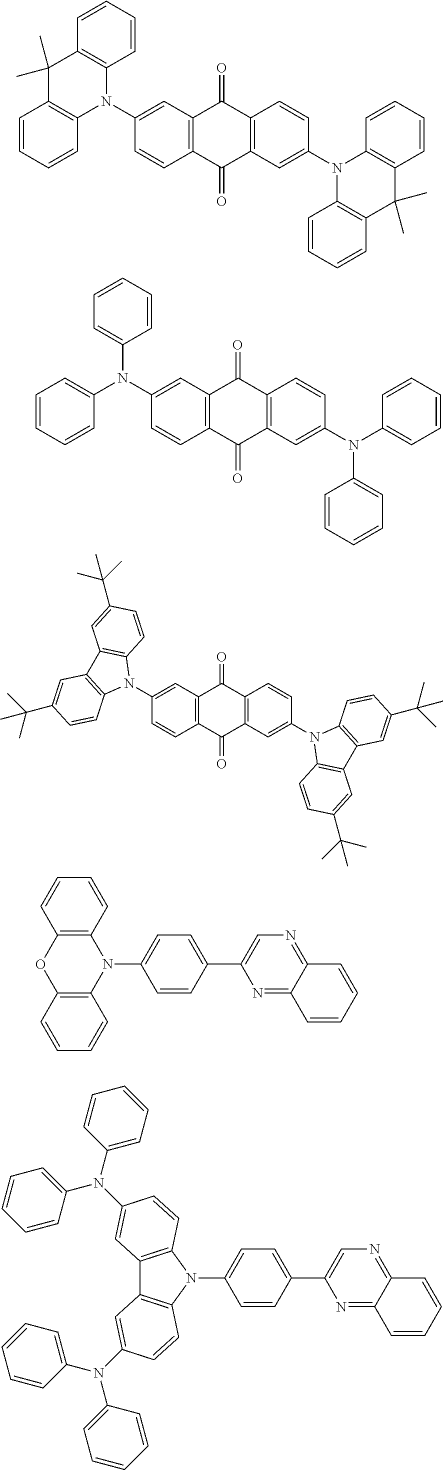

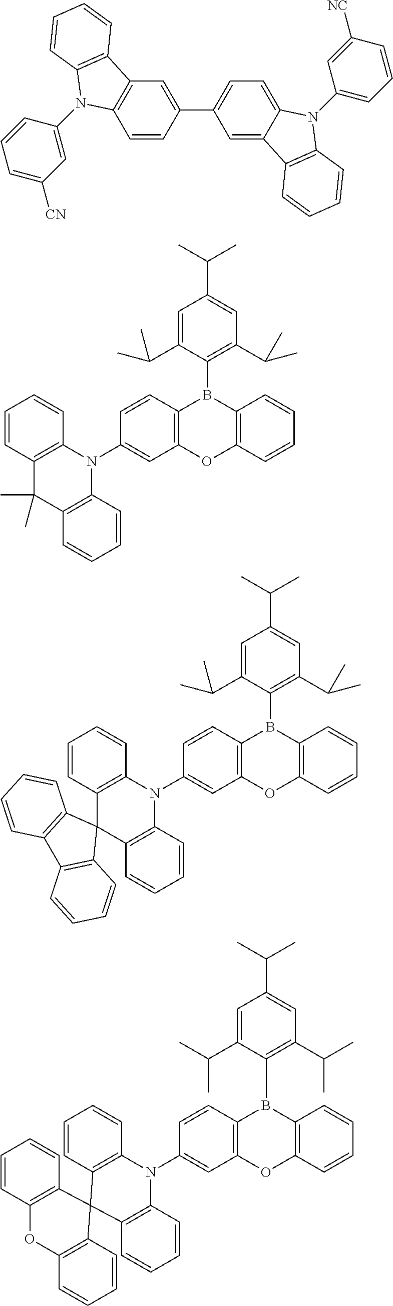 [SMILES: N#Cc1cccc(-n2c3ccccc3c3cc(-c4ccc5c(c4)c4ccccc4n5-c4cccc(C#N)c4)ccc32)c1 ; CC(C)c1cc(C(C)C)c(B2c3ccccc3Oc3cc(N4c5ccccc5C(C)(C)c5ccccc54)ccc32)c(C(C)C)c1 ; CC(C)c1cc(C(C)C)c(B2c3ccccc3Oc3cc(N4c5ccccc5C5(c6ccccc6-c6ccccc65)c5ccccc54)ccc32)c(C(C)C)c1 ; CC(C)c1cc(C(C)C)c(B2c3ccccc3Oc3cc(N4c5ccccc5C5(c6ccccc6Oc6ccccc65)c5ccccc54)ccc32)c(C(C)C)c1]

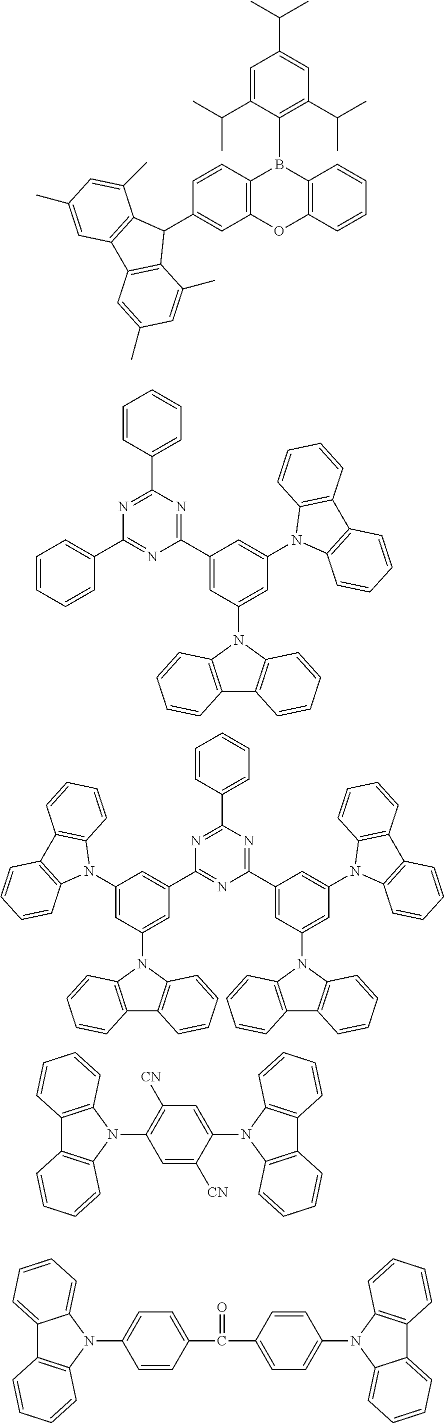

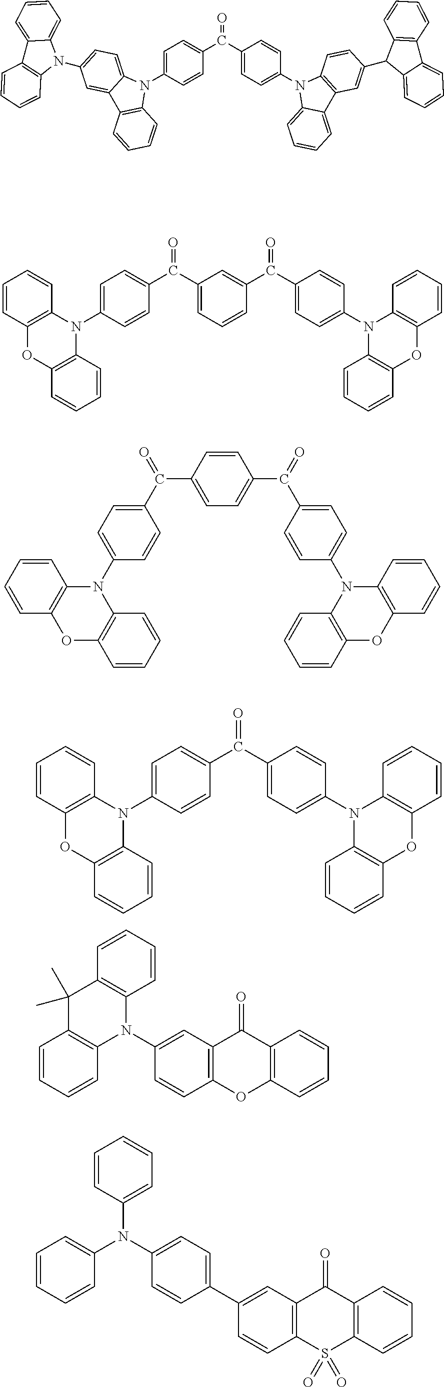

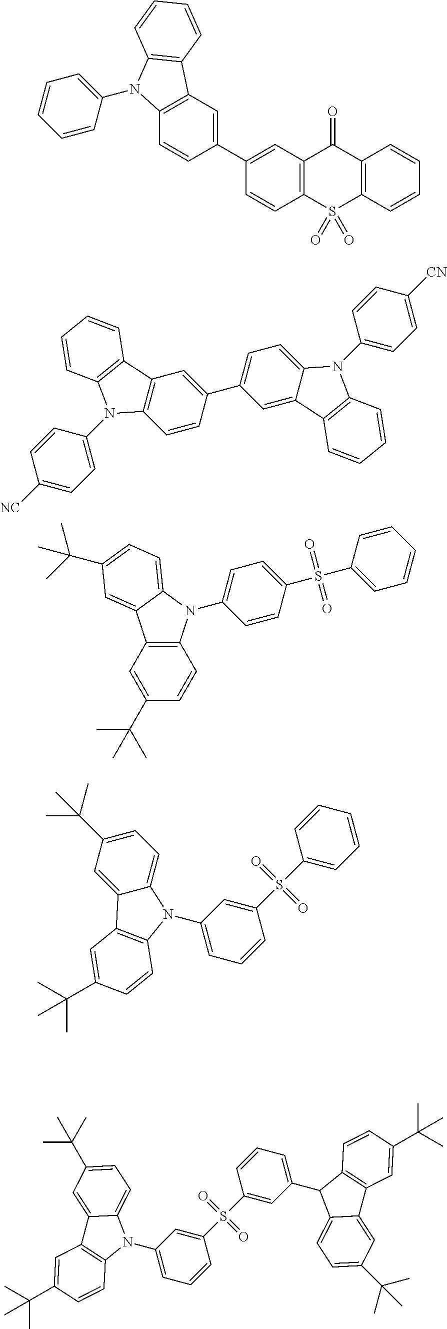

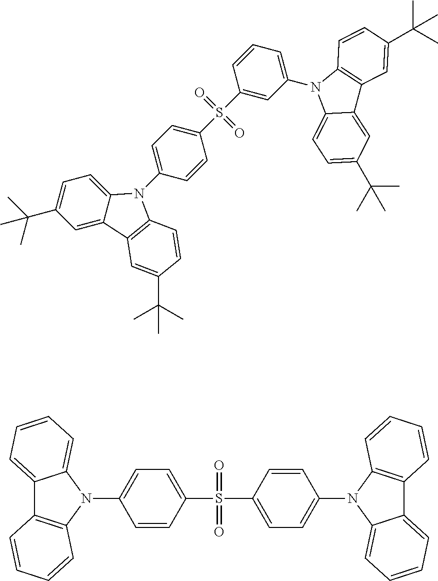 [SMILES: CC(C)(C)c1ccc2c(c1)c1cc(C(C)(C)C)ccc1n2-c1ccc(S(=O)(=O)c2cccc(-n3c4ccc(C(C)(C)C)cc4c4cc(C(C)(C)C)ccc43)c2)cc1 ; O=S(=O)(c1ccc(-n2c3ccccc3c3ccccc32)cc1)c1ccc(-n2c3ccccc3c3ccccc32)cc1]

The present embodiment also provides material solutions for printing OLEDs.

The silicon-containing organic compound according to the present embodiment has a molecular weight greater than or equal to 700 g/mol. In one embodiment, the molecular weight is greater than or equal to 800 g/mol. In another embodiment, the molecular weight is greater than or equal to 900 g/mol. In yet another embodiment, the molecular weight is greater than or equal to 1000 g/mol. In a further embodiment, the molecular weight is greater than or equal to 1100 g/mol.

The silicon-containing organic compound according to the present embodiment has a solubility at 25° C. in toluene greater than or equal to 10 mg/ml. In one embodiment, the solubility is greater than or equal to 15 mg/ml. In another embodiment, the solubility is greater than or equal to 20 mg/ml.

The present embodiment still further relates to a silicon-containing formulation or ink, which includes the aforementioned silicon-containing organic compound or silicon-containing polymer, as well as at least one organic solvent.

When used in a printing process, the viscosity and surface tension of the ink are important parameters. The suitable surface tension parameter of the ink is suitable for a particular substrate and a particular printing method.

In one embodiment, the surface tension of the ink according to the present embodiment is in a range of about 19 dyne/cm to 50 dyne/cm at an operating temperature or at 25° C. In another embodiment, the surface tension is in a range of 22 dyne/cm to 35 dyne/cm. In yet another embodiment, the surface tension is in a range of 25 dyne/cm to 33 dyne/cm. The viscosity of the ink according to the present embodiment is in a range of about 1 cps to 100 cps at an operating temperature or at 25° C. In one embodiment, the viscosity is in a range of 1 cps to 50 cps. In another embodiment, the viscosity is in a range of 1.5 cps to 20 cps. In yet another embodiment, the viscosity is in a range of 4.0 cps to 20 cps. Such formulated formulation will facilitate inkjet printing.

The viscosity can be adjusted by various methods, such as by appropriate solvent selection and the concentration of functional materials in the ink. The ink including the metal organic complex or polymer according to the present embodiment can facilitate the adjustment of the printing ink in an appropriate range according to the printing method used. In general, the formulation according to the present embodiment contains the functional material in a weight ratio in a range of 0.3% to 30% by weight. In one embodiment, the weight ratio is in a range of 0.5% to 20% by weight. In another embodiment, the weight ratio is in a range of 0.5% to 15% by weight. In yet another embodiment, the weight ratio is in a range of 0.5% to 10% by weight. In a further embodiment, the weight ratio is in a range of 1% to 5% by weight.

According to the ink of the present embodiment, the at least one organic solvent is selected from the solvents based on aromatic or heteroaromatic, particularly aliphatic chain/cycle substituted aromatic solvent, aromatic ketone solvent, or aromatic ether solvent.

Examples of solvents suitable for the present embodiment include, but are not limited to, solvents based on aromatic or heteroaromatic, such as p-diisopropylbenzene, amylbenzene, tetrahydronaphthalene, phenylcyclohexane, chloronaphthalene, 1,4-dimethylnaphthalene, 3-isopropylbiphenyl, p-methylisopropylbenzene, diamylbenzene, triamylbenzene, pentyltoluene, o-xylene, m-xylene, p-xylene, o-diethylbenzene, m-diethylbenzene, p-diethylbenzene, 1,2,3,4-tetramethylbenzene, 1,2,3,5-tetramethylbenzene, 1,2,4,5-tetramethylbenzene, butylbenzene, dodecylbenzene, dihexylbenzene, dibutylbenzene, p-diisopropylbenzene, 1-methoxynaphthalene, phenylcyclohexane, dimethylnaphthalene, 3-isopropylbiphenyl, p-methylisopropylbenzene, 1-methylnaphthalene, 1,2,4-trichlorobenzene, 1,3-dipropoxybenzene, 4,4-difluorodiphenylmethane, 1,2-dimethoxy-4-(1-propenyl)benzene, diphenylmethane, 2-phenylpyridine, 3-phenylpyridine, N-methyldiphenylamine, 4-isopropylbiphenyl, α,α-dichlorodiphenylmethane, 4-(3-phenylpropyl)pyridine, benzyl benzoate, 1,1-bis(3,4-dimethylphenyl)ethane, 2-isopropylnaphthalene, dibenzyl ether, and the like; solvents based on ketone, such as 1-tetralone, 2-tetralone, 2-(phenylepoxy)tetralone, 6-(methoxy)-tetralone, acetophenone, propiophenone, benzophenone, and derivatives thereof, such as 4-methylacetophenone, 3-methylacetophenone, 2-methylacetophenone, 4-methylpropiophenone, 3-methylpropiophenone, 2-methylpropiophenone, isophorone, 2,6,8-trimethyl-4-nonanone, fenchone, 2-nonanone, 3-nonanone, 5-nonanone, 2-decanone, 2,5-hexanedione, phorone, and di-n-amyl ketone; solvents based on aromatic ether, such as 3-phenoxytoluene, butoxybenzene, benzyl butylbenzene, p-anisaldehyde dimethyl acetal, tetrahydro-2-phenoxy-2H-pyran, 1,2-dimethoxy-4-(1-propenyl)benzene, 1,4-benzodioxane, 1,3-dipropylbenzene, 2,5-dimethoxytoluene, 4-ethylphenetole, 1,2,4-trimethoxybenzene, 4-(1-propenyl)-1,2-dimethoxybenzene, 1,3-dimethoxybenzene, glycidyl phenyl ether, dibenzyl ether, 4-tert-butylanisole, trans-p-propenylanisole, 1,2-dimethoxybenzene, 1-methoxynaphthalene, diphenyl ether, 2-phenoxymethyl ether, 2-phenoxytetrahydrofuran, ethyl-2-naphthyl ether, amyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethylene glycol ethyl methyl ether, triethylene glycol butyl methyl ether, tripropylene glycol dimethyl ether, tetraethylene glycol dimethyl ether; solvents based on ester, such as alkyl octoate, alkyl sebacate, alkyl stearate, alkyl benzoate, alkyl phenylacetate, alkyl cinnamate, alkyl oxalate, alkyl maleate, alkyl lactone, alkyl oleate, and the like.

In addition, the solvents suitable for the present embodiment may be at least one selected from the group consisting of: aliphatic ketone, such as 2-nonanone, 3-nonanone, 5-nonanone, 2-decanone, 2,5-hexanedione, 2,6,8-trimethyl-4-nonanone, phorone, di-n-amyl ketone, and the like; and aliphatic ether, such as pentyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethylene glycol ethyl methyl ether, triethylene glycol butyl methyl ether, tripropylene glycol dimethyl ether, tetraethylene glycol dimethyl ether, and the like.

In one embodiment, the ink of the present embodiment further includes another organic solvent. Examples of another organic solvent include, but are not limited to, methanol, ethanol, 2-methoxyethanol, dichloromethane, trichloromethane, chlorobenzene, o-dichlorobenzene, tetrahydrofuran, anisole, morpholine, toluene, o-xylene, m-xylene, p-xylene, 1,4-dioxahexane, acetone, methyl ethyl ketone, 1,2-dichloroethane, 3-phenoxytoluene, 1,1,1-trichloroethane, 1,1,2,2-tetrachloroethane, ethyl acetate, butyl acetate, dimethylformamide, dimethylacetamide, dimethyl sulfoxide, tetrahydronaphthalene, decalin, indene, and/or mixtures thereof.

In one embodiment, the silicon-containing formulation is a solution.

In another embodiment, the silicon-containing formulation is a suspension.

The silicon-containing formulation of the present embodiment may include 0.01 to 20% by weight of the silicon-containing organic compound, the silicon-containing polymer, or a mixture of the silicon-containing organic compound and the silicon-containing polymer. In one embodiment, the weight percentage is 0.1 to 15 wt %. In another embodiment, the weight percentage is 0.2 to 10 wt %. In yet another embodiment, the weight percentage is 0.25 to 5 wt %.

The present embodiment also relates to the application of the formulation as a coating or printing ink in the preparation of organic electronic devices, and more specifically a preparation method by means of printing or coating.

Suitable printing or coating techniques include, but are not limited to, inkjet printing, nozzle printing, typographic printing, screen printing, dip coating, spin coating, blade coating, roll printing, torsion printing, lithography, flexography, rotary printing, spray coating, brush coating or pad printing, slit type extrusion coating, and so on. Preferred are gravure printing, nozzle printing, and inkjet printing. The solution or suspension may additionally include one or more components such as surface active compounds, lubricants, wetting agents, dispersing agents, hydrophobic agents, binders, and the like, for adjusting viscosity, film forming properties, and improving adhesion.

Based on the aforementioned silicon-containing organic compounds, the present embodiment also provides a related use thereof, i.e., use of the silicon-containing organic compounds to the organic electronic device. The organic electronic device may be selected from, but not limited to, organic light-emitting diode (OLED), organic photovoltaic cell (OPV), organic light-emitting electrochemical cell (OLEEC), organic field-effect transistor (OFET), organic light-emitting field-effect transistor, organic laser, organic spin electron device, organic sensor, and organic plasmon emitting diode, and the like, especially OLED. In an embodiment, the silicon-containing organic compound is used in a light-emitting layer of an OLED device.

The present embodiment further relates to an organic electronic device, which includes at least one organic compound as described above. In general, such organic electronic device includes at least one cathode, one anode, and a functional layer located between the cathode and the anode. The functional layer includes at least one organic compound as described above.

The aforementioned light-emitting device, particularly OLED, includes a substrate, an anode, at least one light-emitting layer, and a cathode.

The substrate can be opaque or transparent. The substrate can be rigid or elastic. The substrate can be plastic, metal, semiconductor wafer, or glass. In one embodiment, the substrate has a smooth surface. Substrates free of surface defects are particularly desirable. In one embodiment, the substrate is flexible and may be selected from polymer films or plastics, which has a glass transition temperature Tg greater than 150° C. In another embodiment, the glass transition temperature is greater than 200° C. In yet another embodiment, the glass transition temperature is greater than 250° C. In a further embodiment, the glass transition temperature is greater than 300° C. Examples of suitable flexible substrates are poly(ethylene terephthalate) (PET) and polyethylene glycol (2,6-naphthalene) (PEN).

The anode may include a conductive metal or a metal oxide, or a conductive polymer. The anode may easily inject holes into the hole injection layer (HIL) or the hole transport layer (HTL) or the light-emitting layer. In one embodiment, the absolute value of the difference between the work function of the anode and the HOMO energy level or the valence band energy level of the emitter in the light-emitting layer or of the p-type semiconductor material as the HIL or HTL or the electron blocking layer (EBL) is less than 0.5 eV. In one embodiment, the absolute value is less than 0.3 eV. In another embodiment, the absolute value is less than 0.2 eV. Examples of anode materials include, but are not limited to, Al, Cu, Au, Ag, Mg, Fe, Co, Ni, Mn, Pd, Pt, ITO, aluminum-doped zinc oxide (AZO), and the like. Other suitable anode materials are known and can be readily selected for use by one of ordinary skill in the art. The anode material can be deposited using any suitable technique, such as a suitable physical vapor deposition method, including radio frequency magnetron sputtering, vacuum thermal evaporation, electron beam (e-beam), and the like. In some embodiments, the anode is patterned. The patterned ITO conductive substrate is commercially available and can be used to fabricate the device according to the present embodiment.

The cathode may include a conductive metal or a metal oxide. The cathode can easily inject electrons into the EIL or ETL or directly into the light-emitting layer. In one embodiment, the absolute value of the difference between the work function of the cathode and the LUMO energy level or the conduction band energy level of the emitter in the light-emitting layer or of the n-type semiconductor material as the electron injection layer (EIL) or the electron transport layer (ETL) or the hole blocking layer (HBL) is less than 0.5 eV. In one embodiment, the absolute value is less than 0.3 eV. In another embodiment, the absolute value is less than 0.2 eV. In principle, all the materials that can be used as the cathode of the OLED can serve as a cathode material of the device of the present embodiment. Examples of the cathode material include, but are not limited to, Al, Au, Ag, Ca, Ba, Mg, LiF/Al, MgAg alloy, BaF₂/Al, Cu, Fe, Co, Ni, Mn, Pd, Pt, ITO, and the like. The cathode material can be deposited using any suitable technique, such as a suitable physical vapor deposition method, including radio frequency magnetron sputtering, vacuum thermal evaporation, electron beam (e-beam), and the like.

The OLEDs can also include other functional layers such as hole injection layer (HIL), hole transport layer (HTL), electron blocking layer (EBL), electron injection layer (EIL), electron transport layer (ETL), and hole blocking layer (HBL).

The light-emitting device according to the present embodiment has a light emission wavelength between 300 and 1000 nm. In one embodiment, the light emission wavelength is between 350 and 900 nm. In another embodiment, the light emission wavelength is between 400 and 800 nm.

The present embodiment also relates to the use of the organic electronic devices according to the present embodiment in a variety of electronic devices including, but not limited to, display devices, lighting devices, light sources, sensors, and the like.

The present embodiment will be described in detail below with reference to the following embodiments.

### Example 1

### 3′,7′-bis(di-p-toluidine)-3,7-dinitrile-5,5′-spiro[diphenyl[b,d]silylfluorene]

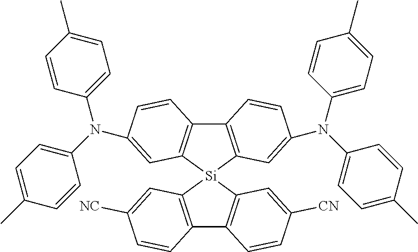

5.4 g, 10 mmol of 3,7-dibromo-3′,7′-dinitrile-5,5′-spirodisilylfluorene, 4.4 g, 22 mmol of 4,4′-dimethyldiphenylamine, 4.8 g, 50 mmol of sodium tert-butoxide, 0.45 g, 2 mmol of Pd(OAc)₂, and 150 ml of toluene were added into a 250 ml of three-necked flask, and were reacted in an atmosphere of N₂ at a temperature of 110° C. The reaction progress was tracked by TLC. After the reaction was completed, the reaction solution was cooled to room temperature. The reaction solution was poured into water, washed to remove the sodium tert-butoxide, and then was suction-filtered to obtain a solid product. The solid product was dissolved with dichloromethane to remove impurities therein. The recrystallization was performed by using ethanol, thereby obtaining 6.2 g of 3′,7′-bis(di-p-toluidine)-3,7-dinitrile-5,5′-spiro[diphenyl[b,d]silylfluorene] as a solid powder. MS(ASAP)=773.4.

### Example 2

### 5′-phenyl-5′H, 1 OH-spiro[diphenyl[b,e]aminosilyl-5,10′-diphenyl[b,e][1,4]-10-ketodiphenylsilane]

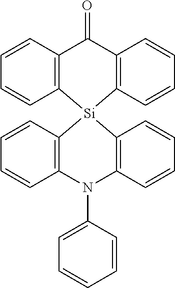 [SMILES: O=C1c2ccccc2[Si]2(c3ccccc31)c1ccccc1N(c1ccccc1)c1ccccc12]

150 ml of dry THF, 4.0 g, 10.0 mmol of 2,2′-dibromotriphenylamine were added into a 250 ml of three-necked flask, and cooled to a temperature of −78° C. until completely dissolved. 20.0 mmol of n-butyllithium solution was slowly dropwise added to the mixed solution, and the reaction was continued for 2 hours. The resulting solution was dropwise added to a THF solution of 2.8 g, 10 mmol of 5,5-dichloro-10-ketobiphenyl[b,e]silane at a temperature of −78° C. The reaction was continued at a low temperature overnight and the reaction progress was tracked by TLC. After the reaction was completed, the reaction solution was spontaneously warmed up to room temperature. The reaction solution was poured into water and extracted with dichloromethane. The organic phases were combined, dried, and suction-filtered, and then evaporated to dryness, thereby obtaining a crude product. The recrystallization was performed by using toluene/methanol mixed solvent, thereby obtaining 3.5 g of 5′-phenyl-5′H, 10H-spiro[diphenyl[b,e]aminosilyl-5,10′-diphenyl[b,e][1,4]-10-ketodiphenylsilane] as a solid powder. MS(ASAP)=451.2.

### Example 3

### 3,7-bis(4,6-diphenyl-1,3,5-triazine)-5′-phenyl-5′H-spiro[diphenyl[b,d]silyl-5,10′-diphenyl[b,e][1,4]aminosilicon]

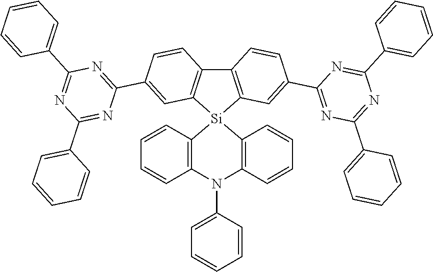 [SMILES: c1ccc(-c2nc(-c3ccccc3)nc(-c3ccc4c(c3)[Si]3(c5cc(-c6nc(-c7ccccc7)nc(-c7ccccc7)n6)ccc5-4)c4ccccc4N(c4ccccc4)c4ccccc43)n2)cc1]

5.1 g, 10.0 mmol of 5′-phenyl-3,7-diboric acid-5′H-spiro[diphenyl[b,d]silyl-5,10′-diphenyl[b,e][1,4]diphenylamino silicon], 5.84 g, 22.0 mmol of 2-chloro-4,6-diphenyl-1,3,5-triazine, 6.9 g, 50 mmol of potassium carbonate, 1.15 g, 1 mmol of Pd(PPh₃)₄, 100 ml of toluene, 25 ml of water, and 25 ml of methanol were added into a 250 ml of three-necked flask, and were reacted in an atmosphere of N₂ at a temperature of 110° C. The reaction progress was tracked by TLC. After the reaction was completed, the reaction solution was cooled to room temperature. The reaction solution was poured into water, washed to remove the potassium carbonate, and then was suction-filtered to obtain a solid product. The solid product was washed with dichloromethane. The recrystallization was performed by using toluene/petroleum ether mixed solvent, thereby obtaining 7.0 g of 3,7-bis(4,6-diphenyl-1,3,5-triazine)-5′-phenyl-5′H-spiro[diphenyl[b,d]silyl-5,10′-diphenyl[b,e][1,4]aminosilicon] as a white solid powder. MS(ASAP)=886.1.

### Example 4

### 3-(10,10-dimethyldiphenyl[b,e][1,4]diphenylamino silicon-5(10H))-9H-9-one-xanthene

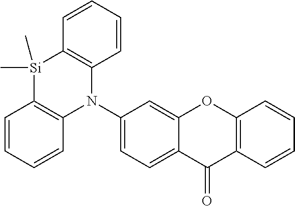 [SMILES: C[Si]1(C)c2ccccc2N(c2ccc3c(=O)c4ccccc4oc3c2)c2ccccc21]

2.74 g, 10 mmol of 3-bromo-9H-9-ketoxanthene, 2.7 g, 12 mmol of 10,10-dimethyl-5,10-diphenyl[b,e][1,4]aminosilicon, 2.4 g, 25 mmol of sodium tert-butoxide, 0.22 g, 1 mmol of Pd(OAc)₂, and 150 ml of toluene were added into a 250 ml of three-necked flask, and were reacted in an atmosphere of N₂ at a temperature of 110° C. The reaction progress was tracked by TLC. After the reaction was completed, the reaction solution was cooled to room temperature. The reaction solution was poured into water, washed to remove the sodium tert-butoxide, and then was suction-filtered to obtain a solid product. The solid product was dissolved with dichloromethane to remove impurities therein. The recrystallization was performed by using ethanol, thereby obtaining 3.0 g of 3-(10,10-dimethyldiphenyl[b,e][1,4]diphenylamino silicon-5(10H))-9H-9-one-xanthene as a solid powder. MS(ASAP)=420.3.

### Example 5

### 5′-phenyl-3,7-dinitrile-5′-spiro[diphenyl[b,d]silane-5,10′-diphenyl[b,e][1,4]aminosilicon]

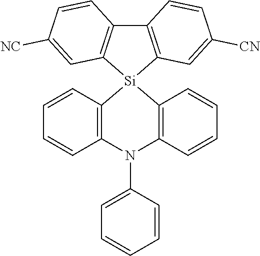 [SMILES: N#Cc1ccc2c(c1)[Si]1(c3cc(C#N)ccc3-2)c2ccccc2N(c2ccccc2)c2ccccc21]

2.0 g, 3.5 mmol of 5′-phenyl-3,7-dibromo-5′H-spiro[diphenyl[b,d]silyl-5,10′-diphenyl[b,e][1,4]aminosilicon], 0.79 g, 8.8 mmol of cuprous cyanide, and 50 ml of N-methyl-pyrrolidone were added into a 100 ml of three-necked flask, and were heated to a temperature of 110° C. in an atmosphere of N₂ and reacted for 20 hours. The reaction progress was tracked by TLC. After the reaction was completed, the reaction solution was cooled to room temperature. The reaction solution was poured into water, dissolved with toluene, and washed with water. The organic solvent therein was evaporated off and the crude product was obtained to purify by flash silica gel column. The recrystallization was performed by using toluene/petroleum ether mixed solvent, thereby obtaining 0.81 g of 5′-phenyl-3,7-dinitrile-5′-spiro[diphenyl[b,d]silane-5,10′-diphenyl[b,e][1,4]aminosilicon] as a yellow needle solid. MS(ASAP)=458.4.

The energy levels of the organic compound materials can be calculated by quantum, for example, using TD-DFT (time-dependent density functional theory) by Gaussian09W (Gaussian Inc.), and specific simulation methods can be referred to WO2011141110. Firstly, the molecular geometry is optimized by semi-empirical method “Ground State/Semi-empirical/Default Spin/AM1” (Charge 0/Spin Singlet). Then, the energy structure of organic molecules is calculated by TD-DFT (time-dependent density functional theory) method for “TD-SCF/DFT/Default Spin/B3PW91” and the base group “6-31G (d)” (Charge 0/Spin Singlet). The HOMO and LUMO energy levels are calculated according to the following calibration equations: S₁, T₁, and the resonance factor f(S₁) are used directly.

HOMO(eV)=((HOMO(G)×27.212)−0.9899)/1.1206

LUMO(eV)=((LUMO(G)×27.212)−2.0041)/1.385

HOMO (G) and LUMO (G) are the direct calculation results of Gaussian 09W, in units of Hartree. The results are shown in Table 1:

TABLE 1

| Examples | HOMO [eV] | LUMO [eV] | T₁ [eV] | S₁ [eV] | ΔE_{ST} |
|---|---|---|---|---|---|
| 1 | −5.26 | −3.25 | 1.99 | 1.99 | 0.00 |
| 2 | −5.66 | −2.88 | 2.71 | 2.83 | 0.13 |
| 3 | −5.58 | −2.97 | 2.53 | 2.71 | 0.18 |
| 4 | −5.64 | −3.00 | 2.60 | 2.62 | 0.02 |
| 5 | −5.90 | −3.17 | 2.71 | 2.83 | 0.14 |
| Ref1 | −5.08 | −3.14 | 1.90 | 1.91 | 0.01 |

ΔE(S₁−T₁) value of all the compounds are less than or equal to 0.18 eV.

In comparison with the aforementioned delayed fluorescent light-emitting material, the delayed fluorescent light-emitting material of the D-A structure is marked with Ref 1:

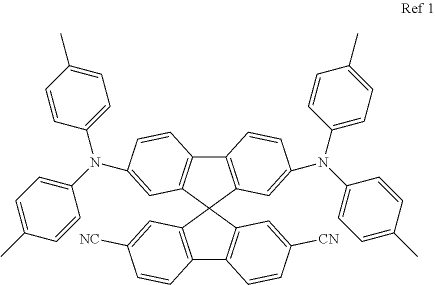

Fabrication of OLED Devices:

The fabrication steps for an OLED device having a silicon-containing organic compound of any one of ITO/NPD (35 nm)/5 wt % (1) to (7): mCP(15 nm)/TPBi(65 nm)/LiF (1 nm)/Al (150 nm)/cathode are as follows:

a. cleaning of conductive glass substrate: when used for the first time, a variety of solvents, such as chloroform, ketone, or isopropyl alcohol can be used for cleaning, and then ion treatments such as UV and ozone are performed;

b. HTL (35 nm), EML (15 nm), ETL (65 nm): in a high vacuum (1×10⁻⁶ mbar) by thermal evaporation;

c. cathode: LiF/Al (1 nm/150 nm) is deposited by thermal evaporation in high vacuum (1×10⁻⁶ mbar);

d. package: the device is packed by UV curing resin in the nitrogen glove box.

The current-voltage (J-V) characteristics of each OLED device are characterized by characterization equipment, while recording important parameters such as efficiency, lifetime, and external quantum efficiency. It was found that the luminous efficiency and lifetime of OLED1 (corresponding to Example 1) are more than three times those of OLED Ref1 (corresponding to Ref1). The luminous efficiency of OLED3 (corresponding to Example 3) is four times that of OLED Ref1, while the lifetime of OLED3 is more than six times that of OLED Ref1. In particular, OLED3 has a maximum external quantum efficiency of more than 12%. It can be seen that the OLED device prepared by using the organic mixture of the present embodiment has greatly improved luminous efficiency and lifetime, and the external quantum efficiency thereof is also significantly improved.

The silicon-containing organic compound contains one or more silicon atoms and has a ΔE(S₁−T₁) less than or equal to 0.20 eV, which facilitates the realization of thermally activated delayed fluorescence (TADF) characteristics. By coordinating with a suitable host material, the aforementioned silicon-containing organic compound can be used as a TADF light-emitting material to improve the luminescent efficiency and lifetime of the electroluminescent device. Thus, the contained organic compound provides a better solution for manufacturing a light-emitting device with low cost, high efficiency, long lifetime, and low roll-off.

Although the respective embodiments have been described one by one, it shall be appreciated that the respective embodiments will not be isolated. Those skilled in the art can apparently appreciate upon reading the disclosure of this application that the respective technical features involved in the respective embodiments can be combined arbitrarily between the respective embodiments as long as they have no collision with each other. Of course, the respective technical features mentioned in the same embodiment can also be combined arbitrarily as long as they have no collision with each other.

Although the invention is illustrated and described herein with reference to specific embodiments, the invention is not intended to be limited to the details shown. Rather, various modifications may be made in the details within the scope and range of equivalents of the claims and without departing from the invention.

What is claimed is:

1. A silicon-containing organic compound having formula selected from any one of the following (1) to (7): 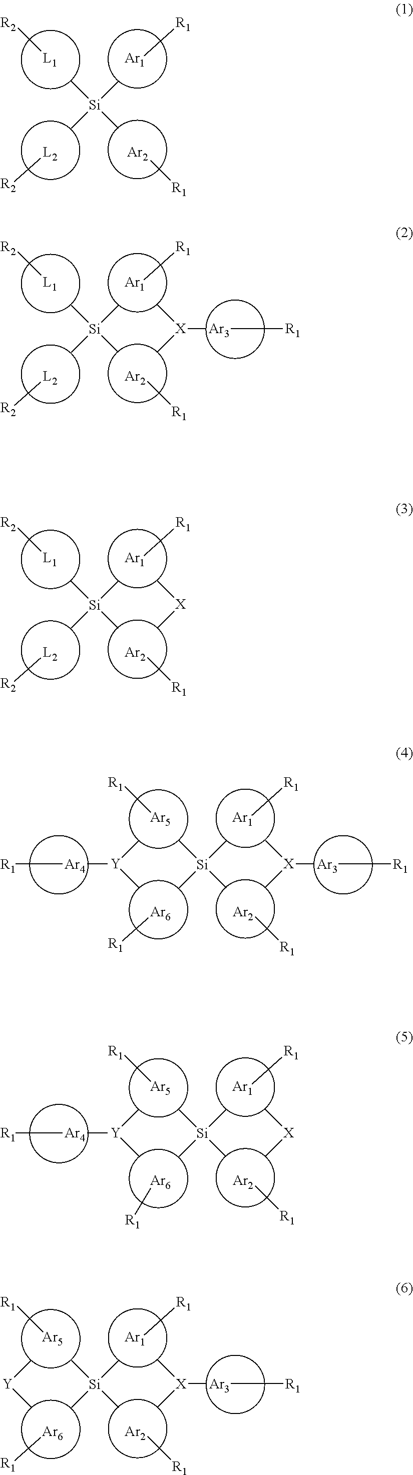 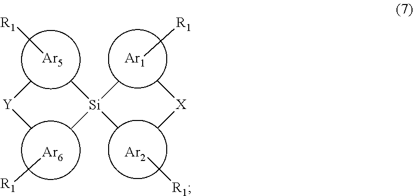
wherein Ar₁, Ar₂, Ar₃, Ar₄, Ar₅, and Ar₆ are independently selected from the group consisting of aromatic group, heteroaromatic group, and non-aromatic cyclic group;
L₁ and L₂ are independently selected from the group consisting of aromatic group, heteroaromatic group, and non-aromatic cyclic group; or independently selected from the group consisting of linear alkyl, alkane ether group, alkane aromatic group, alkane heteroaromatic group, and alkane non-aromatic cyclic group;
the plurality of R₁ are independently selected from the group consisting of H, F, Cl, Br, I, D, CN, NO₂, CF₃, B(OR₃)₂, Si(R₃)₃, linear alkyl, alkane ether group, alkane thioether group containing 1 to 10 carbon atoms, branched alkyl, and cycloalkyl;
the plurality of R₂ are independently selected from the group consisting of H, F, Cl, Br, I, D, CN, NO₂, CF₃, B(OR₃)₂, Si(R₃)₃, linear alkyl, alkane ether group, alkane thioether group containing 1 to 10 carbon atoms, branched alkyl, and cycloalkyl;
the plurality of R₃ are independently selected from the group consisting of aliphatic alkyl containing 1 to 10 carbon atoms, aromatic hydrocarbon group, and substituted or unsubstituted aryl or heteroaryl containing 5 to 10 ring atoms;
X is a triply bridging group or a doubly bridging group; Y is a triply bridging group or a doubly bridging group;
wherein the silicon-containing organic compound has a ΔE(S₁−T₁) less than or equal to 0.20 eV, and the silicon-containing organic compound comprises at least one electron-donating group and/or at least one electron-accepting group.

2. The silicon-containing organic compound according to claim 1, wherein the ΔE(S₁−T₁) is less than or equal to 0.10 eV.

3. The silicon-containing organic compound according to claim 1, wherein the silicon-containing organic compound comprises at least one electron-donating group and at least one electron-accepting group.

4. The silicon-containing organic compound according to claim 1, wherein carbon atoms in each of Ar₁, Ar₂, Ar₃, Ar₄, Ar₅, Ar₆, L₁, and L₂ are less than or equal to 30.

5. The silicon-containing organic compound according to claim 1, wherein carbon atoms in each of Ar₁, Ar₂, Ar₃, Ar₄, Ar₅, Ar₆, L₁, and L₂ are less than or equal to 20.

6. The silicon-containing organic compound according to claim 1, wherein X and Y are independently selected from one of the following groups: 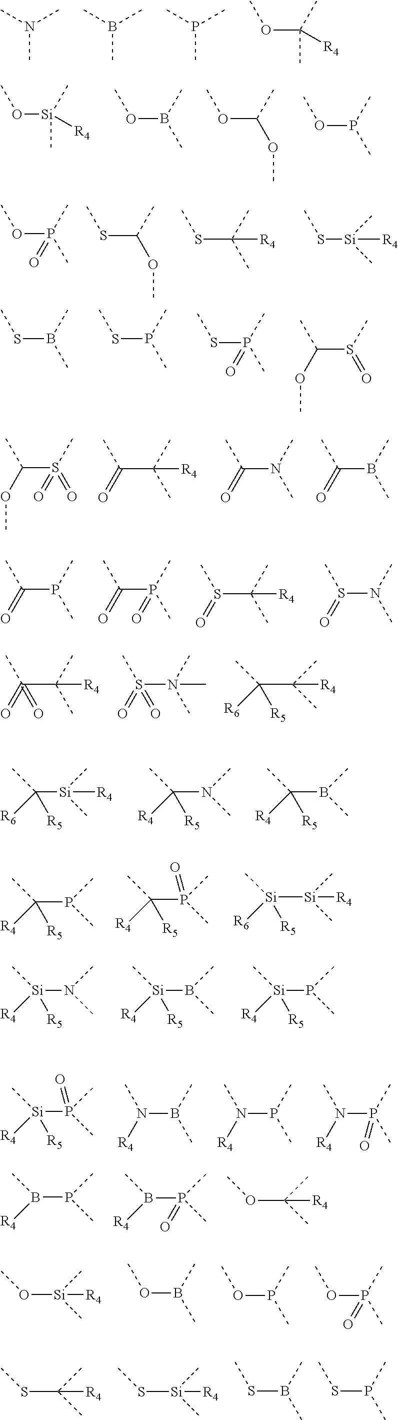 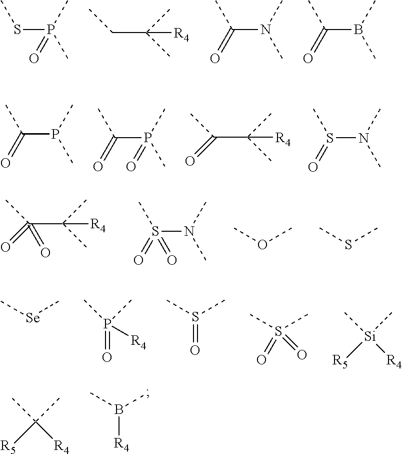
wherein R₄, R₅, and R₆ are independently selected from the group consisting of H, F, Cl, Br, I, D, CN, NO₂, CF₃, B(OR₃)₂, Si(R₃)₃, linear alkyl, alkane ether group, alkane thioether group containing 1 to 10 carbon atoms, branched alkyl, and cycloalkyl; dashed lines represent bonds configured to bond with Ar₁, Ar₂, Ar₃, Ar₅, Ar₆, and Ar₄.

7. The silicon-containing organic compound according to claim 1, wherein Ar₁, Ar₂, Ar₅, and Ar₆ are independently selected from one of the following groups: 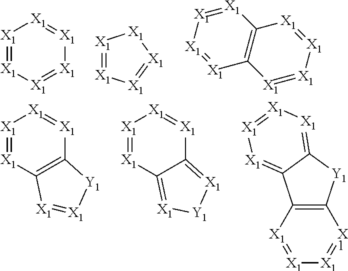
wherein,
X₁ is selected from CR⁵ or N;
Y₁ is selected from CR⁶R⁷, SiR⁸R⁹, NR¹⁰, C(═O), S, or O;
R⁵, R⁶, R⁷, R⁸, R⁹, and R¹⁰ are independently selected from at least one of the group consisting of H; D; linear alkyl containing 1 to 20 carbon atoms, linear alkoxy containing 1 to 20 carbon atoms, or linear thioalkoxy containing 1 to 20 carbon atoms; branched or cyclic alkyl containing 3 to 20 carbon atoms, branched or cyclic alkoxy containing 3 to 20 carbon atoms, or branched or cyclic thioalkoxy group containing 3 to 20 carbon atoms; silyl; substituted keto group containing 1 to 20 carbon atoms; alkoxy carbonyl containing 2 to 20 carbon atoms; aryloxy carbonyl containing 7 to 20 carbon atoms; cyano; carbamoyl; haloformyl; formyl; isocyano; isocyanate group; thiocyanate group; isothiocyanate group; hydroxy; nitro; CF₃; Cl; Br; F; crosslinkable group; substituted or unsubstituted aromatic group or heteroaromatic group containing 5 to 40 ring atoms; and aryloxy or heteroaryloxy containing 5 to 40 ring atoms.

8. The silicon-containing organic compound according to claim 7, wherein Ar₁, Ar₂, Ar₅, and Ar₆ are independently selected from one of the following groups:

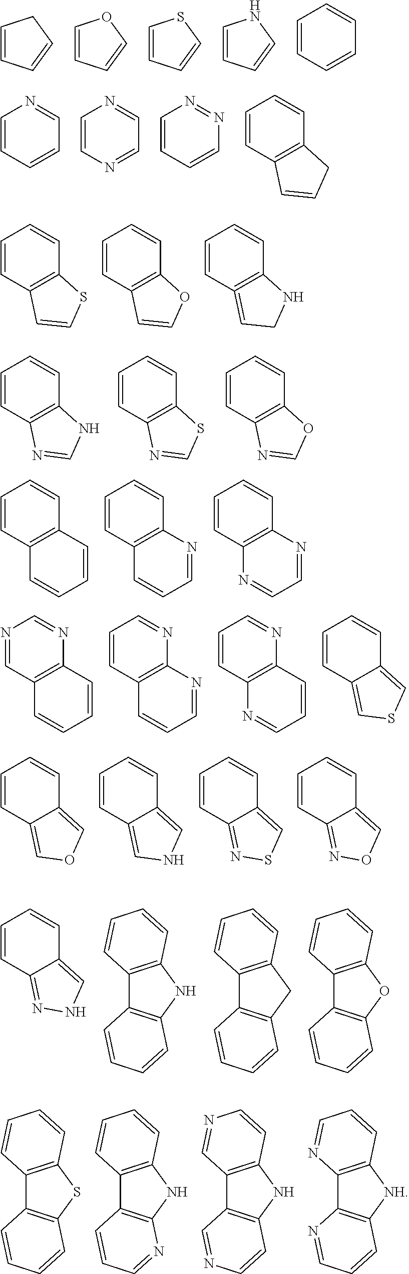

9. The silicon-containing organic compound according to claim 1, wherein Ar₃ and Ar₄ are independently selected from one of the following groups: 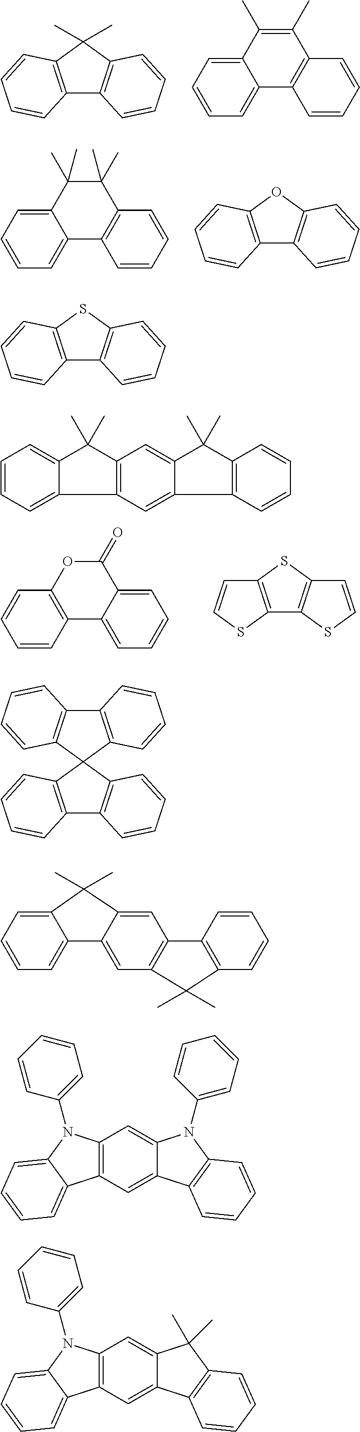 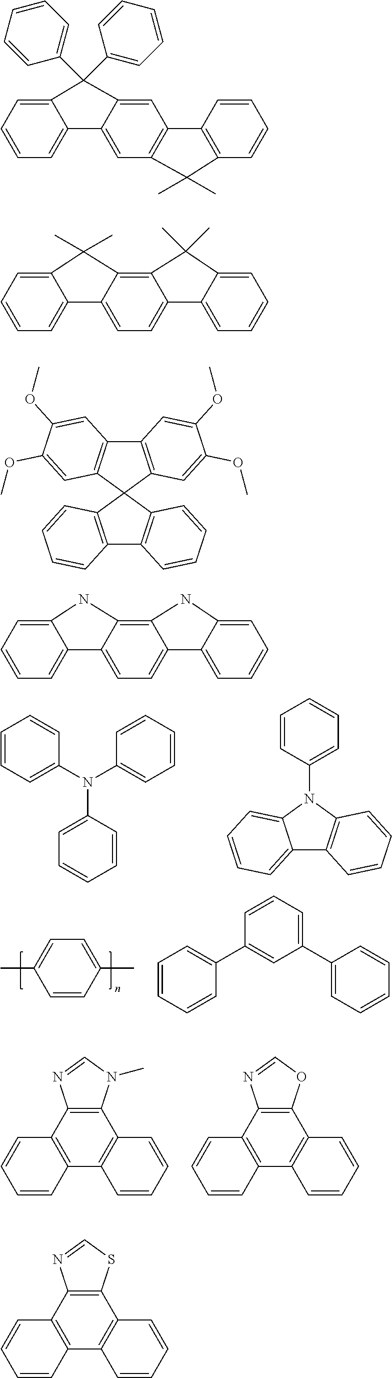 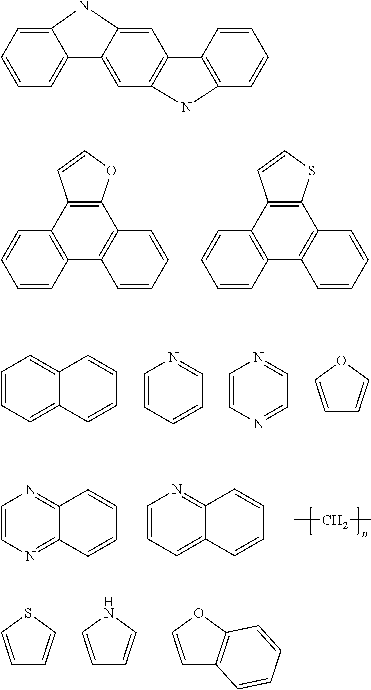
wherein n is an integer selecting from 1 to 4.

10. The silicon-containing organic compound according to claim 1, wherein the silicon-containing organic compound has one of the following formulas: 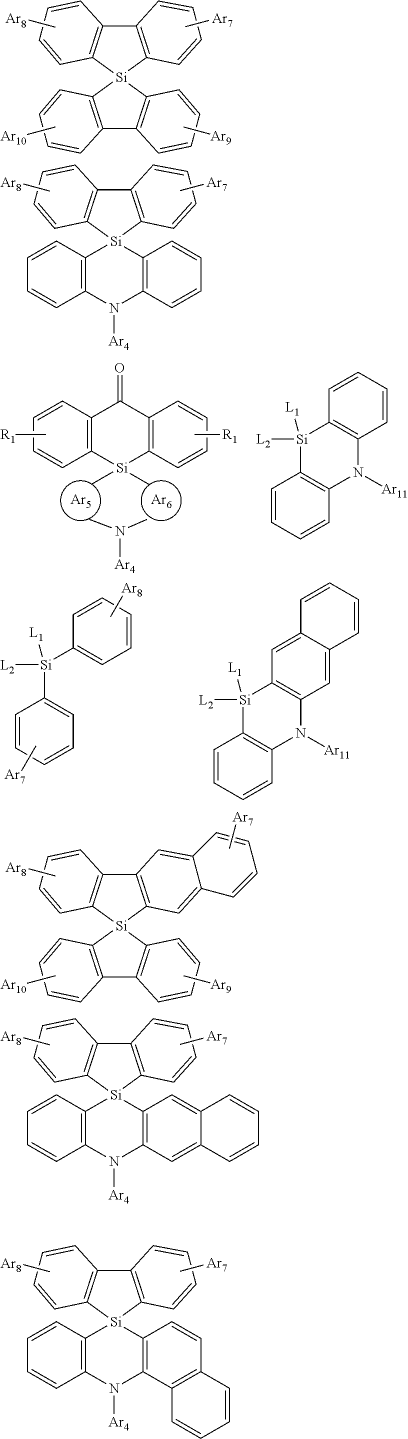 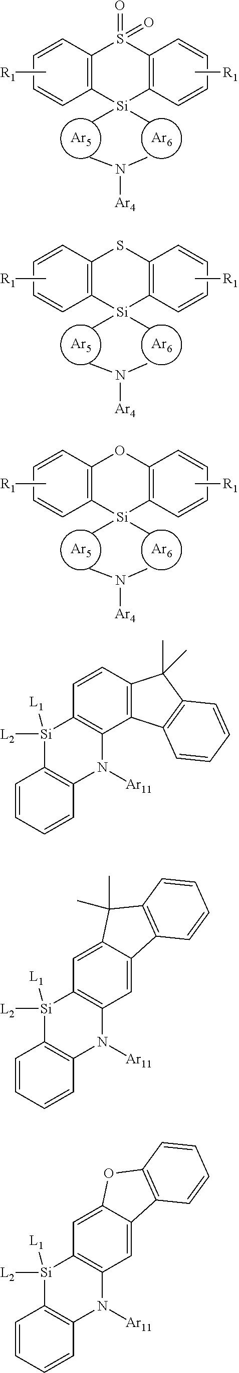 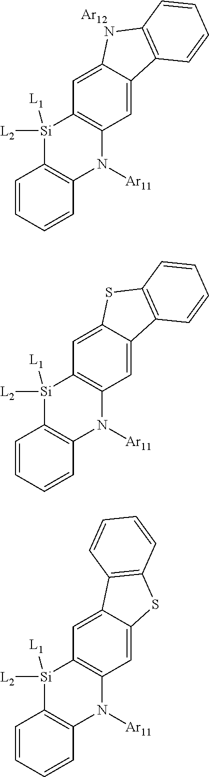
wherein Ar₇ and/or Ar₈ are electron-accepting groups, Ar₁₁ and Ar₁₂ are electron-accepting groups, Ar₉ and/or Ar₁₀ are electron-donating groups.

11. The silicon-containing organic compound according to claim 10, wherein at least one of Ar₁, Ar₂, Ar₃, Ar₄, Ar₅, and Ar₆ comprises one electron-donating group, and/or at least one of Ar₁, Ar₂, Ar₃, Ar₄, Ar₅, and Ar₆ comprises one electron-accepting group.

12. The silicon-containing organic compound according to claim 10, wherein the electron-donating group is at least one selected from the group consisting of:

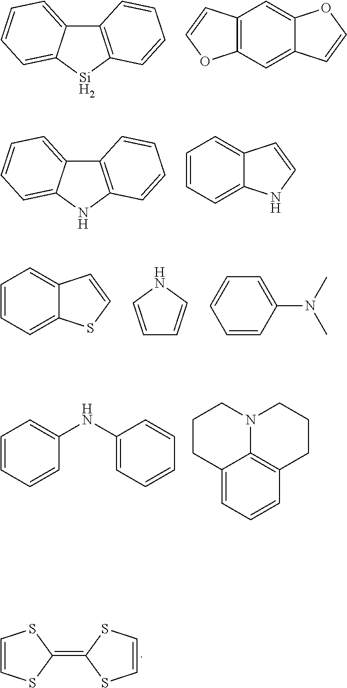

13. The silicon-containing organic compound according to claim 10, wherein the electron-accepting group is selected from —F or cyano, or is at least one selected from the group consisting of: 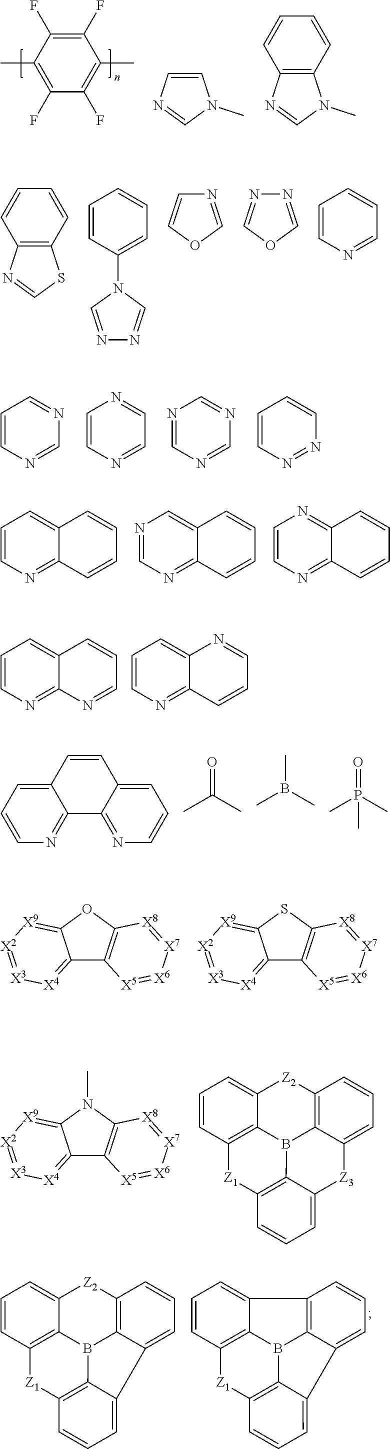
wherein n is an integer selected from 1 to 4;
X² to X⁹ is selected from CR or N, and at least one of X² to X⁹ is N;
Z₁, Z₂, and Z₃ are independently selected from the group consisting of N(R), C(R)₂, Si(R)₂, O, C═N(R), C═C(R)₂, P(R), P(═O)R, S, S═O, and SO₂;
R is selected from the group consisting of hydrogen, alkyl, alkoxy, amino, alkene, alkyne, aralkyl, heteroalkyl, aryl, and heteroaryl.

14. A silicon-containing formulation, comprising a silicon-containing organic compound according to claim 1, and an organic solvent.

15. The silicon-containing formulation according to claim 14, wherein the organic solvent is selected from the group consisting of p-diisopropylbenzene, amylbenzene, tetrahydronaphthalene, phenylcyclohexane, chloronaphthalene, 1,4-dimethylnaphthalene, 3-isopropylbiphenyl, p-methylisopropylbenzene, diamylbenzene, triamylbenzene, pentyltoluene, o-xylene, m-xylene, p-xylene, o-diethylbenzene, m-diethylbenzene, p-diethylbenzene, 1,2,3,4-tetramethylbenzene, 1,2,3,5-tetramethylbenzene, 1,2,4,5-tetramethylbenzene, butylbenzene, dodecylbenzene, dihexylbenzene, dibutylbenzene, p-diisopropylbenzene, 1-methoxynaphthalene, phenylcyclohexane, dimethylnaphthalene, 3-isopropylbiphenyl, p-methylisopropylbenzene, 1-methylnaphthalene, 1,2,4-trichlorobenzene, 1,3-dipropoxybenzene, 4,4-difluorodiphenylmethane, 1,2-dimethoxy-4-(1-propenyl)benzene, diphenylmethane, 2-phenylpyridine, 3-phenylpyridine, N-methyldiphenylamine, 4-isopropylbiphenyl, α,α-dichlorodiphenylmethane, 4-(3-phenylpropyl)pyridine, benzyl benzoate, 1,1-bis(3,4-dimethylphenyl)ethane, 2-isopropylnaphthalene, dibenzyl ether; 1-tetralone, 2-tetralone, 2-(phenylepoxy)tetralone, 6-(methoxy)-tetralone, acetophenone, propiophenone, benzophenone, 4-methylacetophenone, 3-methylacetophenone, 2-methylacetophenone, 4-methylpropiophenone, 3-methylpropiophenone, 2-methylpropiophenone, isophorone, 2,6,8-trimethyl-4-nonanone, fenchone, 2-nonanone, 3-nonanone, 5-nonanone, 2-decanone, 2,5-hexanedione, phorone, and di-n-amyl ketone; 3-phenoxytoluene, butoxybenzene, benzyl butylbenzene, p-anisaldehyde dimethyl acetal, tetrahydro-2-phenoxy-2H-pyran, 1,2-dimethoxy-4-(1-propenyl)benzene, 1,4-benzodioxane, 1,3-dipropylbenzene, 2,5-dimethoxytoluene, 4-ethylphenetole, 1,2,4-trimethoxybenzene, 4-(1-propenyl)-1,2-dimethoxybenzene, 1,3-dimethoxybenzene, glycidyl phenyl ether, dibenzyl ether, 4-tert-butylanisole, trans-p-propenylanisole, 1,2-dimethoxybenzene, 1-methoxynaphthalene, diphenyl ether, 2-phenoxymethyl ether, 2-phenoxytetrahydrofuran, ethyl-2-naphthyl ether, amyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethylene glycol ethyl methyl ether, triethylene glycol butyl methyl ether, tripropylene glycol dimethyl ether, tetraethylene glycol dimethyl ether; alkyl octoate, alkyl sebacate, alkyl stearate, alkyl benzoate, alkyl phenylacetate, alkyl cinnamate, alkyl oxalate, alkyl maleate, alkyl lactone, and alkyl oleate.

16. An organic electronic device, comprising a silicon-containing organic compound according to claim 1.

17. The organic electronic device according to claim 16, wherein the organic electronic device is an organic light-emitting diode, an organic photovoltaic cell, an organic light-emitting electrochemical cell, an organic field-effect transistor, an organic light-emitting field-effect transistor, an organic laser, an organic spin electron device, an organic sensor, or an organic plasmon emitting diode.

18. The organic electronic device according to claim 16, which is an organic electroluminescent device comprising one light-emitting layer, which comprises a silicon-containing organic compound according to claim 1.

19. The organic electronic device according to claim 16, which is an organic electroluminescent device comprising one light-emitting layer, which comprises a silicon-containing organic compound according to claim 1 and a phosphorescent emitter.

20. The organic electronic device according to claim 16, comprising a silicon-containing organic compound according to claim 1 and a TADF material.
